(19) United States
(12) Patent Application Publication
(10) Pub. No.: US 2016/0093627 A1
(43) Pub. Date: Mar. 31, 2016

(54) SEMICONDUCTOR DEVICE AND METHOD OF MANUFACTURING THE SAME

(71) Applicant: FUJITSU SEMICONDUCTOR LIMITED, Yokohama-shi (JP)

(72) Inventors: Naoya SASHIDA, Kuwana (JP); TATSUYA SUGIMACHI, KUWANA (JP)

(21) Appl. No.: 14/830,925

(22) Filed: Aug. 20, 2015

(30) Foreign Application Priority Data
Sep. 30, 2014 (JP) 2014-201912

(51) Int. Cl. H01L 27/115; H01L 21/311; H01L 21/3213; H01L 23/58; H01L 49/02

(52) U.S. Cl. CPC H01L 27/11507; H01L 27/11512; H01L 23/585; H01L 28/60; H01L 21/32133; H01L 21/31111

(57) ABSTRACT

A semiconductor device includes: a semiconductor substrate; a ferroelectric capacitor above the semiconductor substrate; a first guard ring around the ferroelectric capacitor above the semiconductor substrate. The ferroelectric capacitor includes a bottom electrode, a capacitor insulating film and a top electrode. The first guard ring includes a first pseudo bottom electrode, a first pseudo capacitor insulating film and a first pseudo top electrode, and surrounds the ferroelectric capacitors in planar view.

### CROSS-REFERENCE TO RELATED APPLICATION

This application is based upon and claims the benefit of priority of the prior Japanese Patent Application No. 2014-201912, filed on Sep. 30, 2014, the entire contents of which are incorporated herein by reference.

### FIELD

The embodiments discussed herein are directed to a semiconductor device and a method of manufacturing the same.

### BACKGROUND

Examples of non-volatile memories include flash memories, electrically erasable programmable read-only memories (EEPROMs), and ferroelectric memories. Data are stored by accumulation of charge in a floating gate in the flash memory and the EEPROM. Data are stored utilizing polarization inversion in a ferroelectric film in the ferroelectric memory. The ferroelectric memory has an advantage of having higher resistance to radiations, such as gamma rays, electron rays and neutron rays, than that of the flash memory and the EEPROM.

However, conventional ferroelectric memories have a problem of difficulty in securing a desired polarization charge amount when ferroelectric capacitors are microfabricated.
Patent Literature 1: Japanese Laid-Open Patent Publication No. 2004-95877

### SUMMARY

According to an aspect of the embodiments, a semiconductor device includes: a semiconductor substrate; a ferroelectric capacitor above the semiconductor substrate; a first guard ring around the ferroelectric capacitor above the semiconductor substrate. The ferroelectric capacitor includes a bottom electrode, a capacitor insulating film and a top electrode. The first guard ring includes a first pseudo bottom electrode, a first pseudo capacitor insulating film and a first pseudo top electrode, and surrounds the ferroelectric capacitors in planar view.

According to another aspect of the embodiments, a method of manufacturing a semiconductor device includes: forming a first conductive film, a ferroelectric film and a second conductive film over a semiconductor substrate; and etching the first conductive film, the ferroelectric film and the second conductive film so as to form a ferroelectric capacitor and a first guard ring. The first guard ring surrounds the ferroelectric capacitor in planar view.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic diagram illustrating a layout of a semiconductor device according to a first embodiment;

FIG. 2 is a circuit diagram illustrating a structure of the semiconductor device according to the first embodiment;

FIG. 3A is a cross-sectional view illustrating the structure of the semiconductor device according to the first embodiment;

FIG. 3B is a schematic view illustrating a three-dimensional positional relation of a word line, a bit line and a plate line;

FIG. 4A is a cross-sectional view illustrating a structure of a field effect transistor;

FIG. 4B is a cross-sectional view illustrating a structure of a ferroelectric capacitor;

FIG. 4C is a cross-sectional view illustrating a structure of a pseudo ferroelectric capacitor;

FIG. 5A to FIG. 5H are cross-sectional views illustrating a method of manufacturing the semiconductor device according to the first embodiment in order of steps;

FIG. 6A is a cross-sectional view illustrating a structure of a plug;

FIG. 6B is a cross-sectional view illustrating a structure of another plug;

FIG. 6C is a cross-sectional view illustrating a structure of a wiring;

FIG. 7 is a cross-sectional view illustrating a structure of a semiconductor device according to a second embodiment;

FIG. 8 is a cross-sectional view illustrating a structure of a semiconductor device according to a third embodiment;

FIG. 9 is a cross-sectional view illustrating a structure of a semiconductor device according to a fourth embodiment;

FIG. 10 is a cross-sectional view illustrating a structure of a semiconductor device according to a fifth embodiment;

FIG. 11 is a cross-sectional view illustrating a structure of a semiconductor device according to a sixth embodiment;

FIG. 12 is a cross-sectional view illustrating a structure of a semiconductor device according to a seventh embodiment;

FIG. 13 is a cross-sectional view illustrating a structure of a semiconductor device according to an eighth embodiment;

FIG. 14 is a cross-sectional view illustrating a structure of a semiconductor device according to a ninth embodiment;

FIG. 15 is a cross-sectional view illustrating a structure of a semiconductor device according to a tenth embodiment;

FIG. 16 is a cross-sectional view illustrating a structure of a semiconductor device according to an eleventh embodiment;

FIG. 17 is a cross-sectional view illustrating a structure of a semiconductor device according to a twelfth embodiment;

FIG. 18 is a cross-sectional view illustrating a structure of a semiconductor device according to a thirteenth embodiment;

FIG. 19 is a cross-sectional view illustrating a structure of a semiconductor device according to a fourteenth embodiment;

FIG. 20 is a cross-sectional view illustrating a structure of a semiconductor device according to a fifteenth embodiment;

FIG. 21 is a cross-sectional view illustrating a structure of a semiconductor device according to a sixteenth embodiment;

FIG. 22 is a cross-sectional view illustrating a structure of a semiconductor device according to a seventeenth embodiment;

FIG. 23 is a cross-sectional view illustrating a structure of a semiconductor device according to an eighteenth embodiment;

FIG. 24 is a cross-sectional view illustrating a structure of a semiconductor device according to a nineteenth embodiment;

FIG. 25 is a cross-sectional view illustrating a structure of a semiconductor device according to a twentieth embodiment;

FIG. 26 is a cross-sectional view illustrating a structure of a semiconductor device according to a twenty-first embodiment;

FIG. 27 is a cross-sectional view illustrating a structure of a semiconductor device according to a twenty-second embodiment;

FIG. 28 is a cross-sectional view illustrating a structure of a semiconductor device according to a twenty-third embodiment;

FIG. 29 is a cross-sectional view illustrating a structure of a semiconductor device according to a twenty-fourth embodiment;

FIG. 30 is a cross-sectional view illustrating a structure of a semiconductor device according to a twenty-fifth embodiment;

FIG. 31 is a cross-sectional view illustrating a structure of a semiconductor device according to a twenty-sixth embodiment;

FIG. 32 is a cross-sectional view illustrating a structure of a semiconductor device according to a twenty-seventh embodiment;

FIG. 33 is a cross-sectional view illustrating a structure of a semiconductor device according to a twenty-eighth embodiment;

FIG. 34 is a cross-sectional view illustrating a structure of a semiconductor device according to a twenty-ninth embodiment;

FIG. 35 is a cross-sectional view illustrating a structure of a semiconductor device according to a thirtieth embodiment;

FIG. 36 is a cross-sectional view illustrating a structure of a semiconductor device according to a thirty-first embodiment;

FIG. 37 is a view illustrating a layout of a semiconductor device according to a thirty-second embodiment;

FIG. 38A and FIG. 38B are views illustrating parts of FIG. 37 in enlargement;

FIG. 39 is a cross-sectional view taken along a line I-I in FIG. 38A;

FIG. 40 is a cross-sectional view taken along a line II-II in FIG. 38A;

FIG. 41 is a cross-sectional view taken along a line III-III in FIG. 38B;

FIG. 42 is a cross-sectional view illustrating a structure of a semiconductor device according to a modified example of the thirty-second embodiment;

FIG. 43 is a view illustrating a layout of a semiconductor device according to a thirty-third embodiment;

FIG. 44 is a cross-sectional view taken along a line I-I in FIG. 43;

FIG. 45 is a cross-sectional view illustrating a manufacturing process of the semiconductor device according to the thirty-third embodiment;

FIG. 46 is a cross-sectional view illustrating a structure of a semiconductor device according to a modified example of the thirty-third embodiment;

FIG. 47 is a view illustrating a layout of a semiconductor device according to a thirty-fourth embodiment;

FIG. 48 is a cross-sectional view taken along a line I-I in FIG. 47;

FIG. 49A to FIG. 49E are cross-sectional views illustrating structures of samples; and

FIG. 50 is a graph illustrating polarization charge amounts Qsw of the samples.

### DESCRIPTION OF EMBODIMENTS

Hereinafter, embodiments will be explained specifically with reference to accompanying drawings.

### First Embodiment

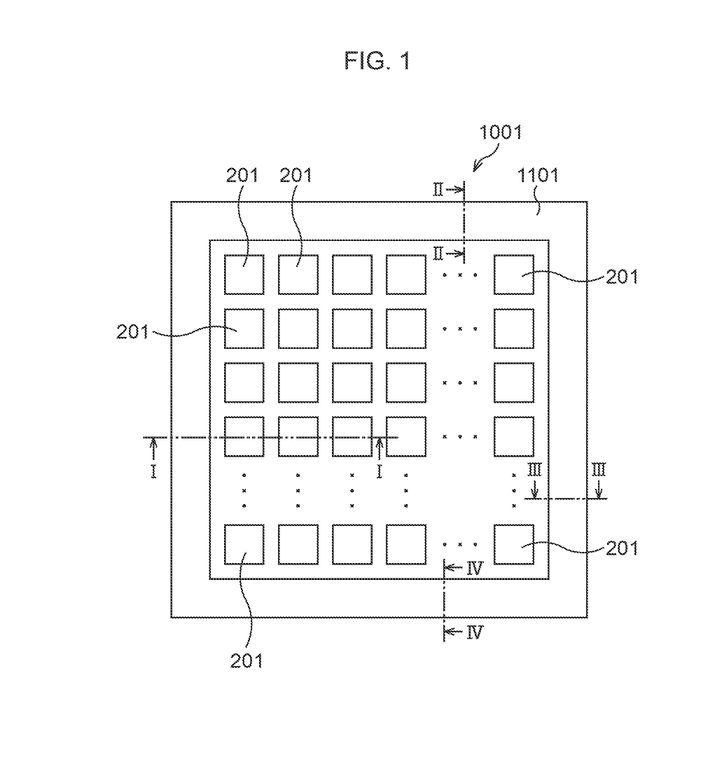

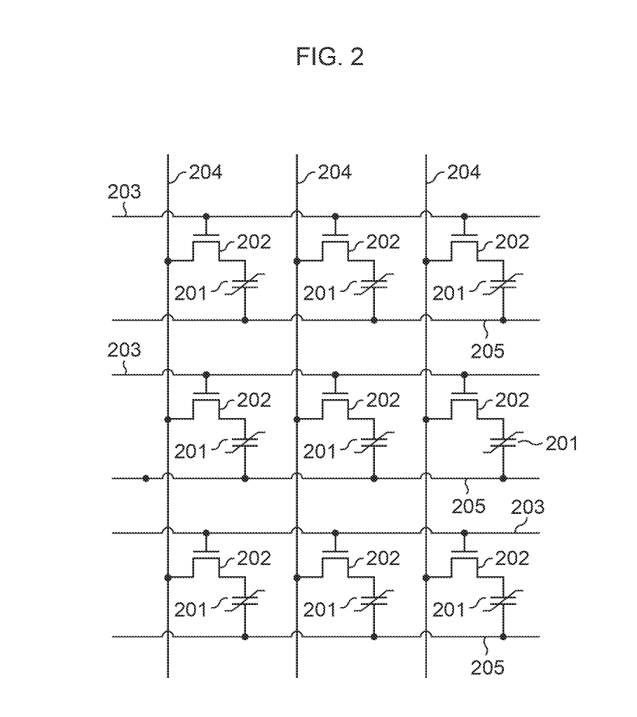

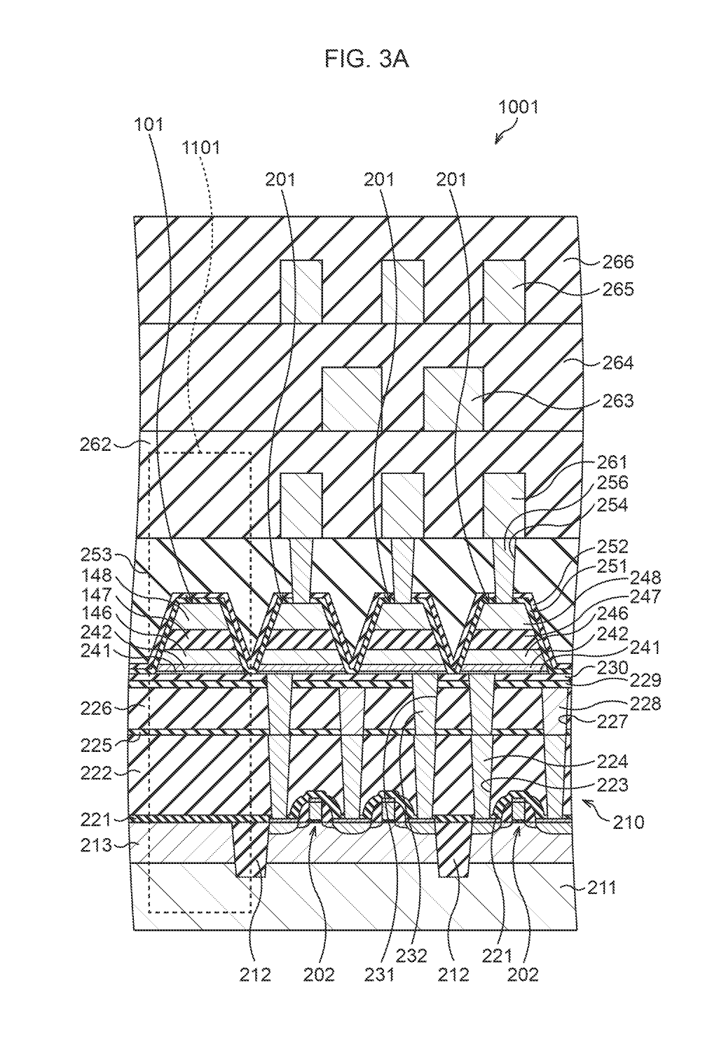

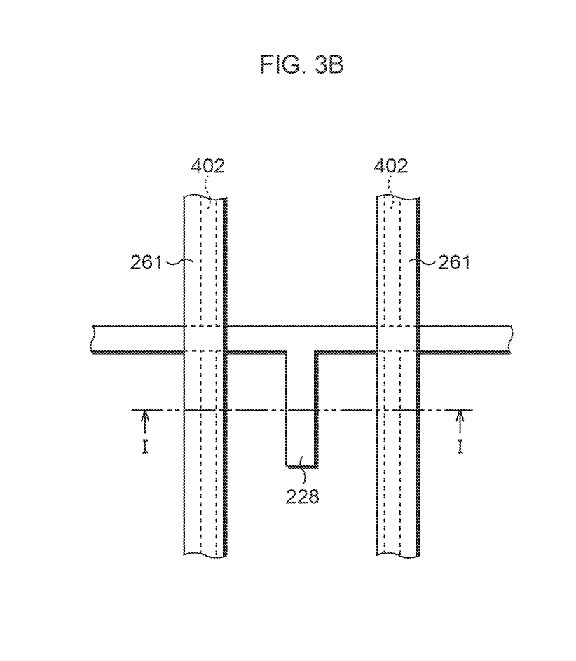

First, a first embodiment will be explained. The first embodiment is an example of a ferroelectric memory. FIG. 1 is a schematic diagram illustrating a layout of a semiconductor device according to the first embodiment. FIG. 2 is a circuit diagram illustrating a structure of the semiconductor device according to the first embodiment. FIG. 3A is a cross-sectional view illustrating the structure of the semiconductor device according to the first embodiment. FIG. 3A illustrates a cross section taken along a line I-I in FIG. 1. FIG. 3B is a schematic view illustrating a three-dimensional positional relation of a word line, a bit line and a plate line in a vicinity of an area illustrated in FIG. 3A.

A semiconductor device 1001 according to the first embodiment includes, as illustrated in FIG. 1, a plurality of ferroelectric capacitors 201 and a guard ring 1101 surrounding these ferroelectric capacitors 201. The semiconductor device 1001 also includes, as illustrated in FIG. 2, a plurality of switching elements 202, a plurality of word lines 203, a plurality of bit lines 204 and a plurality of plate lines 205. The word lines 203 each switch on and off two or more of the plurality of switching elements 202. The bit lines 204 are each connected to two or more of the plurality of switching elements 202. The plate lines 205 are connected to two or more ferroelectric capacitors 201, which are connected respectively to two or more switching elements 202 which are switched on and off by the word lines 203.

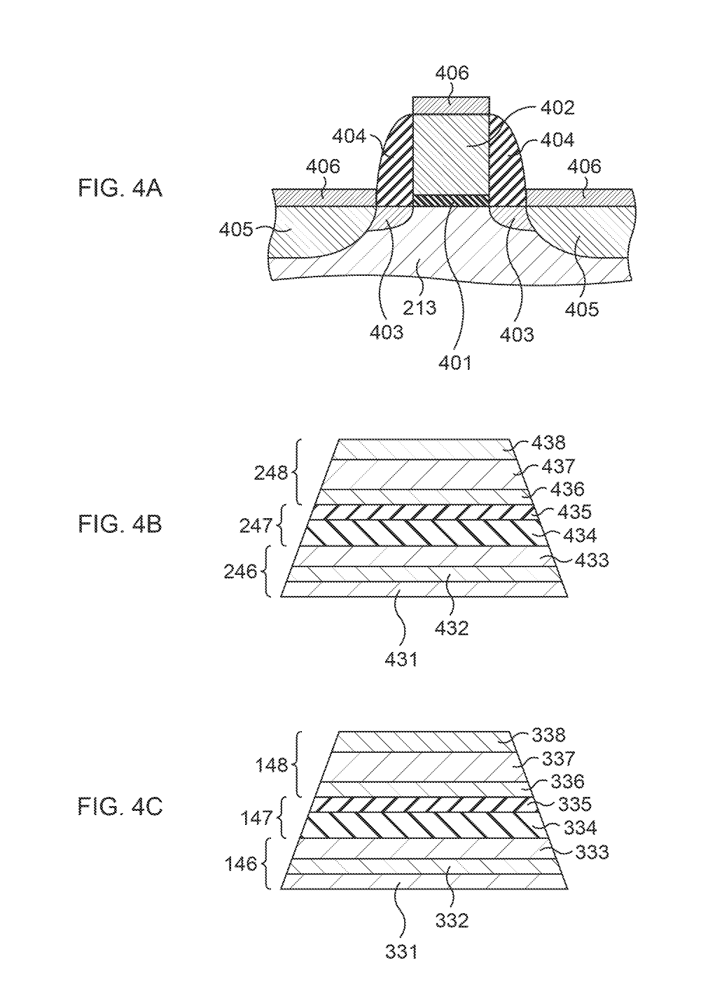

As illustrated in FIG. 3A, the semiconductor device 1001 includes a semiconductor substrate 211 of an n-type or p-type silicon substrate, for example. An element isolation region 212 defining active regions of transistors are formed at a surface of the semiconductor substrate 211. A P-well 213 is formed in the active region, and the switching element 202 with the P-well 213 is formed. The switching element 202 is a field effect transistor, for example. This field effect transistor includes, as illustrated in FIG. 4A, a gate insulating film 401, a gate electrode 402, impurity doped regions 403, an insulating side wall 404, impurity doped regions 405 and silicide layers 406, for example. The gate electrode 402 functions as a part of the word line 203 (FIG. 3B).

A cover film 221 covering the switching elements 202 is formed over the semiconductor substrate 211, and an interlayer insulating film 222 is formed over the cover film 221. A contact hole 223 through which the silicide layer 406 is exposed is formed in the interlayer insulating film 222 and the cover film 221, and a conductive plug 224 is formed in the contact hole 223. An etching stopper film 225 is formed over the interlayer insulating film 222 and the conductive plug 224, and an interlayer insulating film 226 is formed over the etching stopper film 225. An opening 227 is formed in the interlayer insulating film 226 and the etching stopper film 225, and a wiring 228 is formed in the opening 227. The wiring 228 is connected to a part of the conductive plugs 224 and functions as a part of the bit line 224 (FIG. 3B). An oxidation preventing film 229 is formed over the interlayer insulating film 226 and the wiring 228, and a buffer film 230 is formed over the oxidation preventing film 229. A contact hole 231 through which a part of the conductive plugs 224 is exposed is formed in the buffer film 230, the oxidation preventing film 229, the interlayer insulating film 226 and the etching stopper film 225, and a conductive plug 232 is formed in the contact hole 231.

A titanium nitride film 241 and an aluminum titanium nitride film 242 are formed on and above the buffer film 230 and the conductive plug 232. The ferroelectric capacitors 201 and a pseudo ferroelectric capacitor 101 with an annular planar shape are formed above the aluminum titanium nitride film 242. The pseudo ferroelectric capacitor 101 is included in the guard ring 1101 and surrounds the ferroelectric capacitors 201. The ferroelectric capacitor 201 includes a bottom electrode 246, a capacitor insulating film 247 and a top electrode 248, and the pseudo ferroelectric capacitor 101 includes a pseudo bottom electrode 146, a pseudo capacitor insulating film 147 and a pseudo top electrode 148. The titanium nitride film 241 and the aluminum titanium nitride film 242 are patterned similarly to the bottom electrode 246, the capacitor insulating film 247 and the top electrode 248, and the pseudo bottom electrode 146, the pseudo capacitor insulating film 147 and the pseudo top electrode 148. The bottom electrode 246 of one of the ferroelectric capacitors 201 is electrically connected to one of the conductive plugs 232.

The bottom electrode 246 includes, as illustrated in FIG. 4B, an iridium film 431, an iridium oxide film 432 and a platinum film 433. The capacitor insulating film 247 includes a ferroelectric film 434 and a ferroelectric film 435. The ferroelectric film 434 and the ferroelectric film 435 are different in composition, for example. The top electrode 248 includes an iridium oxide film 436, an iridium oxide film 437 and an iridium film 438. For example, the oxidation degree of the iridium oxide film 437 is higher than the oxidation degree of the iridium oxide film 436.

The pseudo bottom electrode 146 includes, as illustrated in FIG. 4C, an iridium film 331, an iridium oxide film 332 and a platinum film 333. The pseudo capacitor insulating film 147 includes a ferroelectric film 334 and a ferroelectric film 335. The ferroelectric film 334 and the ferroelectric film 335 are different in composition, for example. The pseudo top electrode 148 includes an iridium oxide film 336, an iridium oxide film 337 and an iridium film 338. For example, the oxidation degree of the iridium oxide film 337 is higher than the oxidation degree of the iridium oxide film 336.

A protection film 251 covering the ferroelectric capacitors 201 and the pseudo ferroelectric capacitor 101 is formed over the buffer film 230, a protection film 252 is formed over the protection film 251, and an interlayer insulating film 253 is formed over the protection film 252. A contact hole 254 through which the top electrode 248 is exposed is formed in the interlayer insulating film 253, the protection film 252 and the protection film 251, and a conductive plug 256 is formed in the contact hole 254.

A wiring 261 electrically connected to the conductive plug 256 is formed above the interlayer insulating film 253. The wiring 261 functions as a part of the plate line 205 (FIG. 3B). An interlayer insulating film 262 covering the wiring 261 is formed over the interlayer insulating film 253, and a wiring 263 is formed above the interlayer insulating film 262. The wiring 263 functions as a shunt of the word line 203. An interlayer insulating film 264 covering the wirings 263 is formed over the interlayer insulating film 262, a wiring 265 is formed above the interlayer insulating film 264, and an interlayer insulating film 266 covering the wiring 265 is formed over the interlayer insulating film 264. The wiring 265 functions as a shunt of the bit line 204. The guard ring 1101 has a structure similar to that illustrated in FIG. 3A also in the cross section taken along a line II-II, the cross section taken along a line III-III, and the cross section taken along a line IV-IV in FIG. 1.

The protection film 251, the protection film 252 and the interlayer insulating film 253 are included in a first insulating film. The oxidation preventing film 229 and the buffer film 230 are included in a third insulating film. The etching stopper film 225 and the interlayer insulating film 226 are included in a fourth insulating film. The cover film 221 and the interlayer insulating film 222 are included in a fifth insulating film. The third insulating film, the fourth insulating film and the fifth insulating film are included in a base 210.

In the semiconductor device 1001, the guard ring 1101 including the pseudo ferroelectric capacitor 101 is formed annularly so as to surround the ferroelectric capacitors 201. Thus, intrusion of moisture and hydrogen from outside the pseudo ferroelectric capacitor 101 can be appropriately suppressed during annealing performed in a state that the contact hole 254 is formed, and in-process degradation which the ferroelectric capacitors 201 would suffer can be suppressed significantly. Therefore, even when the ferroelectric capacitors 201 are microfabricated, a sufficient polarization charge amount can be obtained.

Further, in this embodiment, the ferroelectric capacitors 201 are located at a level above the wiring 228, which functions as a part of the bit line 204. That is, a capacitor over bit line (COB) structure is employed.

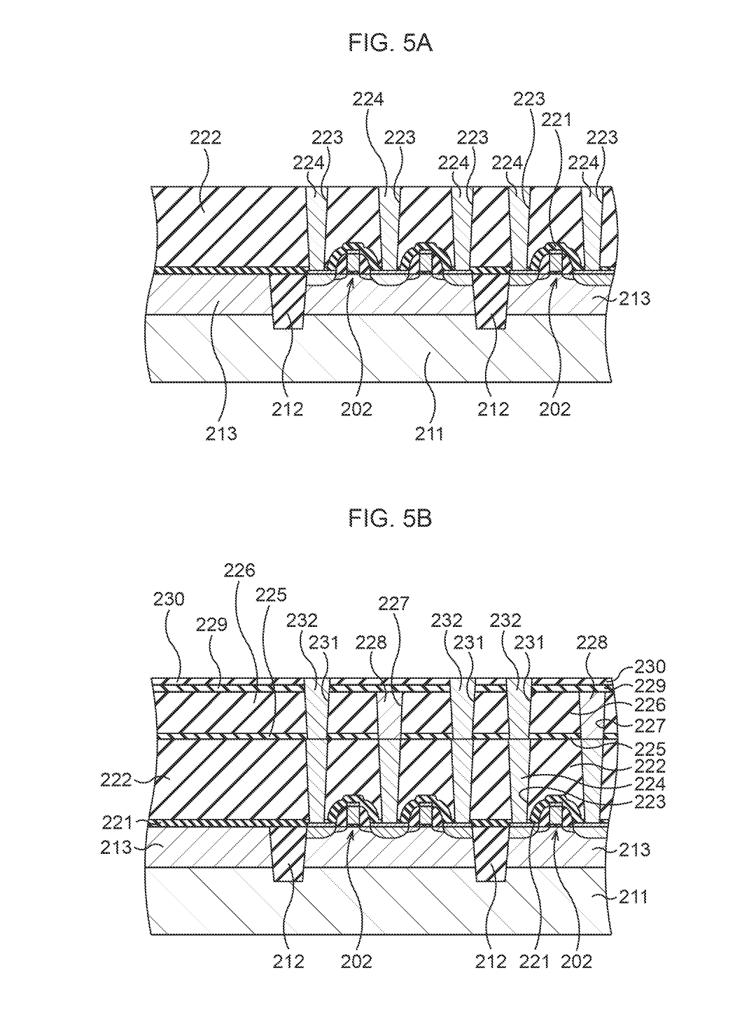

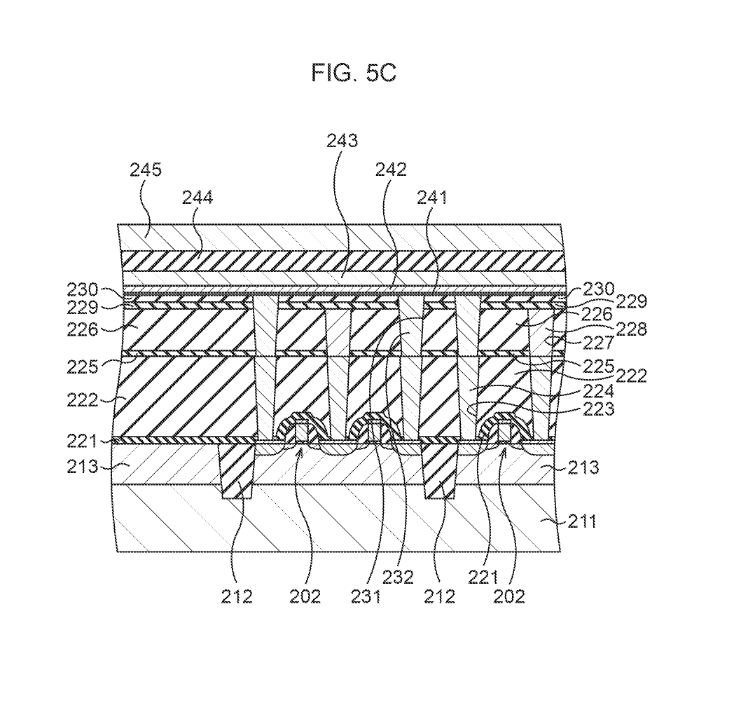

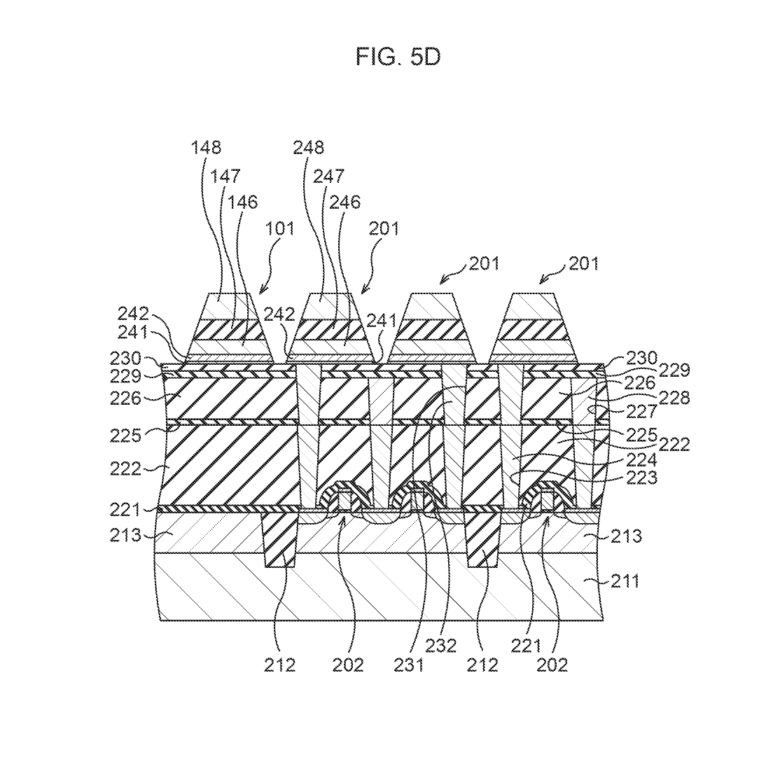

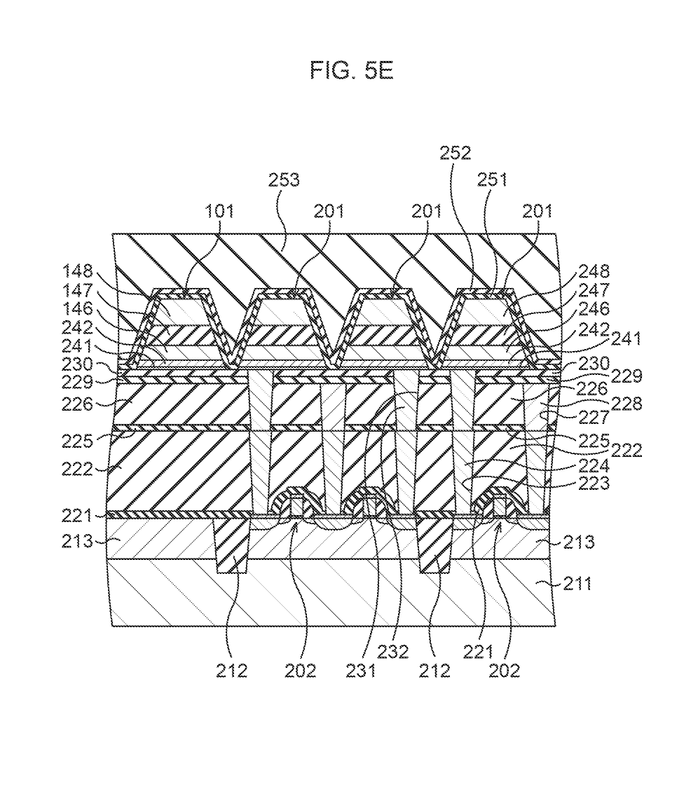

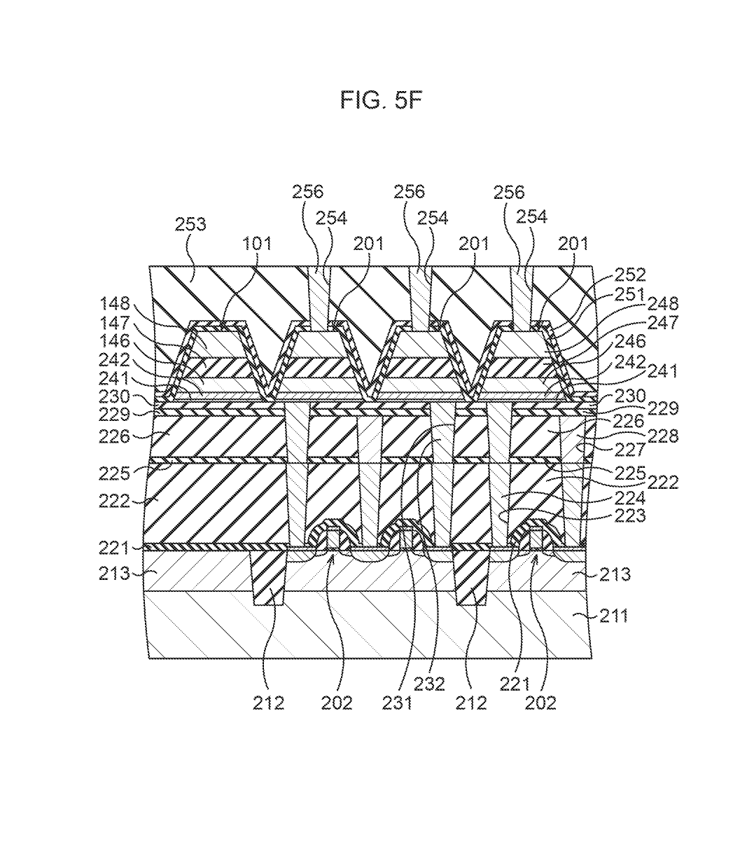

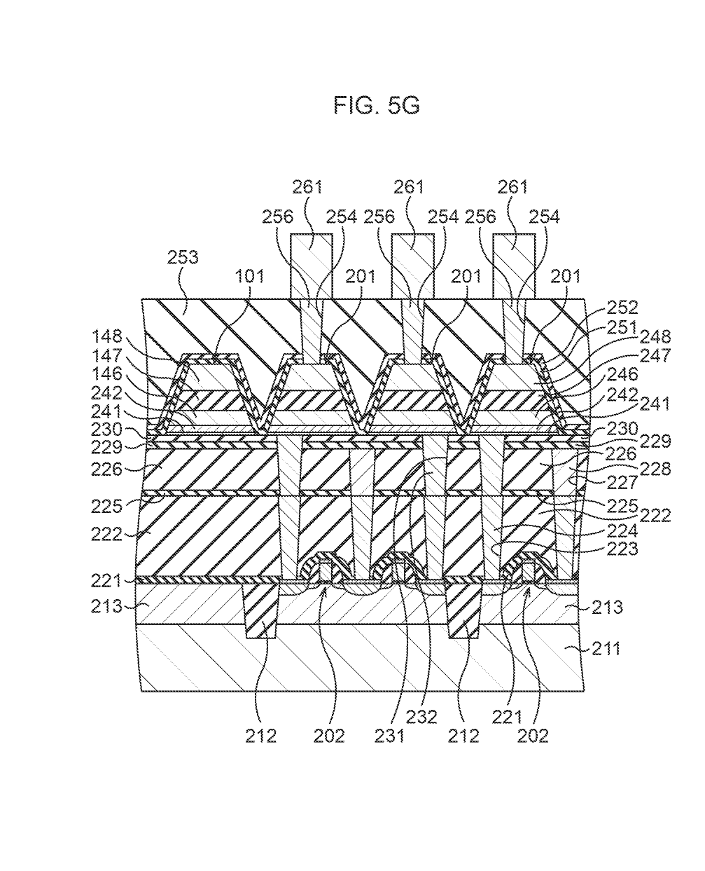

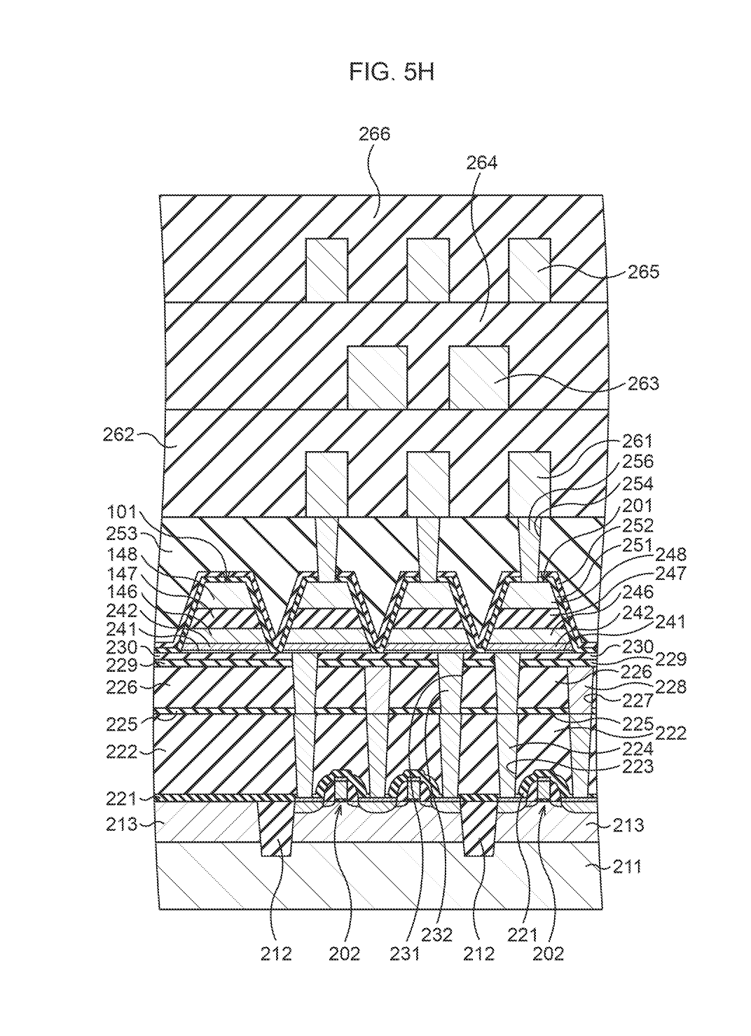

Next, a method of manufacturing the semiconductor device according to the first embodiment will be explained. FIG. 5A to FIG. 5H are cross-sectional views illustrating the method of manufacturing the semiconductor device according to the first embodiment in order of steps.

First, as illustrated in FIG. 5A, the element isolation region 212 defining the active regions of transistors is formed at the surface of the semiconductor substrate 211. As the element isolation region 212, for example, shallow trench isolation (STI) is formed. The STI may be formed by forming a trench at the surface of the semiconductor substrate 211 and embedding an insulating film of such as a silicon oxide therein. An insulating film may be formed by a local oxidation of silicon (LOCOS) method as the element isolation region 212. Then, impurities are introduced into the active regions, to thereby form the P-wells 213, for example. Thereafter, the switching elements 202 are formed in the active regions. As the switching elements 202, for example, the field effect transistor illustrated in FIG. 4A is formed.

In formation of this field effect transistor, first, the gate insulating film 401 is formed on a surface of the active region. The gate insulating film 401 may be formed by thermal oxidation, for example. Then, the gate electrode 402 is formed on the gate insulating film 401. The gate electrode 402 may be formed by forming an amorphous or polycrystalline silicon film on the entire upper surface of the semiconductor substrate 211, and patterning this silicon film by a photolithography method, for example. Thereafter, using the gate electrode 402 as a mask, n-type impurities are ion implanted into the P-well 213 on both sides of the gate electrode 402, to thereby form n-type impurity doped regions 403 as extension regions. Subsequently, the insulating side wall 404 is formed on a side surface of the gate electrode 402. The side wall 404 may be formed by forming an insulating film over the semiconductor substrate 211 and the gate electrode 402, and etching-back this insulating film, for example. A silicon oxide film may be formed as the insulating film by a chemical vapor deposition (CVD) method, for example. Then, using the side wall 404 and the gate electrode 402 as a mask, n-type impurities are ion implanted into the P-wells 213 by higher concentration than that at the time of forming the impurity doped regions 403, to thereby form n-type impurity doped regions 405. As a result, source/drain regions including the impurity doped region 403 and the impurity doped region 405 are obtained. After forming the impurity doped regions 405, the silicide layers 406 are formed on the gate electrode 402 and on the impurity doped regions 405. When the silicide layers 406 are formed, a metal film such as a cobalt film is formed by a sputtering method, and this metal film is heated and brought into reaction with silicon. Then, non-reacted portions of the metal film are removed by wet etching.

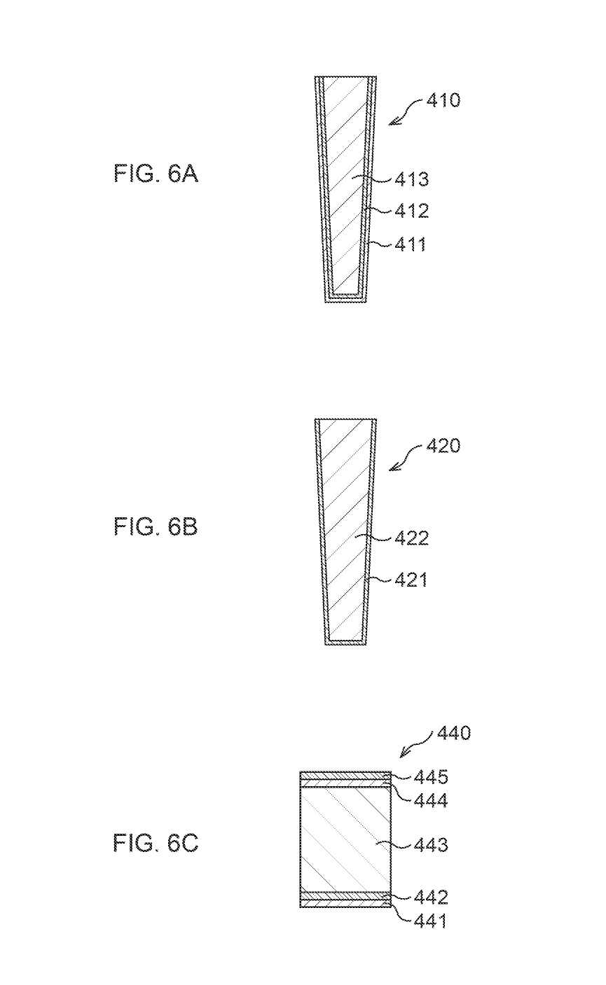

Then, the cover film 221 covering the switching elements 202 is formed. A silicon nitride film with a thickness of approximately 70 nm is formed as the cover film 221 by a plasma CVD method, for example. Thereafter, the interlayer insulating film 222 is formed over the cover film 221. A silicon oxide film with a thickness of approximately 1.1 μm is formed as the interlayer insulating film 222 by a plasma CVD method using gas containing tetraethoxysilane (TEOS), for example. Subsequently, an upper surface of the interlayer insulating film 222 is polished and planarized by a chemical-mechanical polishing (CMP) method. The thickness of the interlayer insulating film 222 after polishing is, for example, approximately 600 nm above a flat surface of the semiconductor substrate 211. Then, the contact hole 223 thorough which the silicide layer 406 is exposed is formed in the interlayer insulating film 222 and the cover film 221. In formation of the contact hole 223, for example, the interlayer insulating film 222 and the cover film 221 are patterned by a photolithography method. The diameter of the contact hole 223 is, for example, 0.20 μm. Thereafter, the conductive plug 224 is formed in the contact hole 223. A plug having a stacked structure similar to a conductive stack 410 illustrated in FIG. 6A is formed as the conductive plug 224, for example. More specifically, for example, a titanium film 411 with a thickness of 30 nm and a titanium nitride film 412 with a thickness of 20 nm are formed sequentially as an adhering film (glue film) by a CVD method in the contact hole 223, and a tungsten film 413 is formed by a CVD method on the titanium nitride film 412. Then, the tungsten film 413, the titanium nitride film 412, and the titanium film 411 are polished by a CMP method until the upper surface of the interlayer insulating film 222 is exposed.

Then, as illustrated in FIG. 5B, the etching stopper film 225 is formed over the interlayer insulating film 222 and the conductive plugs 224. A silicon nitride film with a thickness of approximately 30 nm is formed as the etching stopper film 225, for example. Thereafter, the interlayer insulating film 226 is formed over the etching stopper film 225. A silicon oxide film with a thickness of approximately 350 nm is formed by the plasma CVD method using gas containing TEOS as the interlayer insulating film 226, for example. Subsequently, the opening 227 through which a part of the conductive plugs 224 is exposed is formed in a region where the bit lines 204 are to be formed in the interlayer insulating film 226 and the etching stopper film 225. In formation of the opening 227, for example, a silicon nitride film with a thickness of approximately 15 nm is formed as a sacrificial film over the interlayer insulating film 226, an opening reaching the etching stopper film 225 is formed in this sacrificial film and the interlayer insulating film 226 by using a mask of photoresist, the mask is removed, and the sacrificial film and the etching stopper film 225 are etched.

After the opening 227 is formed, the wiring 228 is formed as a part of the bit lines 204 in the opening 227. A wiring having a stacked structure similar to the conductive stack 410 illustrated in FIG. 6A is formed as the wirings 228, for example. More specifically, for example, a titanium film 411 with a thickness of 10 nm and a titanium nitride film 412 with a thickness of 20 nm are formed sequentially as an adhering film (glue film) by a CVD method in the opening 227, and a tungsten film 413 is formed by a CVD method on the titanium nitride film 412. Then, the tungsten film 413, the titanium nitride film 412, and the titanium film 411 are polished by a CMP method until the upper surface of the interlayer insulating film 226 is exposed.

After the wiring 228 is formed, the oxidation preventing film 229 is formed over the interlayer insulating film 226 and the wiring 228. A silicon nitride film with a thickness of approximately 30 nm is formed as the oxidation preventing film 229, for example. The oxidation preventing film 229 prevents oxidation of the wiring 228 during forming the contact hole 231 or the like later. Then, a buffer film 230 is formed over the oxidation preventing film 229. A silicon oxide film with a thickness of approximately 200 nm is formed by the plasma CVD method using gas containing TEOS as the buffer film 230, for example. The buffer film 230, as will be described later, suppresses damage (film reduction) to below during etching for forming the ferroelectric capacitors 201. The buffer film 230 can also improve adhesiveness to the ferroelectric capacitors 201. Thereafter, the contact hole 231 through which a part of the conductive plugs 224 is exposed is formed in the buffer film 230, the oxidation preventing film 229, the interlayer insulating film 226 and the etching stopper film 225. In formation of the contact hole 231, for example, the buffer film 230, the oxidation preventing film 229 and the interlayer insulating film 226 are patterned by a photolithography method. The diameter of the contact hole 231 is, for example, 0.20 μm. Subsequently, the conductive plug 232 is formed in the contact hole 231. A plug having a stacked structure similar to the conductive stack 410 illustrated in FIG. 6A is formed as the conductive plugs 232, for example. More specifically, for example, a titanium film 411 with a thickness of 10 nm and a titanium nitride film 412 with a thickness of 20 nm are formed sequentially as an adhering film (glue film) by a CVD method in the contact hole 231, and a tungsten film 413 is formed by a CVD method on the titanium nitride film 412. Then, the tungsten film 413, the titanium nitride film 412, and the titanium film 411 are polished by a CMP method until the upper surface of the interlayer buffer film 230 is exposed. At this time, the buffer film 230 can stop excessive film reduction in polishing by the CMP method in the inside thereof, and prevent polishing of the oxidation preventing film 229. Instead of the tungsten film 413, a conductive film composed of a different material may be used, but also in this case, it is preferred to form a film of high-melting-point metal such as titanium in order to avoid deterioration due to a thermal treatment at high temperatures.

Then, as illustrated in FIG. 5C, for example, a titanium film with a thickness of 5 nm is formed over the buffer film 230 and the conductive plugs 232, and a nitriding treatment by RTA (rapid thermal annealing) method is performed, to thereby form the titanium nitride film 241. Thereafter, the aluminum titanium nitride film 242 is formed over the titanium nitride film 241. In formation of the aluminum titanium nitride film 242, for example, an aluminum titanium nitride film with a thickness of 40 nm is formed, this aluminum titanium nitride film is polished by a CMP method until its film thickness becomes approximately 20 nm, and another aluminum titanium nitride film is formed with a thickness of 25 nm. The aluminum titanium nitride film 242 has oxidation resistance. Due to influence of CMP, the upper surface of the conductive plug 232 is lower than an upper surface of the buffer film 230, and a recess may exist. However, this recess may disappear by the titanium nitride film 241 and the aluminum titanium nitride film 242. Subsequently, the conductive film 243, the ferroelectric film 244, and the conductive film 245 are formed over the aluminum titanium nitride film 242. The conductive film 243 is an example of a first conductive film, and the conductive film 245 is an example of a second conductive film.

In formation of the conductive film 243, for example, as illustrated in FIG. 4B and FIG. 4C, an iridium film with a thickness of 30 nm, an iridium oxide film with a thickness of 30 nm, and a platinum film with a thickness of 50 nm are formed. The iridium oxide film contributes to improvement of adhesiveness and cancel of orientation. The platinum film contributes to improvement of orientation.

In formation of the ferroelectric film 244, for example, as illustrated in FIG. 4B and FIG. 4C, a first ferroelectric film with a thickness of 75 nm, for example, PZT(Pb(Zrₓ, Ti₁₋ₓ)O₃) film (0<x<1) is formed, and a thermal treatment is performed by an RTA method in a mixed gas atmosphere of argon and oxygen. By this thermal treatment, crystals of the first ferroelectric film are oriented to be aligned with the orientation of crystals of the platinum film. Then, an amorphous second ferroelectric film with a thickness of 10 nm is formed over the first ferroelectric film. Formation of the second ferroelectric film may be omitted.

In formation of the conductive film 245, for example, as illustrated in FIG. 4B and FIG. 4C, a first iridium oxide film with a thickness of 25 nm is formed. A film capable of being crystallized at the point of film formation is formed as the first iridium oxide film by a sputtering method, for example. In formation of the first iridium oxide film, for example, pressure is set to 2 Pa and a substrate temperature is set to 300° C., an iridium target is used, mixed gas of argon and oxygen is used as reaction gas, and sputter power is, for example, about 1 kW to 2 kW. At this time, the flow rate ratio between argon gas and oxygen gas is, for example, 100:56. When formation of the second ferroelectric film is omitted, the conductive film 245 is formed over the first ferroelectric film. Then, a thermal treatment by an RTA method is performed in an atmosphere containing oxygen. In this thermal treatment, for example, mixed gas of argon and oxygen is used, the flow rate ratio between argon gas and oxygen gas is 100:1, a substrate temperature is set to 725° C., and a thermal treatment time is set to 60 seconds. By this thermal treatment, iridium atoms contained in the first iridium oxide film may diffuse across the first ferroelectric film, and the second ferroelectric film crystallizes.

After this thermal treatment, a second iridium oxide film higher in oxidation degree than the first iridium oxide film is formed over the first iridium oxide film. As the second iridium oxide film, for example, an IrO₂ film is formed. Formation temperature of the second iridium oxide film is preferably 100° C. or lower. This is for suppressing abnormal growth. Iridium oxide has a catalytic effect to activate hydrogen atoms to hydrogen radicals, and the higher the oxidation degree, the lower this catalytic effect is. The hydrogen radicals reduce ferroelectric, and thus the higher the oxidation degree of iridium oxide, the harder the ferroelectrics to be reduced. Therefore, by forming the second iridium oxide film higher in oxidation degree than the first iridium oxide film, reduction of the first and second ferroelectric films by hydrogen radicals can be suppressed. Then, an iridium film with a thickness of 80 nm is formed over the second iridium oxide film, for example. The iridium film contributes to decrease in contact resistance. Thereafter, a rear surface of the semiconductor substrate 211 is washed.

Subsequently, as illustrated in FIG. 5D, the conductive film 245, the ferroelectric film 244, the conductive film 243, the aluminum titanium nitride film 242 and the titanium nitride film 241 are patterned, to thereby form the ferroelectric capacitor 201 having the top electrode 248, the capacitor insulating film 247 and the bottom electrode 246, and the pseudo ferroelectric capacitor 101 having the pseudo top electrode 148, the pseudo capacitor insulating film 147 and the pseudo bottom electrode 146. At this time, the bottom electrode 246 is made to be electrically connected to the conductive plug 232. The pseudo bottom electrode 146 is formed at a same level as the bottom electrode 246, the pseudo capacitor insulating film 147 is formed at a same level as the capacitor insulating film 247, and the pseudo top electrode 148 is formed at a same level as the top electrode 248 in relation to the substrate 211.

For example, the bottom electrode 246 includes the iridium film 431, the iridium oxide film 432 and the platinum film 433, the capacitor insulating film 247 includes the ferroelectric film 434 and the ferroelectric film 435, and the top electrode 248 includes the iridium oxide film 436, the iridium oxide film 437 and the iridium film 438. For example, the pseudo bottom electrode 146 includes the iridium film 331, the iridium oxide film 332 and the platinum film 333, the pseudo capacitor insulating film 147 includes the ferroelectric film 334 and the ferroelectric film 335, and the pseudo top electrode 148 includes the iridium oxide film 336, the iridium oxide film 337 and the iridium film 338. The titanium nitride film 241 and the aluminum titanium nitride film 242 below the iridium film 431 may be regarded as a part of the bottom electrode 246, and the titanium nitride film 241 and the aluminum titanium nitride film 242 below the iridium film 331 may be regarded as a part of the pseudo bottom electrode 146. In patterning of the conductive film 245, the ferroelectric film 244, the conductive film 243, the aluminum titanium nitride film 242 and the titanium nitride film 241, a mask material film is formed on the conductive film 245, this mask is patterned by a photolithography method to form a hard mask, and the conductive film 245 and so on are etched using this hard mask. This etching is preferred to be finished inside the buffer film 230. Damage to below can be suppressed by finishing the etching inside the buffer film 230. In formation of the mask material film, for example, an aluminum titanium nitride film is formed by a sputtering method, and a silicon oxide film is formed thereon by the plasma CVD method using gas containing TEOS. Thicknesses of the aluminum titanium nitride film and the silicon oxide film are preferred to be adjusted so that the aluminum titanium nitride film and the silicon oxide film disappear when the etching is finished inside the buffer film 230. For example, the thickness of the aluminum titanium nitride film is approximately 200 nm, and the thickness of the silicon oxide film is approximately 280 nm.

Then, as illustrated in FIG. 5E, the protection film 251 covering the ferroelectric capacitors 201 is formed over the buffer film 230. An aluminum oxide film with a thickness of 5 nm to 20 nm is formed as the protection film 251 by a sputtering method, for example. Thereafter, annealing is performed in an oxygen atmosphere at temperatures of 500° C. to 650° C. in order to recover damage which occurred during formation of the protection film 251. Subsequently, the protection film 252 is formed over the protection film 251. An aluminum oxide film with a thickness of 30 nm to 100 nm is formed as the protection film 252 by a metal organic chemical vapor deposition (MOCVD) method or an atomic layer deposition (ALD) method, for example. Then, the interlayer insulating film 253 is formed over the protection film 252. A silicon oxide film with a thickness of approximately 1400 nm is formed as the interlayer insulating film 253 by a plasma CVD method using mixed gas of TEOS, oxygen and helium, for example. An inorganic film having an insulating property may be formed as the interlayer insulating film 253, for example.

Thereafter, a surface of the interlayer insulating film 253 is planarized by a CMP method, for example. Subsequently, a thermal treatment is performed in a plasma atmosphere generated using N₂O gas or N₂ gas. As a result of the thermal treatment, moisture in the interlayer insulating film 253 is removed, characteristic of the interlayer insulating film 253 changes, and it becomes difficult for moisture to enter the interlayer insulating film 253. After planarization by CMP of the interlayer insulating film 253, for example, a silicon oxide film with a thickness of approximately 250 nm may be formed by the plasma CVD method using gas containing TEOS. Even when a recess has occurred in the surface of the interlayer insulating film 253 between the ferroelectric capacitors 201 due to the influence of CMP, the recess is embedded and a smooth surface is obtained by forming this silicon oxide film. When this silicon oxide film is formed, it is also preferred to perform thereafter a thermal treatment in a plasma atmosphere generated using N₂O gas or N₂ gas.

Then, as illustrated in FIG. 5F, the contact hole 254 through which the top electrode 248 is exposed is formed in the interlayer insulating film 253, the protection film 252 and the protection film 251. In formation of the contact hole 254, for example, the interlayer insulating film 253, the protection film 252 and the protection film 251 are patterned by a photolithography method. When the hard mask remains on the top electrode 248, the contact hole 254 is formed, for example, so as to penetrate the hard mask. After the contact hole 254 is formed, annealing for 40 minutes is performed at a temperature of 450° C. in an oxygen atmosphere. By this annealing, oxygen is supplied to the capacitor insulating film 247. Thereafter, the conductive plug 256 is formed in the contact hole 254. A plug having a stacked structure similar to a conductive stack 420 illustrated in FIG. 6B is formed as the conductive plug 256, for example. More specifically, for example, a titanium nitride film 421 is formed as an adhering film (glue film) by a CVD method in the contact holes 254, and a tungsten film 422 is formed by a CVD method on the titanium nitride film 421. Then, the tungsten film 422 and the titanium nitride film 421 are polished by a CMP method until the upper surface of the interlayer insulating film 253 is exposed. A stack of a titanium film and a titanium nitride film may be formed instead of the titanium nitride film 421.

Thereafter, as illustrated in FIG. 5G, the wiring 261 electrically connected to the conductive plugs 256 is formed above the interlayer insulating film 253. A wiring having a stacked structure similar to a conductive stack 440 illustrated in FIG. 6C is formed as the wiring 261, for example. More specifically, for example, a titanium film 441 with a thickness of 60 nm, a titanium nitride film 442 with a thickness of 30 nm, an AlCu alloy film 443 with a thickness of 360 nm, a titanium film 444 with a thickness of 5 nm, and a titanium nitride film 445 with a thickness of 70 nm are formed sequentially by a sputtering method over the interlayer insulating film 253 and the conductive plugs 256. Then, these films are patterned by a photolithography method.

Subsequently, as illustrated in FIG. 5H, the interlayer insulating film 262 covering the wirings 261 is formed over the interlayer insulating film 253, and the wiring 263 is formed above the interlayer insulating film 262. Then, the interlayer insulating film 264 covering the wiring 263 is formed over the interlayer insulating film 262, the wiring 265 is formed above the interlayer insulating film 264, and the interlayer insulating film 266 covering the wiring 265 is formed over the interlayer insulating film 262. A wiring having a stacked structure similar to the conductive stack 440 illustrated in FIG. 6C is formed as the wiring 263 and the wiring 265, for example. A silicon oxide film is formed by the plasma CVD method using mixed gas of TEOS, oxygen and helium as the interlayer insulating film 262, the interlayer insulating film 264 and the interlayer insulating film 266, for example. An inorganic film having an insulating property may be formed as these interlayer insulating films, for example. Then, a wiring and an interlayer insulating film in an upper layer and so on are formed, thereby completing the semiconductor device.

In the manufacturing method, during annealing after the contact hole 254 is formed and before the conductive plug 256 is formed, during which damage to the ferroelectric capacitors 201 in particular easily occurs, the pseudo ferroelectric capacitor 101 is formed already. Thus, intrusion of moisture and hydrogen from outside the pseudo ferroelectric capacitor 101 can be suppressed appropriately, and in-process degradation which the ferroelectric capacitors 201 would suffer can be suppressed significantly.

### Second Embodiment

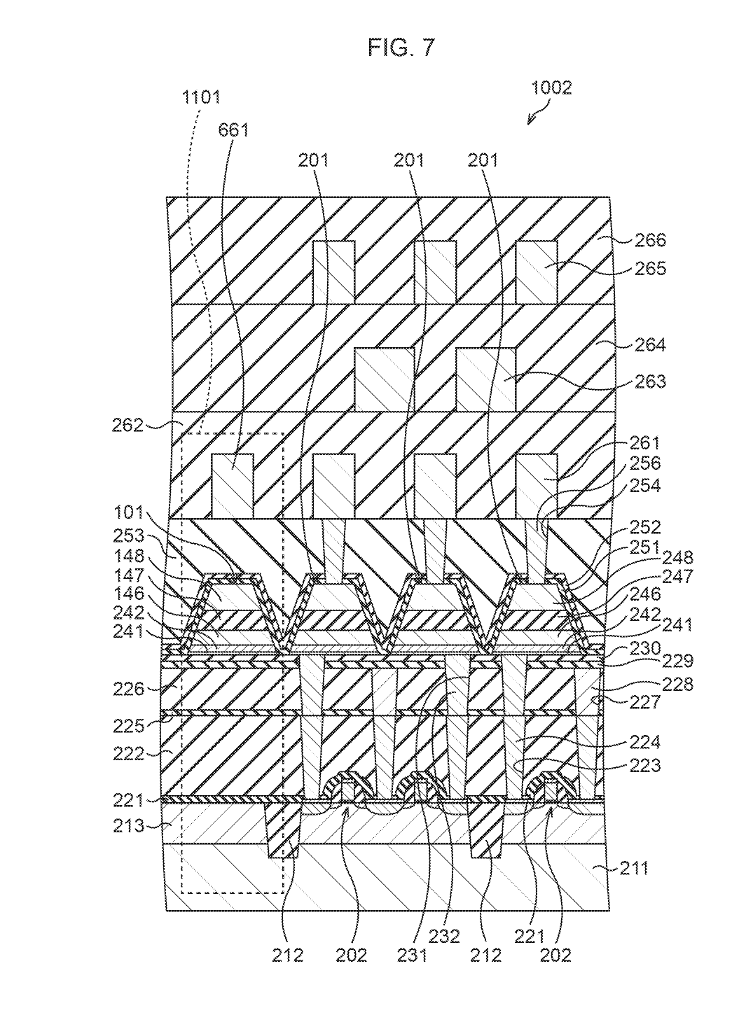

Next, a second embodiment will be explained. The second embodiment is an example of a ferroelectric memory. FIG. 7 is a cross-sectional view illustrating a structure of a semiconductor device according to the second embodiment. The layout and the circuit structure of the semiconductor device according to the second embodiment are similar to those of the first embodiment. FIG. 7 illustrates a cross section corresponding to the cross section taken along the line I-I in FIG. 1.

In a semiconductor device 1002 according to the second embodiment, as illustrated in FIG. 7, the guard ring 1101 includes a pseudo wiring 661 with an annular planar shape as well as the pseudo ferroelectric capacitor 101. The pseudo wiring 661 is formed in an annular shape above the interlayer insulating film 253, and has a stacked structure similar to the wirings 261 (FIG. 6C) and similar height and width. The other structure is similar to the first embodiment (FIG. 3A). The guard ring 1101 has a structure similar to that illustrated in FIG. 7 also in the cross section taken along a line II-II, the cross section taken along a line III-III, and the cross section taken along a line IV-IV in FIG. 1. The pseudo wiring 661 is an example of a first conductive pattern.

Effects similar to those of the first embodiment can be obtained by the semiconductor device 1002. The pseudo wiring 661 also contributes to suppression of intrusion of moisture and hydrogen. The pseudo wiring 661 may be formed contemporaneously with forming the wiring 261.

### Third Embodiment

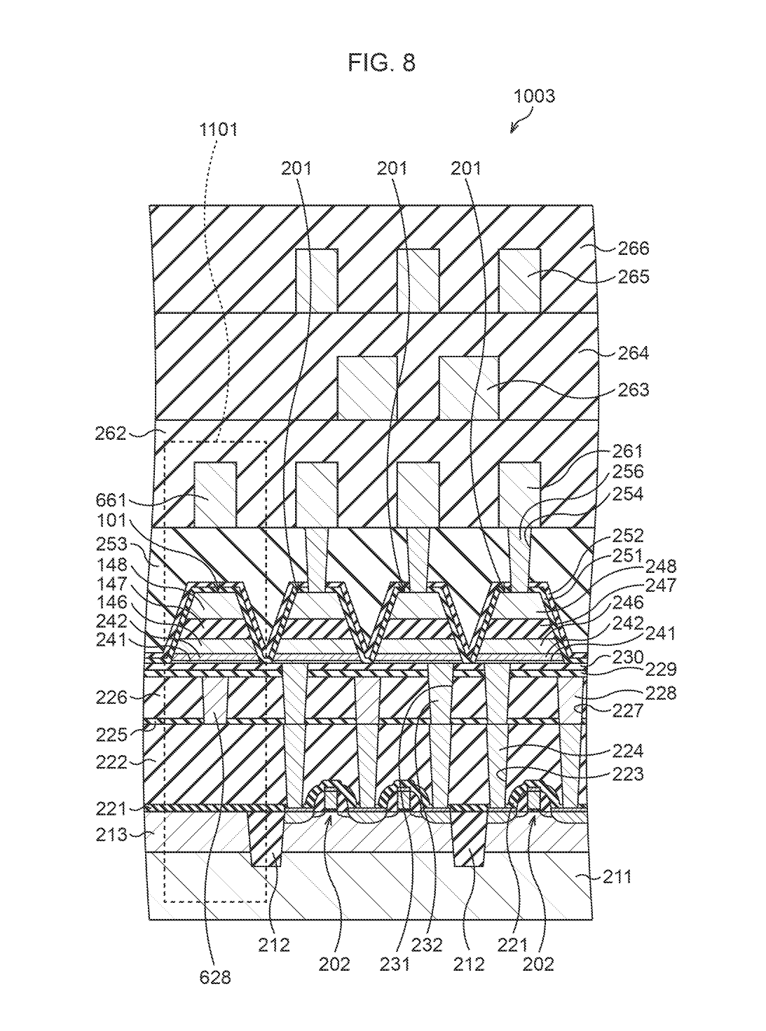

Next, a third embodiment will be explained. The third embodiment is an example of a ferroelectric memory. FIG. 8 is a cross-sectional view illustrating a structure of a semiconductor device according to the third embodiment. The layout and the circuit structure of the semiconductor device according to the third embodiment are similar to those of the first embodiment. FIG. 8 illustrates a cross section corresponding to the cross section taken along the line I-I in FIG. 1.

In a semiconductor device 1003 according to the third embodiment, as illustrated in FIG. 8, the guard ring 1101 includes a pseudo wiring 628 with an annular planar shape as well as the pseudo ferroelectric capacitor 101 and the pseudo wiring 661. The pseudo wiring 628 is formed in an annular opening formed in the interlayer insulating film 226 and the etching stopper film 225, and has a width similar to that of the wiring 228. The other structure is similar to the second embodiment (FIG. 7). The guard ring 1101 has a structure similar to that illustrated in FIG. 8 also in the cross section taken along a line II-II, the cross section taken along a line III-III, and the cross section taken along a line IV-IV in FIG. 1. The pseudo wiring 628 is an example of a third conductive pattern.

Effects similar to those of the second embodiment can be obtained by the semiconductor device 1003. The pseudo wiring 628 also contributes to suppression of intrusion of moisture and hydrogen. The pseudo wiring 628 may be formed contemporaneously with forming the wiring 228.

### Fourth Embodiment

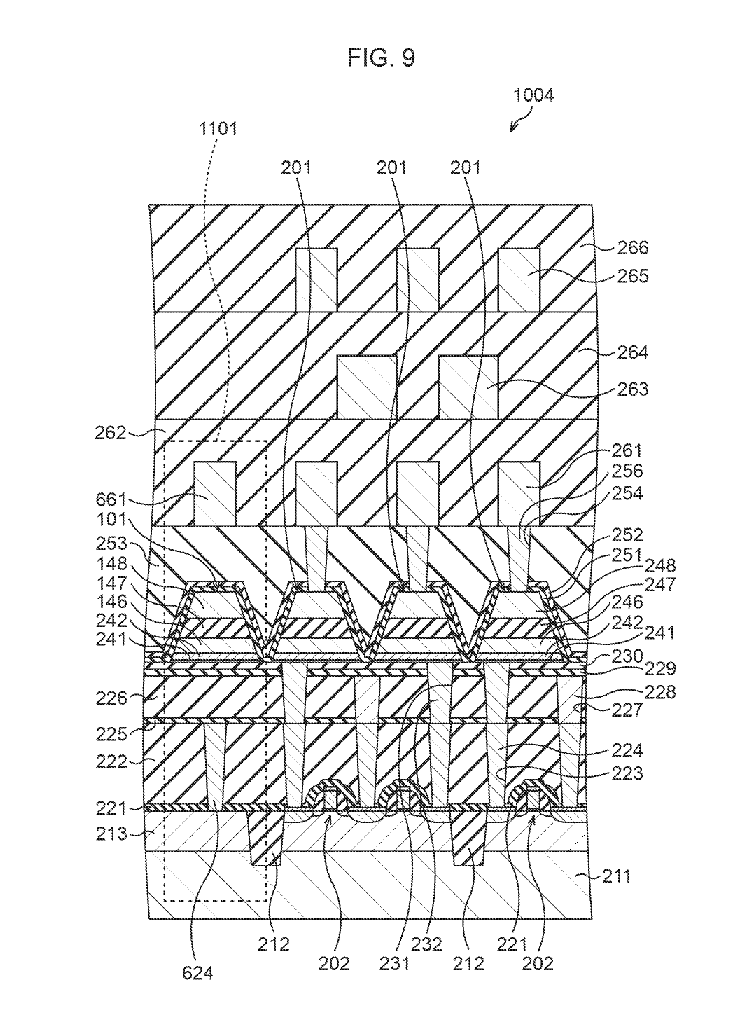

Next, a fourth embodiment will be explained. The fourth embodiment is an example of a ferroelectric memory. FIG. 9 is a cross-sectional view illustrating a structure of a semiconductor device according to the fourth embodiment. The layout and the circuit structure of the semiconductor device according to the fourth embodiment are similar to those of the first embodiment. FIG. 9 illustrates a cross section corresponding to the cross section taken along the line I-I in FIG. 1.

In a semiconductor device 1004 according to the fourth embodiment, as illustrated in FIG. 9, the guard ring 1101 includes a pseudo wiring 624 with an annular planar shape as well as the pseudo ferroelectric capacitor 101 and the pseudo wiring 661. The pseudo wiring 624 is formed in an annular opening formed in the interlayer insulating film 222 and the cover film 221, and has a width similar to the diameter of the conductive plug 224. The other structure is similar to the second embodiment (FIG. 7). The guard ring 1101 has a structure similar to that illustrated in FIG. 9 also in the cross section taken along a line II-II, the cross section taken along a line III-III, and the cross section taken along a line IV-IV in FIG. 1. The pseudo wiring 624 is an example of a fourth conductive pattern.

Effects similar to those of the second embodiment can be obtained by the semiconductor device 1004. The pseudo wiring 624 also contributes to suppression of intrusion of moisture and hydrogen. The pseudo wiring 624 may be formed contemporaneously with forming the conductive plugs 224.

### Fifth Embodiment

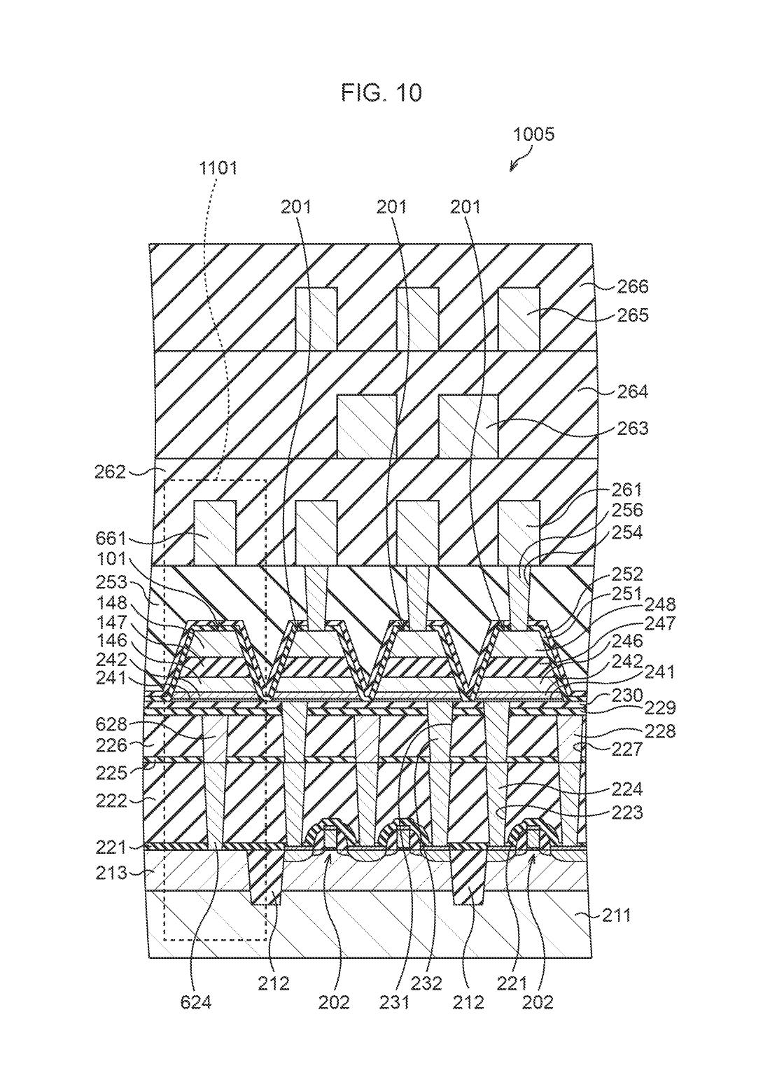

Next, a fifth embodiment will be explained. The fifth embodiment is an example of a ferroelectric memory. FIG. 10 is a cross-sectional view illustrating a structure of a semiconductor device according to the fifth embodiment. The layout and the circuit structure of the semiconductor device according to the fifth embodiment are similar to those of the first embodiment. FIG. 10 illustrates a cross section corresponding to the cross section taken along the line I-I in FIG. 1.

In a semiconductor device 1005 according to the fifth embodiment, as illustrated in FIG. 10, the guard ring 1101 includes a pseudo wiring 628 and a pseudo wiring 624 with an annular planar shape as well as the pseudo ferroelectric capacitor 101 and the pseudo wiring 661. The other structure is similar to the second embodiment (FIG. 7). The guard ring 1101 has a structure similar to that illustrated in FIG. 10 also in the cross section taken along a line II-II, the cross section taken along a line III-III, and the cross section taken along a line IV-IV in FIG. 1.

Effects similar to those of the second embodiment can be obtained by the semiconductor device 1005. The pseudo wiring 628 and the pseudo wiring 624 also contribute to suppression of intrusion of moisture and hydrogen.

### Sixth Embodiment

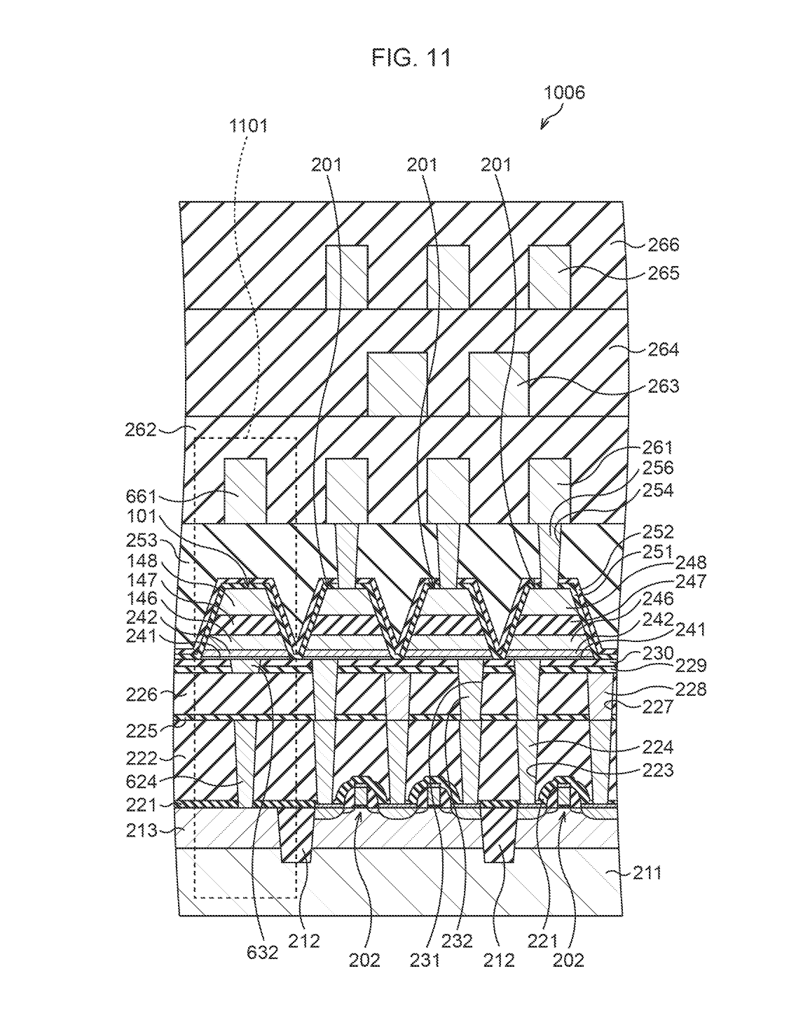

Next, a sixth embodiment will be explained. The sixth embodiment is an example of a ferroelectric memory. FIG. 11 is a cross-sectional view illustrating a structure of a semiconductor device according to the sixth embodiment. The layout and the circuit structure of the semiconductor device according to the sixth embodiment are similar to those of the first embodiment. FIG. 11 illustrates a cross section corresponding to the cross section taken along the line I-I in FIG. 1.

In a semiconductor device 1006 according to the sixth embodiment, as illustrated in FIG. 11, the guard ring 1101 includes a pseudo wiring 632 with an annular planar shape as well as the pseudo ferroelectric capacitor 101, the pseudo wiring 661 and the pseudo wiring 624. The pseudo wiring 632 is formed in an annular opening formed in the oxidation preventing film 229 and the buffer film 230, and has a width larger than the diameter of the conductive plug 232. The pseudo wiring 632 is in contact with a lower surface of the pseudo bottom electrode, if the aluminum titanium nitride film 242 and the titanium nitride film 241 are regarded as a part of the pseudo bottom electrode. The other structure is similar to the fourth embodiment (FIG. 9). The guard ring 1101 has a structure similar to that illustrated in FIG. 11 also in the cross section taken along a line II-II, the cross section taken along a line III-III, and the cross section taken along a line IV-IV in FIG. 1. The pseudo wiring 632 is an example of a fifth conductive pattern.

Effects similar to those of the fourth embodiment can be obtained by the semiconductor device 1006. The pseudo wiring 632 also contributes to suppression of intrusion of moisture and hydrogen. The pseudo wiring 632 may be formed by forming the opening for the pseudo wiring 632 in the buffer film 230 and the oxidation preventing film 229 while the contact hole 231 is formed, and forming and polishing of a conductive film contemporaneously forming the conductive plugs 232.

### Seventh Embodiment

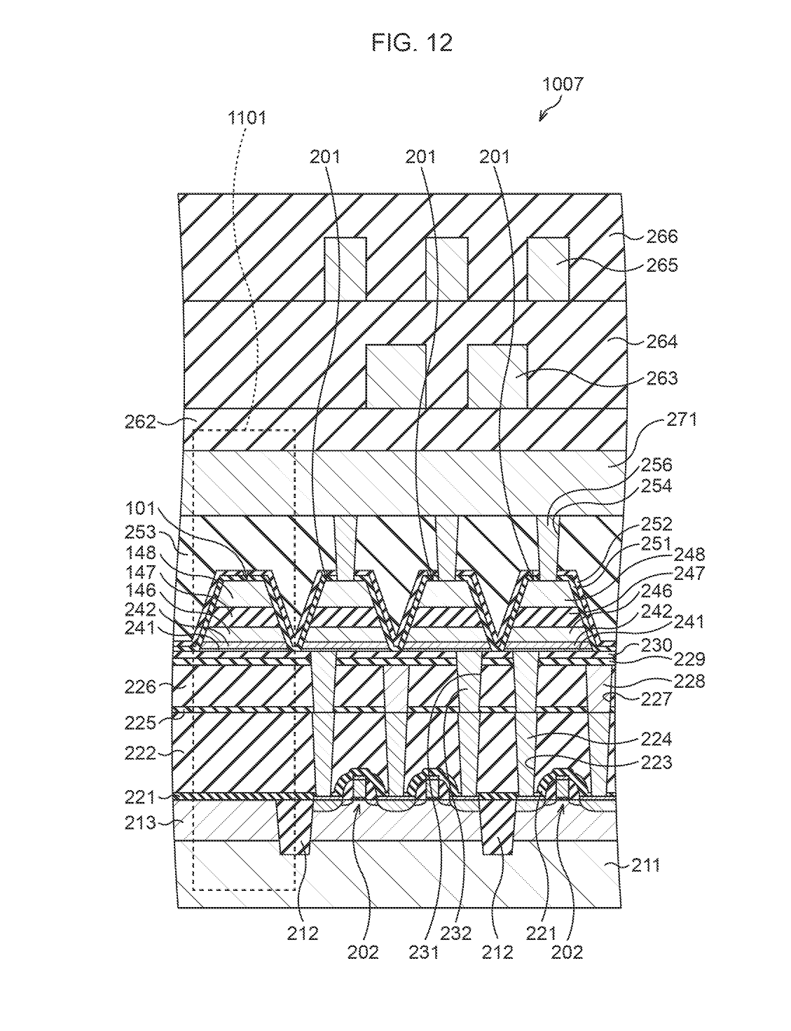

Next, a seventh embodiment will be explained. The seventh embodiment is an example of a ferroelectric memory. FIG. 12 is a cross-sectional view illustrating a structure of a semiconductor device according to the seventh embodiment. The layout and the circuit structure of the semiconductor device according to the seventh embodiment are similar to those of the first embodiment. FIG. 12 illustrates a cross section corresponding to the cross section taken along the line I-I in FIG. 1.

In a semiconductor device 1007 according to the seventh embodiment, as illustrated in FIG. 12, an integrated wiring 271 is provided instead of the wirings 261 which are divided in the first embodiment. Similarly to the wirings 261, the wiring 271 has a stacked structure similar to the conductive stack 440 illustrated in FIG. 6C, and functions as a part of the plate line 205. The wiring 271 is connected to a part selected from the plurality of ferroelectric capacitors 201 or all of the plurality of ferroelectric capacitors 201, and covers the selected plurality of ferroelectric capacitors 201 and regions between the selected ferroelectric capacitors 201 from above the top electrode 248. Here, two or more ferroelectric capacitors 201 connected to switching elements 202 which are switched on and off by word lines 203 different from each other are included in the selected plurality of ferroelectric capacitors 201, and two or more ferroelectric capacitors 201 connected to switching elements 202 which are connected to bit lines 204 different from each other are included in the selected plurality of ferroelectric capacitors 201. Therefore, the plurality of ferroelectric capacitors 201 connected to the wiring 271 and the regions between the plurality of ferroelectric capacitors 201 are in a contour of the wiring 271 in planar view. The wiring 271 is formed to extend into the guard ring 1101, and a part of the wiring 271 is included in the guard ring 1101. The other structure is similar to the first embodiment (FIG. 3A). The guard ring 1101 has a structure similar to that illustrated in FIG. 12 also in the cross section taken along a line II-II, the cross section taken along a line III-III, and the cross section taken along a line IV-IV in FIG. 1.

Effects similar to those of the first embodiment can be obtained by the semiconductor device 1007. The wiring 271 also contributes to suppression of intrusion of moisture and hydrogen from thereabove. Thus, a higher polarization charge amount can be obtained.

The COB structure is employed also in this embodiment. Because the COB structure is employed, a structure is quite effective, in which the wiring 271 as a part of the plate line 205 covers a predetermined plurality of ferroelectric capacitors 201 and regions between the ferroelectric capacitors 201 from above.

The number of ferroelectric capacitors 201 covered by the wiring 271 from above is not limited, but it is preferred that larger numbers of ferroelectric capacitors and regions between the ferroelectric capacitors 201 be covered by one wiring 271. That is, it is preferred that the number of wirings 271 included in one semiconductor device is small, and gaps between the wirings 271 are smaller.

It is not necessary for the wiring 271 to include a part in the guard ring 1101. For example, the guard ring 1101 may include a pseudo wiring 661 insulated from the wiring 271, and the guard ring 1101 need not include both of the pseudo wiring 661 and a part of the wiring 271. The seventh embodiment may also be regarded to have a structure such that a pseudo wiring above the pseudo ferroelectric capacitor 101 is connected to a wiring covering a plurality of ferroelectric capacitors 201 and regions between the ferroelectric capacitors 201 from above the top electrode 248.

The wiring 271 may be formed by changing the pattern of etching when the wirings 261 are formed.

### Eighth Embodiment

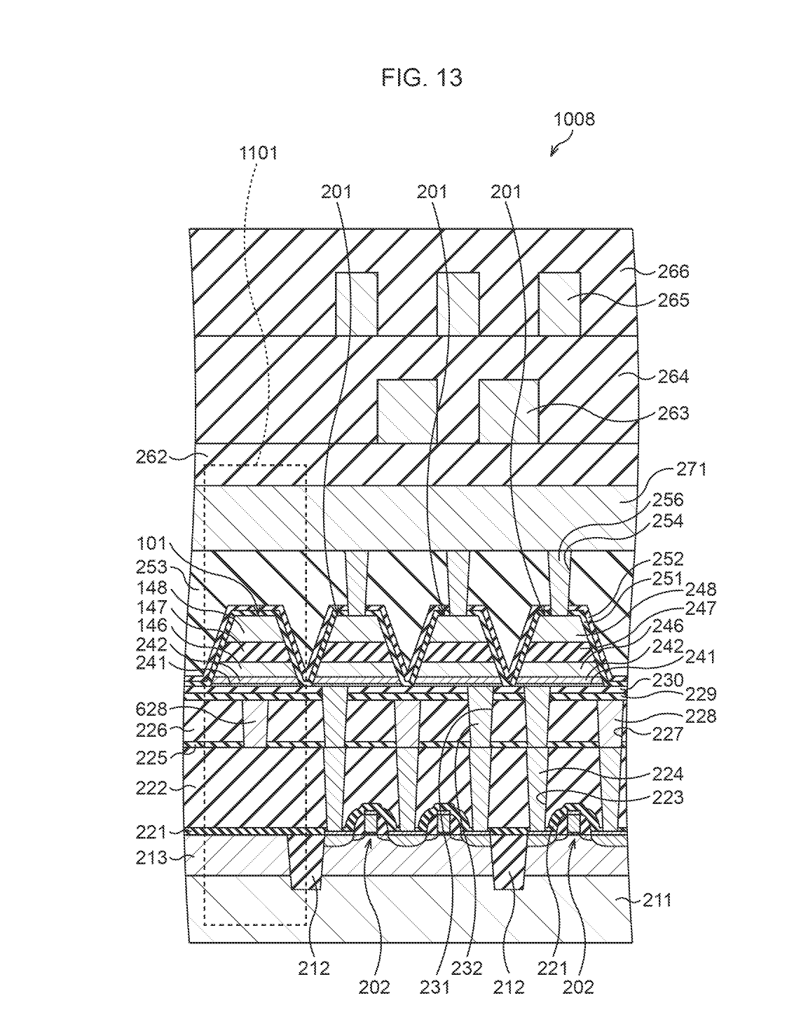

Next, an eighth embodiment will be explained. The eighth embodiment is an example of a ferroelectric memory. FIG. 13 is a cross-sectional view illustrating a structure of a semiconductor device according to the eighth embodiment. The layout and the circuit structure of the semiconductor device according to the eighth embodiment are similar to those of the first embodiment. FIG. 13 illustrates a cross section corresponding to the cross section taken along the line I-I in FIG. 1.

In a semiconductor device 1008 according to the eighth embodiment, as illustrated in FIG. 13, the guard ring 1101 includes a pseudo wiring 628 with an annular planar shape as well as the pseudo ferroelectric capacitor 101 and the part of the wiring 271. The other structure is similar to the seventh embodiment (FIG. 12). The guard ring 1101 has a structure similar to that illustrated in FIG. 13 also in the cross section taken along a line II-II, the cross section taken along a line III-III, and the cross section taken along a line IV-IV in FIG. 1.

Effects similar to those of the seventh embodiment can be obtained by the semiconductor device 1008. The pseudo wiring 628 also contributes to suppression of intrusion of moisture and hydrogen.

### Ninth Embodiment

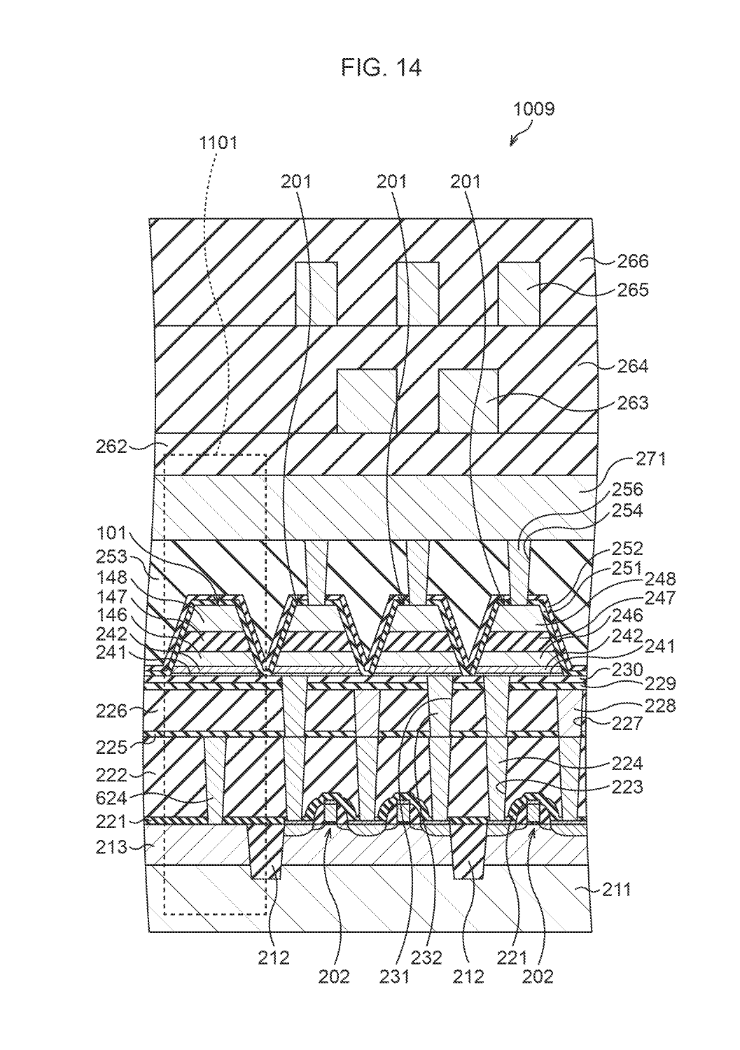

Next, a ninth embodiment will be explained. The ninth embodiment is an example of a ferroelectric memory. FIG. 14 is a cross-sectional view illustrating a structure of a semiconductor device according to the ninth embodiment. The layout and the circuit structure of the semiconductor device according to the ninth embodiment are similar to those of the first embodiment. FIG. 14 illustrates a cross section corresponding to the cross section taken along the line I-I in FIG. 1.

In a semiconductor device 1009 according to the ninth embodiment, as illustrated in FIG. 14, the guard ring 1101 includes a pseudo wiring 624 with an annular planar shape as well as the pseudo ferroelectric capacitor 101 and the part of the wiring 271. The other structure is similar to the seventh embodiment (FIG. 12). The guard ring 1101 has a structure similar to that illustrated in FIG. 14 also in the cross section taken along a line II-II, the cross section taken along a line III-III, and the cross section taken along a line IV-IV in FIG. 1.

Effects similar to those of the seventh embodiment can be obtained by the semiconductor device 1009. The pseudo wiring 624 also contributes to suppression of intrusion of moisture and hydrogen.

### Tenth Embodiment

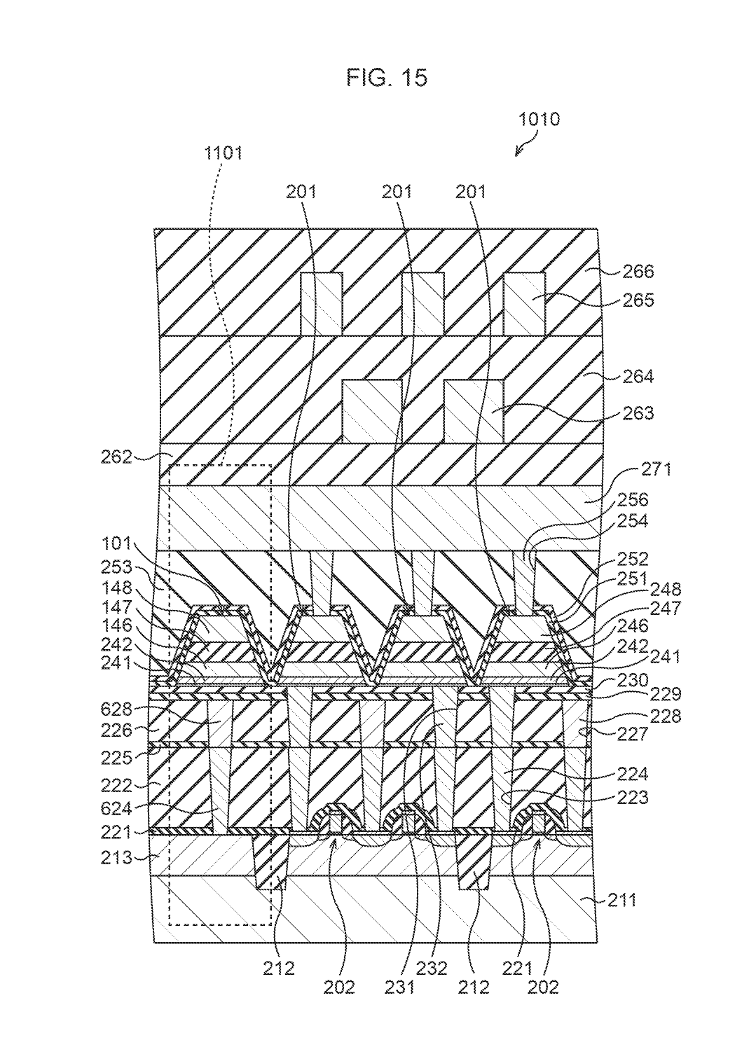

Next, a tenth embodiment will be explained. The tenth embodiment is an example of a ferroelectric memory. FIG. 15 is a cross-sectional view illustrating a structure of a semiconductor device according to the tenth embodiment. The layout and the circuit structure of the semiconductor device according to the tenth embodiment are similar to those of the first embodiment. FIG. 15 illustrates a cross section corresponding to the cross section taken along the line I-I in FIG. 1.

In a semiconductor device 1010 according to the tenth embodiment, as illustrated in FIG. 15, the guard ring 1101 includes a pseudo wiring 628 and a pseudo wiring 624 with an annular planar shape as well as the pseudo ferroelectric capacitor 101 and the part of the wiring 271. The other structure is similar to the seventh embodiment (FIG. 12). The guard ring 1101 has a structure similar to that illustrated in FIG. 15 also in the cross section taken along a line II-II, the cross section taken along a line III-III, and the cross section taken along a line IV-IV in FIG. 1.

Effects similar to those of the seventh embodiment can be obtained by the semiconductor device 1010. The pseudo wiring 628 and the pseudo wiring 624 also contribute to suppression of intrusion of moisture and hydrogen.

### Eleventh Embodiment

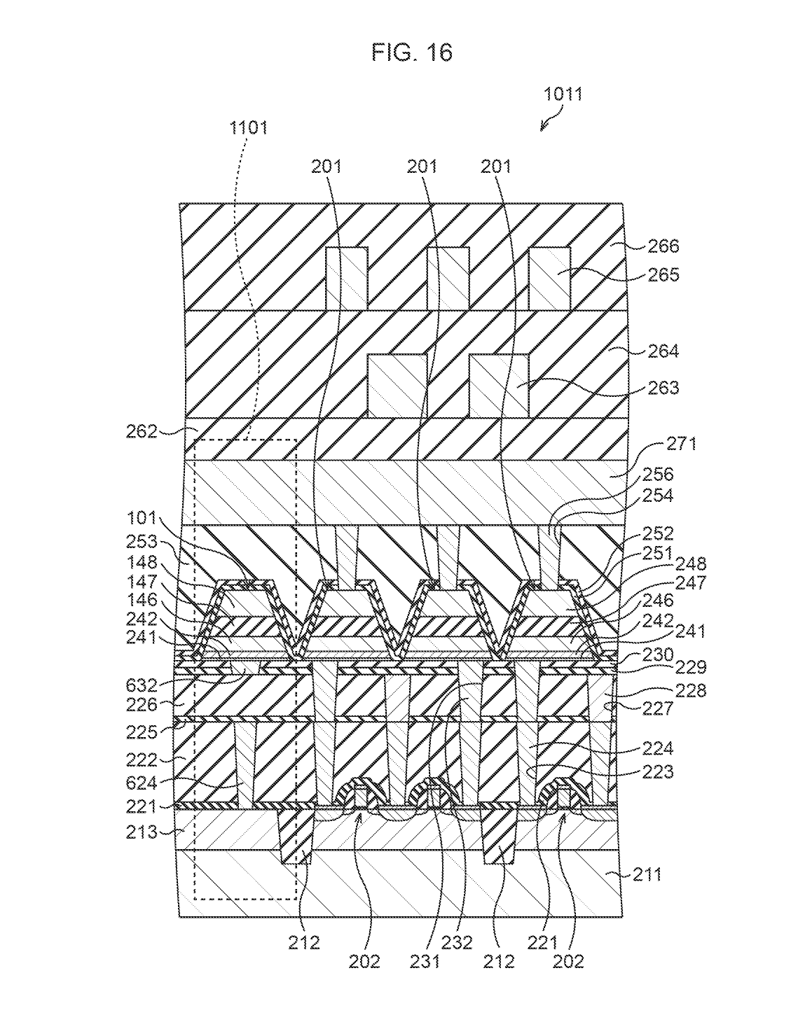

Next, an eleventh embodiment will be explained. The eleventh embodiment is an example of a ferroelectric memory. FIG. 16 is a cross-sectional view illustrating a structure of a semiconductor device according to the eleventh embodiment. The layout and the circuit structure of the semiconductor device according to the eleventh embodiment are similar to those of the first embodiment. FIG. 16 illustrates a cross section corresponding to the cross section taken along the line I-I in FIG. 1.

In a semiconductor device 1011 according to the eleventh embodiment, as illustrated in FIG. 16, the guard ring 1101 includes a pseudo wiring 632 with an annular planar shape as well as the pseudo ferroelectric capacitor 101, the part of the wiring 271 and the pseudo wiring 624. The other structure is similar to the ninth embodiment (FIG. 14). The guard ring 1101 has a structure similar to that illustrated in FIG. 16 also in the cross section taken along a line II-II, the cross section taken along a line III-III, and the cross section taken along a line IV-IV in FIG. 1.

Effects similar to those of the ninth embodiment can be obtained by the semiconductor device 1011. The pseudo wiring 632 also contributes to suppression of intrusion of moisture and hydrogen.

### Twelfth Embodiment

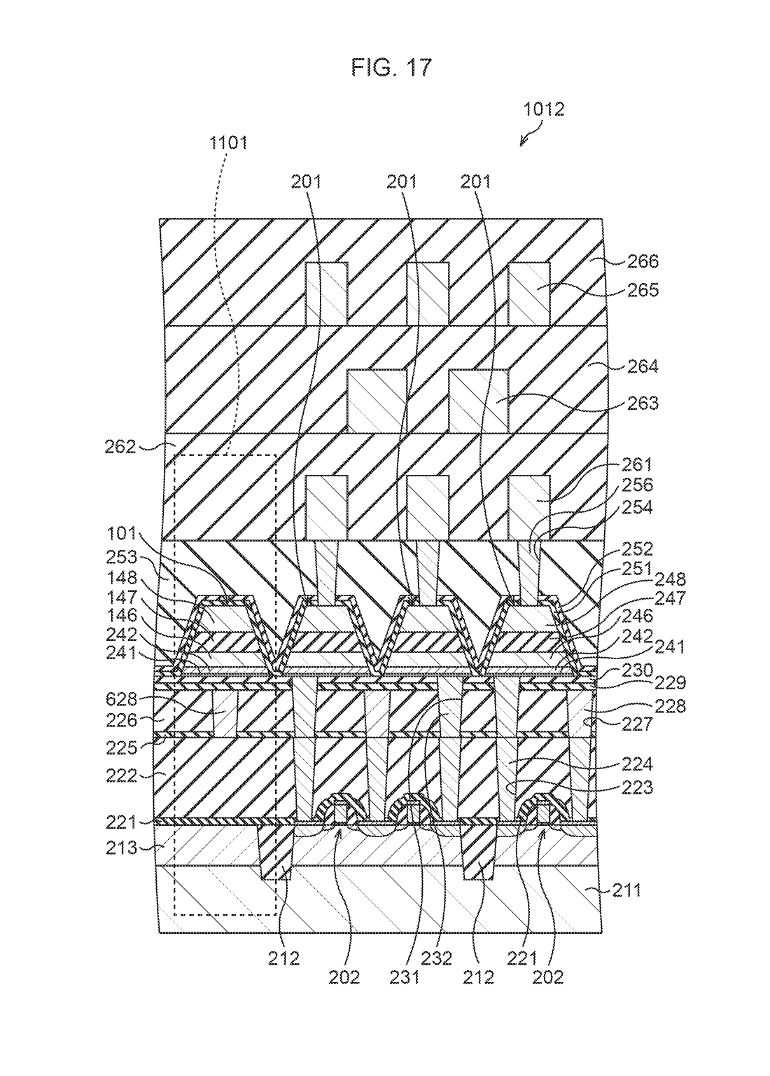

Next, a twelfth embodiment will be explained. The twelfth embodiment is an example of a ferroelectric memory. FIG. 17 is a cross-sectional view illustrating a structure of a semiconductor device according to the twelfth embodiment. The layout and the circuit structure of the semiconductor device according to the twelfth embodiment are similar to those of the first embodiment. FIG. 17 illustrates a cross section corresponding to the cross section taken along the line I-I in FIG. 1.

In a semiconductor device 1012 according to the twelfth embodiment, as illustrated in FIG. 17, the guard ring 1101 includes a pseudo wiring 628 with an annular planar shape as well as the pseudo ferroelectric capacitor 101. The other structure is similar to the first embodiment (FIG. 3A). The guard ring 1101 has a structure similar to that illustrated in FIG. 17 also in the cross section taken along a line II-II, the cross section taken along a line III-III, and the cross section taken along a line IV-IV in FIG. 1.

Effects similar to those of the first embodiment can be obtained by the semiconductor device 1012. The pseudo wiring 628 also contributes to suppression of intrusion of moisture and hydrogen.

### Thirteenth Embodiment

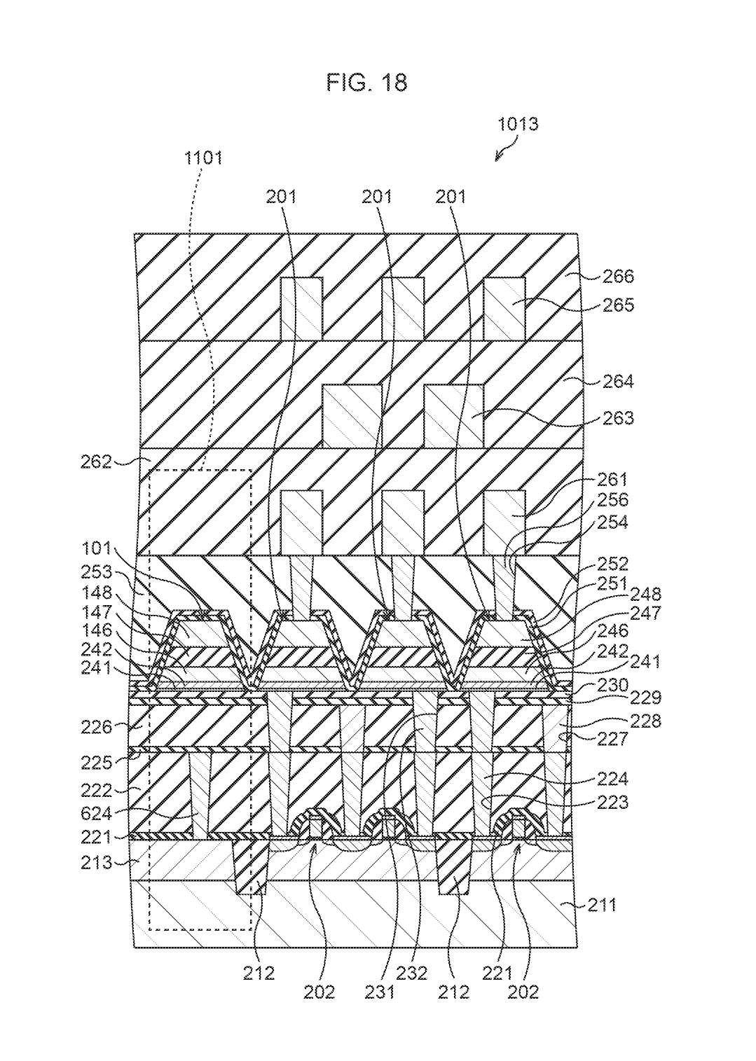

Next, a thirteenth embodiment will be explained. The thirteenth embodiment is an example of a ferroelectric memory. FIG. 18 is a cross-sectional view illustrating a structure of a semiconductor device according to the thirteenth embodiment. The layout and the circuit structure of the semiconductor device according to the thirteenth embodiment are similar to those of the first embodiment. FIG. 18 illustrates a cross section corresponding to the cross section taken along the line I-I in FIG. 1.

In a semiconductor device 1013 according to the thirteenth embodiment, as illustrated in FIG. 18, the guard ring 1101 includes a pseudo wiring 624 with an annular planar shape as well as the pseudo ferroelectric capacitor 101. The other structure is similar to the first embodiment (FIG. 3A). The guard ring 1101 has a structure similar to that illustrated in FIG. 18 also in the cross section taken along a line II-II, the cross section taken along a line III-III, and the cross section taken along a line IV-IV in FIG. 1.

Effects similar to those of the first embodiment can be obtained by the semiconductor device 1013. The pseudo wiring 624 also contributes to suppression of intrusion of moisture and hydrogen.

### Fourteenth Embodiment

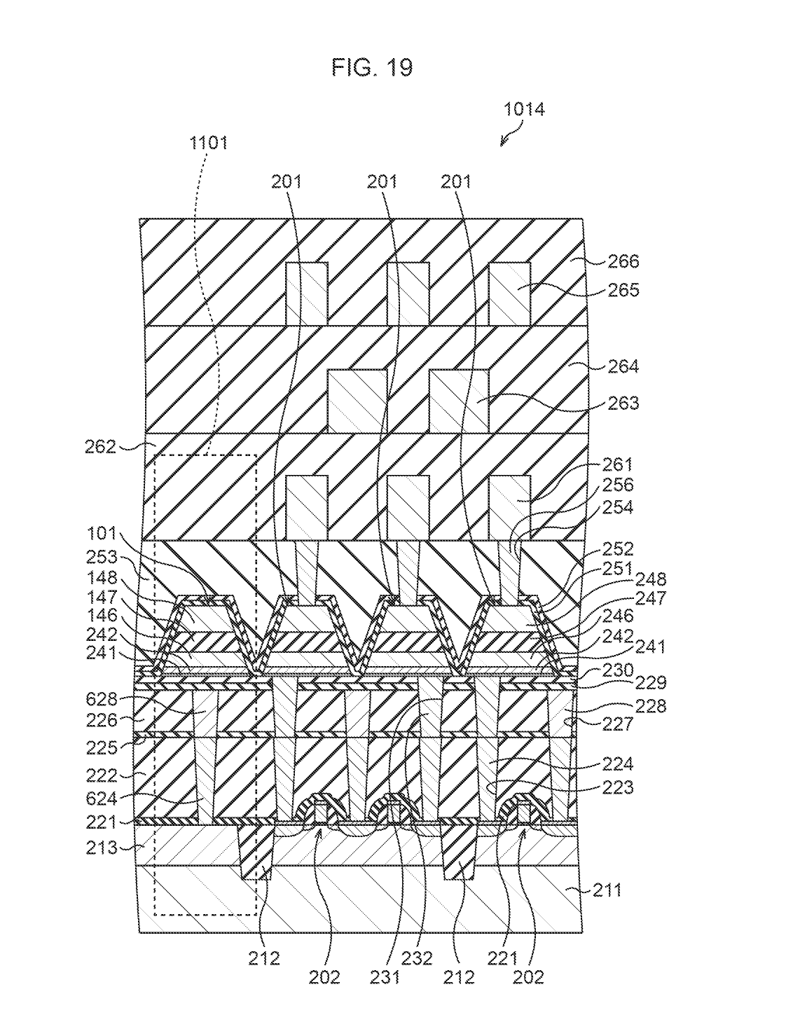

Next, a fourteenth embodiment will be explained. The fourteenth embodiment is an example of a ferroelectric memory. FIG. 19 is a cross-sectional view illustrating a structure of a semiconductor device according to the fourteenth embodiment. The layout and the circuit structure of the semiconductor device according to the fourteenth embodiment are similar to those of the first embodiment. FIG. 19 illustrates a cross section corresponding to the cross section taken along the line I-I in FIG. 1.

In a semiconductor device 1014 according to the fourteenth embodiment, as illustrated in FIG. 19, the guard ring 1101 includes a pseudo wiring 628 and a pseudo wiring 624 with an annular planar shape as well as the pseudo ferroelectric capacitor 101. The other structure is similar to the first embodiment (FIG. 3A). The guard ring 1101 has a structure similar to that illustrated in FIG. 19 also in the cross section taken along a line II-II, the cross section taken along a line III-III, and the cross section taken along a line IV-IV in FIG. 1.

Effects similar to those of the first embodiment can be obtained by the semiconductor device 1014. The pseudo wiring 628 and the pseudo wiring 624 also contribute to suppression of intrusion of moisture and hydrogen.

### Fifteenth Embodiment

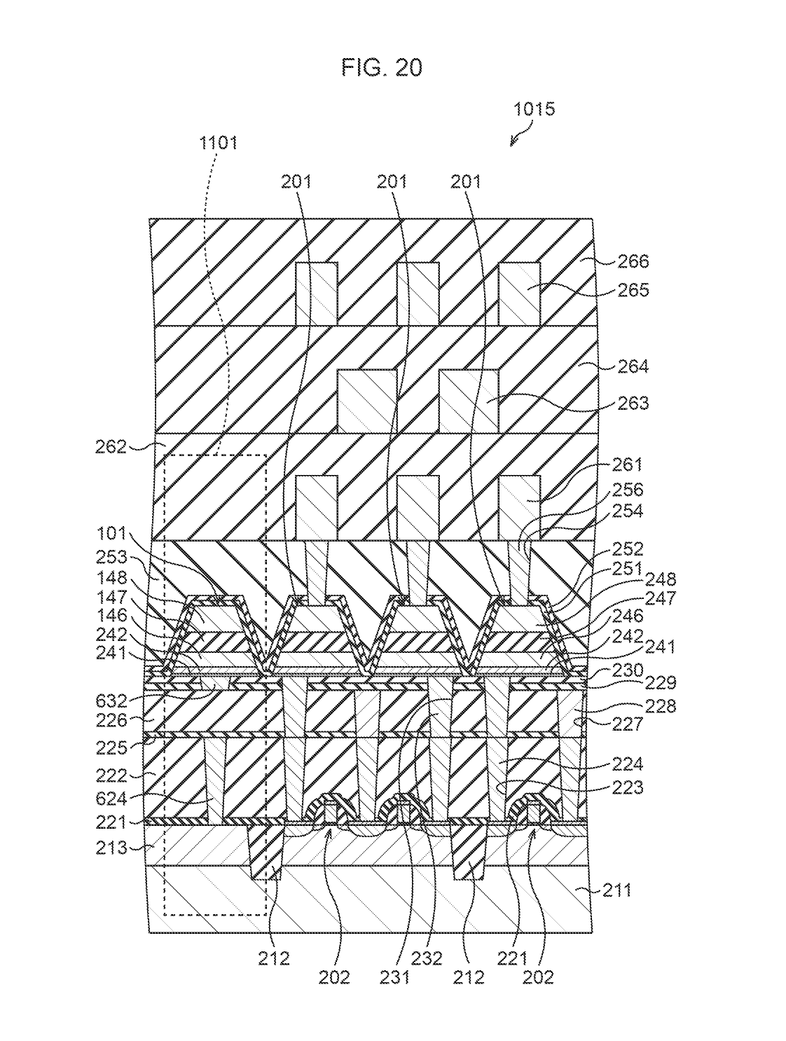

Next, a fifteenth embodiment will be explained. The fifteenth embodiment is an example of a ferroelectric memory. FIG. 20 is a cross-sectional view illustrating a structure of a semiconductor device according to the fifteenth embodiment. The layout and the circuit structure of the semiconductor device according to the fifteenth embodiment are similar to those of the first embodiment. FIG. 20 illustrates a cross section corresponding to the cross section taken along the line I-I in FIG. 1.

In a semiconductor device 1015 according to the fifteenth embodiment, as illustrated in FIG. 20, the guard ring 1101 includes a pseudo wiring 632 with an annular planar shape as well as the pseudo ferroelectric capacitor 101 and the pseudo wiring 624. The other structure is similar to the thirteenth embodiment (FIG. 18). The guard ring 1101 has a structure similar to that illustrated in FIG. 20 also in the cross section taken along a line II-II, the cross section taken along a line III-III, and the cross section taken along a line IV-IV in FIG. 1.

Effects similar to those of the thirteenth embodiment can be obtained by the semiconductor device 1015. The pseudo wiring 632 also contributes to suppression of intrusion of moisture and hydrogen.

### Sixteenth Embodiment

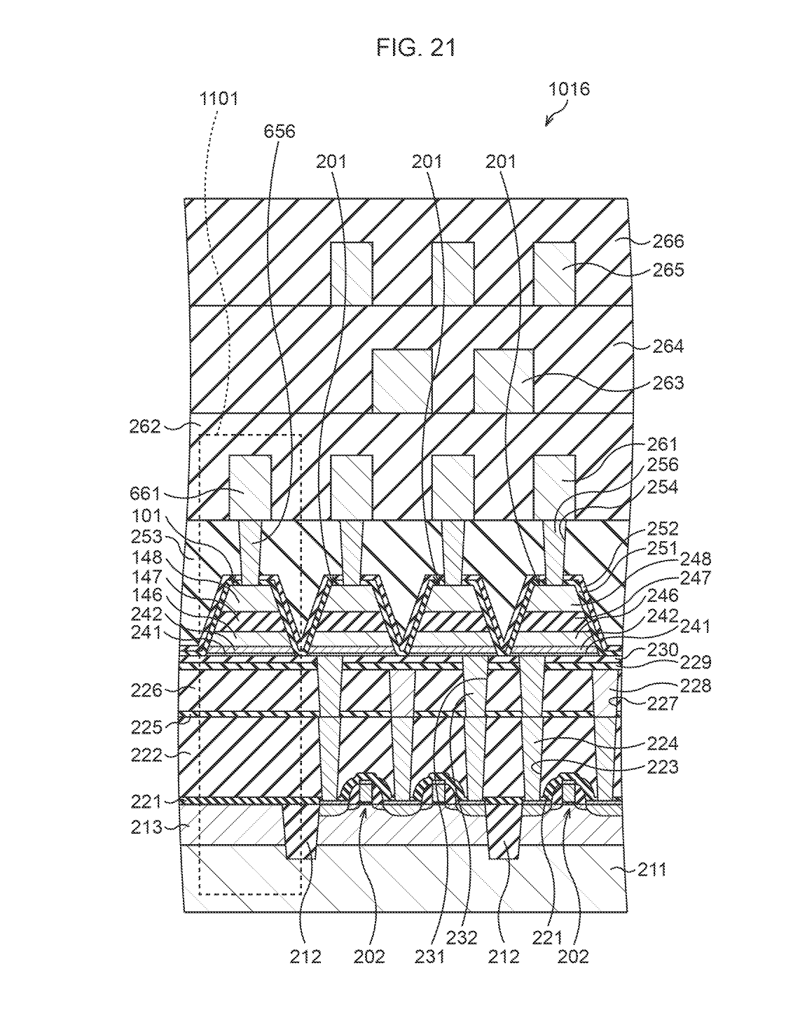

Next, a sixteenth embodiment will be explained. The sixteenth embodiment is an example of a ferroelectric memory. FIG. 21 is a cross-sectional view illustrating a structure of a semiconductor device according to the sixteenth embodiment. The layout and the circuit structure of the semiconductor device according to the sixteenth embodiment are similar to those of the first embodiment. FIG. 21 illustrates a cross section corresponding to the cross section taken along the line I-I in FIG. 1.

In a semiconductor device 1016 according to the sixteenth embodiment, as illustrated in FIG. 21, the guard ring 1101 includes a pseudo wiring 656 with an annular planar shape as well as the pseudo ferroelectric capacitor 101 and the pseudo wiring 661. The pseudo wiring 656 is formed in an annular opening formed in the interlayer insulating film 253, the protection film 252 and the protection film 251, and has a width larger than the diameter of the conductive plugs 256. The other structure is similar to the second embodiment (FIG. 7). The guard ring 1101 has a structure similar to that illustrated in FIG. 21 also in the cross section taken along a line II-II, the cross section taken along a line III-III, and the cross section taken along a line IV-IV in FIG. 1. The pseudo wiring 656 is an example of a second conductive pattern.

Effects similar to those of the second embodiment can be obtained by the semiconductor device 1016. The pseudo wiring 656 also contributes to suppression of intrusion of moisture and hydrogen. The pseudo wiring 656 may be formed contemporaneously with forming the conductive plugs 256. In this case, annealing is performed after formation of the opening for the pseudo wiring 656 and before formation of the conductive film for the pseudo wiring 656. Therefore, moisture and hydrogen diffusing from a portion more outside than this opening in the interlayer insulating film 253 toward the ferroelectric capacitors 201 during this annealing are discharged from this opening, and do not reach the ferroelectric capacitors 201. On the other hand, oxygen can be supplied to the ferroelectric capacitors 201 via this opening.

### Seventeenth Embodiment

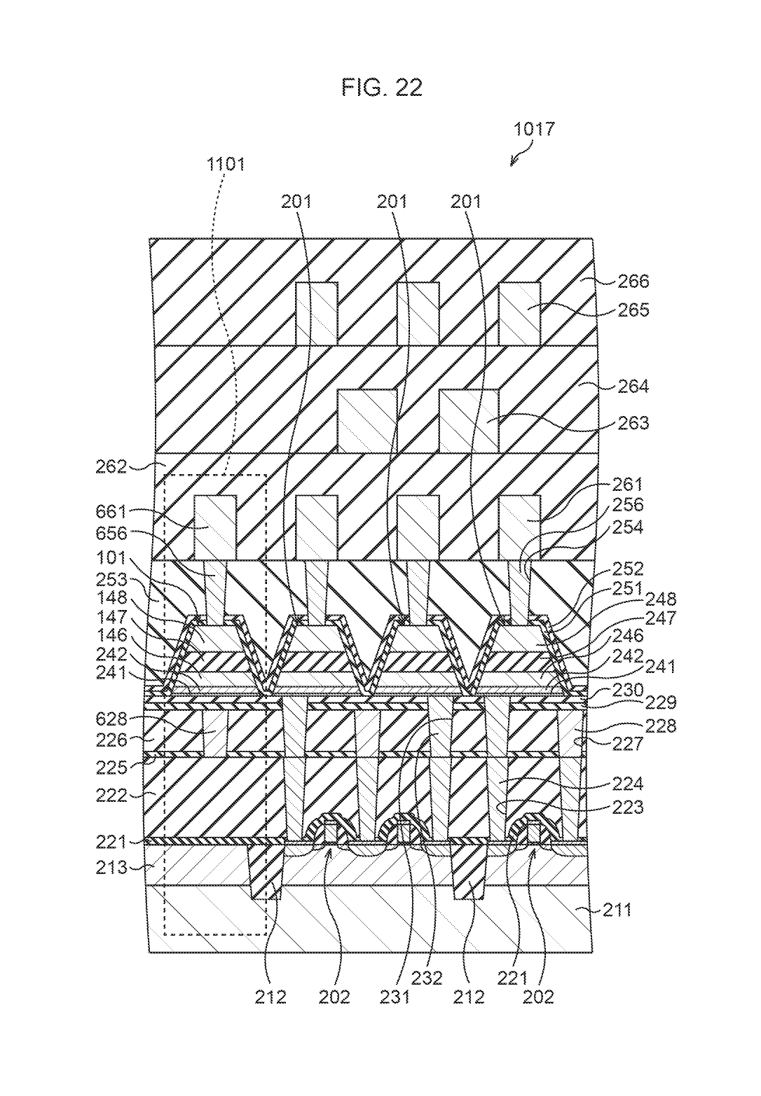

Next, a seventeenth embodiment will be explained. The seventeenth embodiment is an example of a ferroelectric memory. FIG. 22 is a cross-sectional view illustrating a structure of a semiconductor device according to the seventeenth embodiment. The layout and the circuit structure of the semiconductor device according to the seventeenth embodiment are similar to those of the first embodiment. FIG. 22 illustrates a cross section corresponding to the cross section taken along the line I-I in FIG. 1.

In a semiconductor device 1017 according to the seventeenth embodiment, as illustrated in FIG. 22, the guard ring 1101 includes a pseudo wiring 628 with an annular planar shape as well as the pseudo ferroelectric capacitor 101, the pseudo wiring 661 and the pseudo wiring 656. The other structure is similar to the sixteenth embodiment (FIG. 21). The guard ring 1101 has a structure similar to that illustrated in FIG. 22 also in the cross section taken along a line II-II, the cross section taken along a line III-III, and the cross section taken along a line IV-IV in FIG. 1.

Effects similar to those of the sixteenth embodiment can be obtained by the semiconductor device 1017. The pseudo wiring 628 also contributes to suppression of intrusion of moisture and hydrogen.

### Eighteenth Embodiment

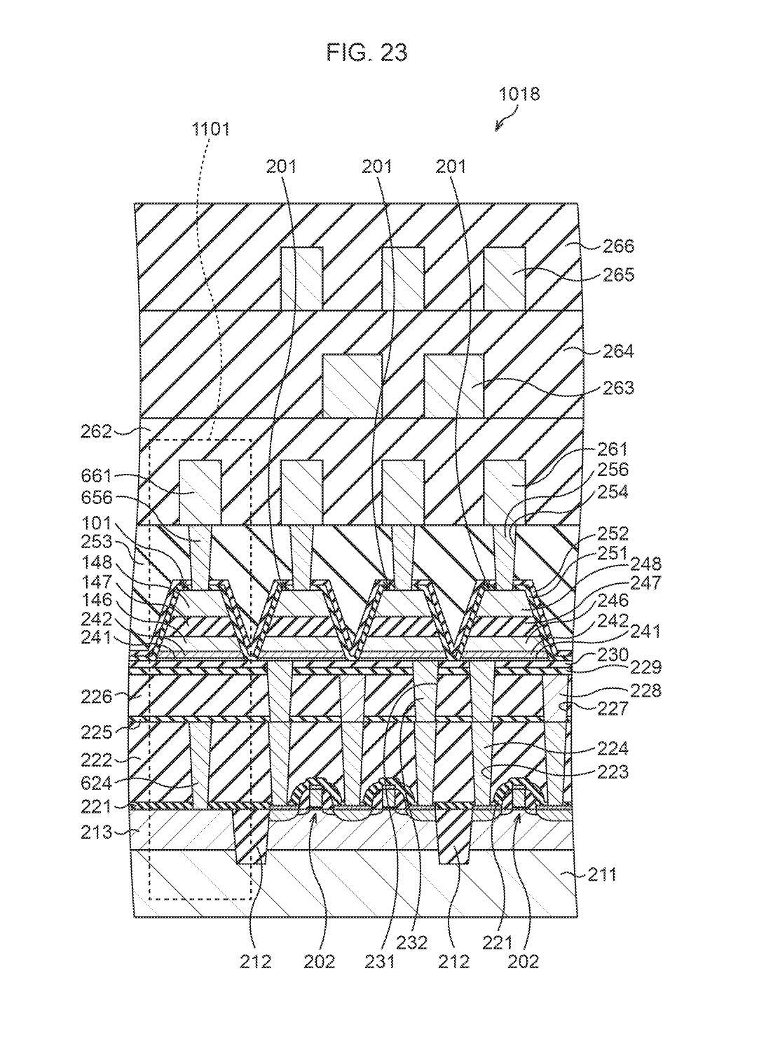

Next, an eighteenth embodiment will be explained. The eighteenth embodiment is an example of a ferroelectric memory. FIG. 23 is a cross-sectional view illustrating a structure of a semiconductor device according to the eighteenth embodiment. The layout and the circuit structure of the semiconductor device according to the eighteenth embodiment are similar to those of the first embodiment. FIG. 23 illustrates a cross section corresponding to the cross section taken along the line I-I in FIG. 1.

In a semiconductor device 1018 according to the eighteenth embodiment, as illustrated in FIG. 23, the guard ring 1101 includes a pseudo wiring 624 with an annular planar shape as well as the pseudo ferroelectric capacitor 101, the pseudo wiring 661 and the pseudo wiring 656. The other structure is similar to the sixteenth embodiment (FIG. 21). The guard ring 1101 has a structure similar to that illustrated in FIG. 23 also in the cross section taken along a line II-II, the cross section taken along a line III-III, and the cross section taken along a line IV-IV in FIG. 1.

Effects similar to those of the sixteenth embodiment can be obtained by the semiconductor device 1018. The pseudo wiring 624 also contributes to suppression of intrusion of moisture and hydrogen.

### Nineteenth Embodiment

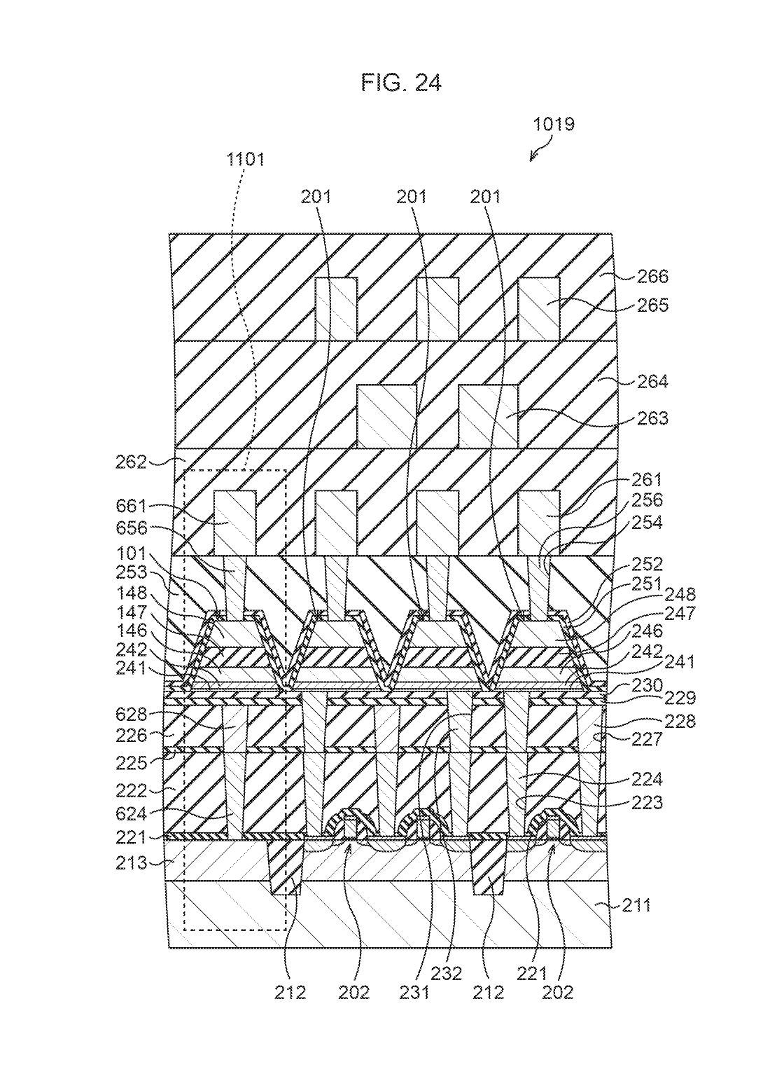

Next, a nineteenth embodiment will be explained. The nineteenth embodiment is an example of a ferroelectric memory. FIG. 24 is a cross-sectional view illustrating a structure of a semiconductor device according to the nineteenth embodiment. The layout and the circuit structure of the semiconductor device according to the nineteenth embodiment are similar to those of the first embodiment. FIG. 24 illustrates a cross section corresponding to the cross section taken along the line I-I in FIG. 1.

In a semiconductor device 1019 according to the nineteenth embodiment, as illustrated in FIG. 24, the guard ring 1101 includes a pseudo wiring 624 and a pseudo wiring 628 with an annular planar shape as well as the pseudo ferroelectric capacitor 101, the pseudo wiring 661 and the pseudo wiring 656. The other structure is similar to the sixteenth embodiment (FIG. 21). The guard ring 1101 has a structure similar to that illustrated in FIG. 24 also in the cross section taken along a line II-II, the cross section taken along a line III-III, and the cross section taken along a line IV-IV in FIG. 1.

Effects similar to those of the sixteenth embodiment can be obtained by the semiconductor device 1019. The pseudo wiring 628 and the pseudo wiring 624 also contribute to suppression of intrusion of moisture and hydrogen.

### Twentieth Embodiment

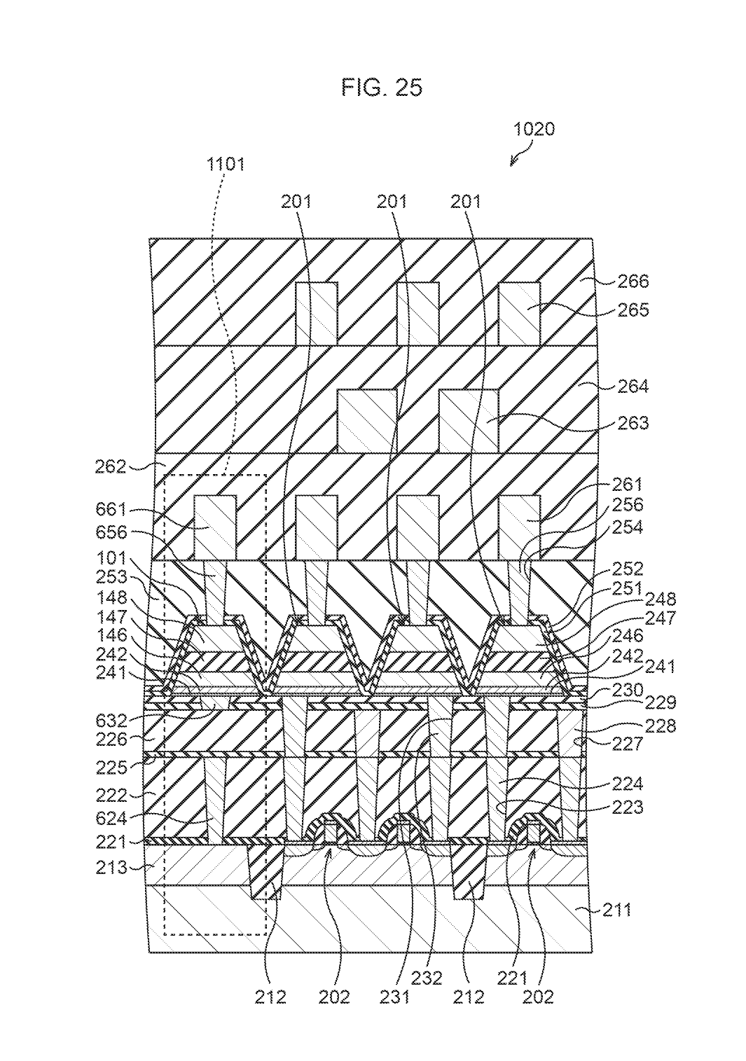

Next, a twentieth embodiment will be explained. The twentieth embodiment is an example of a ferroelectric memory. FIG. 25 is a cross-sectional view illustrating a structure of a semiconductor device according to the twentieth embodiment. The layout and the circuit structure of the semiconductor device according to the twentieth embodiment are similar to those of the first embodiment. FIG. 25 illustrates a cross section corresponding to the cross section taken along the line I-I in FIG. 1.

In a semiconductor device 1020 according to the twentieth embodiment, as illustrated in FIG. 25, the guard ring 1101 includes a pseudo wiring 632 with an annular planar shape as well as the pseudo ferroelectric capacitor 101, the pseudo wiring 661, the pseudo wiring 656 and the pseudo wiring 624. The other structure is similar to the eighteenth embodiment (FIG. 23). The guard ring 1101 has a structure similar to that illustrated in FIG. 25 also in the cross section taken along a line II-II, the cross section taken along a line III-III, and the cross section taken along a line IV-IV in FIG. 1.

Effects similar to those of the eighteenth embodiment can be obtained by the semiconductor device 1020. The pseudo wiring 632 also contributes to suppression of intrusion of moisture and hydrogen.

### Twenty-First Embodiment

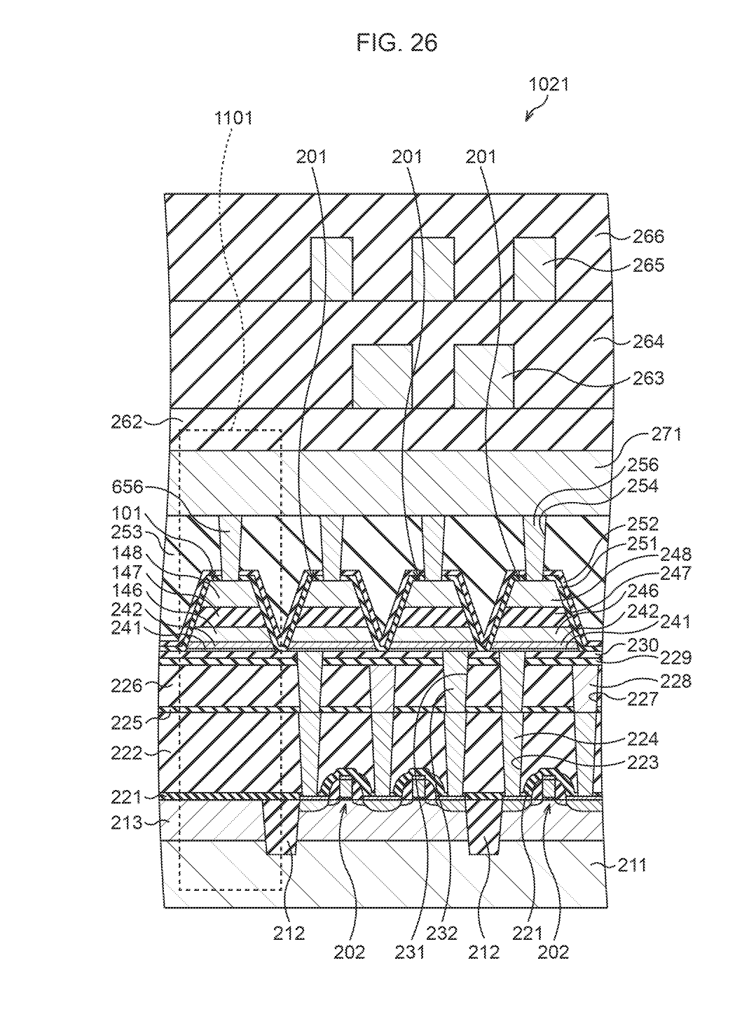

Next, a twenty-first embodiment will be explained. The twenty-first embodiment is an example of a ferroelectric memory. FIG. 26 is a cross-sectional view illustrating a structure of a semiconductor device according to the twenty-first embodiment. The layout and the circuit structure of the semiconductor device according to the twenty-first embodiment are similar to those of the first embodiment. FIG. 26 illustrates a cross section corresponding to the cross section taken along the line I-I in FIG. 1.

In a semiconductor device 1021 according to the twenty-first embodiment, as illustrated in FIG. 26, the guard ring 1101 includes a pseudo wiring 656 with an annular planar shape as well as the pseudo ferroelectric capacitor 101 and the part of the wiring 271. The other structure is similar to the seventh embodiment (FIG. 12). The guard ring 1101 has a structure similar to that illustrated in FIG. 26 also in the cross section taken along a line II-II, the cross section taken along a line III-III, and the cross section taken along a line IV-IV in FIG. 1.

Effects similar to those of the seventh embodiment can be obtained by the semiconductor device 1021. The pseudo wiring 656 also contributes to suppression of intrusion of moisture and hydrogen.

### Twenty-Second Embodiment

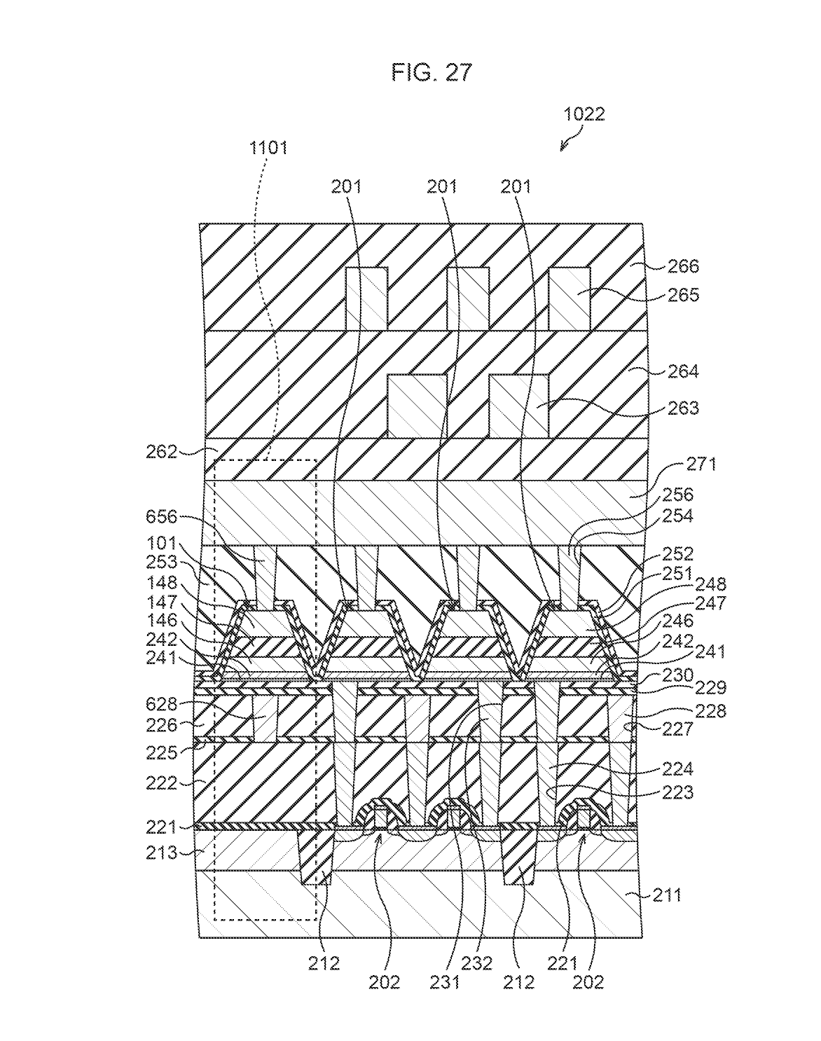

Next, a twenty-second embodiment will be explained. The twenty-second embodiment is an example of a ferroelectric memory. FIG. 27 is a cross-sectional view illustrating a structure of a semiconductor device according to the twenty-second embodiment. The layout and the circuit structure of the semiconductor device according to the twenty-second embodiment are similar to those of the first embodiment. FIG. 27 illustrates a cross section corresponding to the cross section taken along the line I-I in FIG. 1.

In a semiconductor device 1022 according to the twenty-second embodiment, as illustrated in FIG. 27, the guard ring 1101 includes a pseudo wiring 628 with an annular planar shape as well as the pseudo ferroelectric capacitor 101, the part of the wiring 271 and the pseudo wiring 656. The other structure is similar to the twenty-first embodiment (FIG. 26). The guard ring 1101 has a structure similar to that illustrated in FIG. 27 also in the cross section taken along a line II-II, the cross section taken along a line III-III, and the cross section taken along a line IV-IV in FIG. 1.

Effects similar to those of the twenty-first embodiment can be obtained by the semiconductor device 1022. The pseudo wiring 628 also contributes to suppression of intrusion of moisture and hydrogen.

### Twenty-Third Embodiment

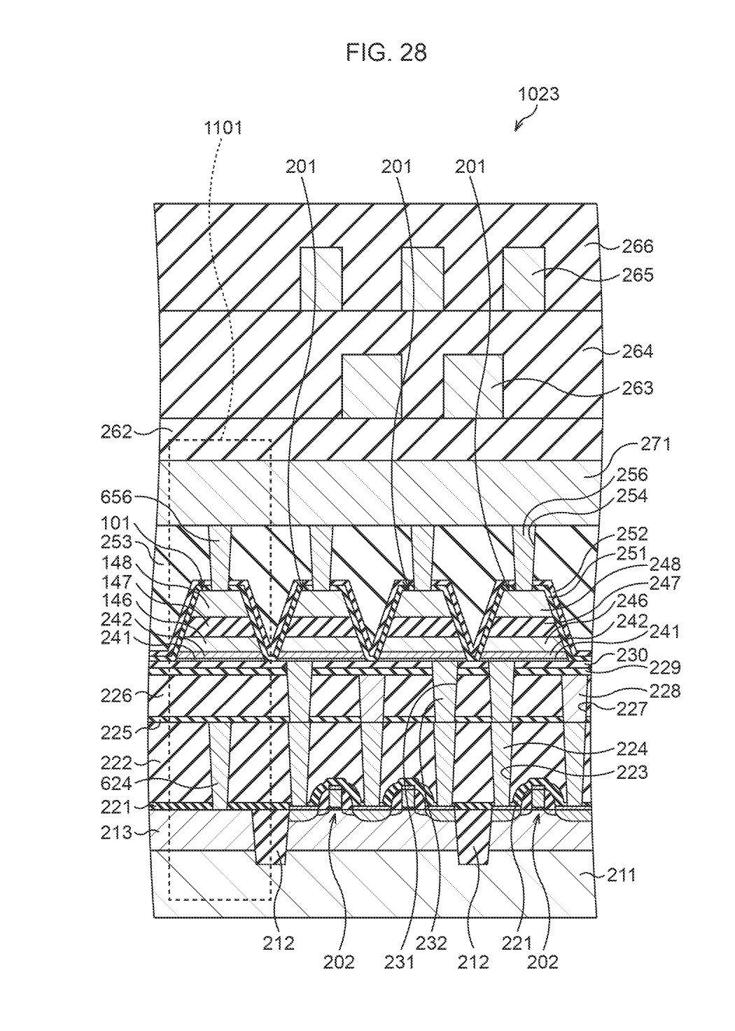

Next, a twenty-third embodiment will be explained. The twenty-third embodiment is an example of a ferroelectric memory. FIG. 28 is a cross-sectional view illustrating a structure of a semiconductor device according to the twenty-third embodiment. The layout and the circuit structure of the semiconductor device according to the twenty-third embodiment are similar to those of the first embodiment. FIG. 28 illustrates a cross section corresponding to the cross section taken along the line I-I in FIG. 1.

In a semiconductor device 1023 according to the twenty-third embodiment, as illustrated in FIG. 28, the guard ring 1101 includes a pseudo wiring 624 with an annular planar shape as well as the pseudo ferroelectric capacitor 101, the part of the wiring 271 and the pseudo wiring 656. The other structure is similar to the twenty-first embodiment (FIG. 26). The guard ring 1101 has a structure similar to that illustrated in FIG. 28 also in the cross section taken along a line II-II, the cross section taken along a line III-III, and the cross section taken along a line IV-IV in FIG. 1.

Effects similar to those of the twenty-first embodiment can be obtained by the semiconductor device 1023. The pseudo wiring 624 also contributes to suppression of intrusion of moisture and hydrogen.

### Twenty-Fourth Embodiment

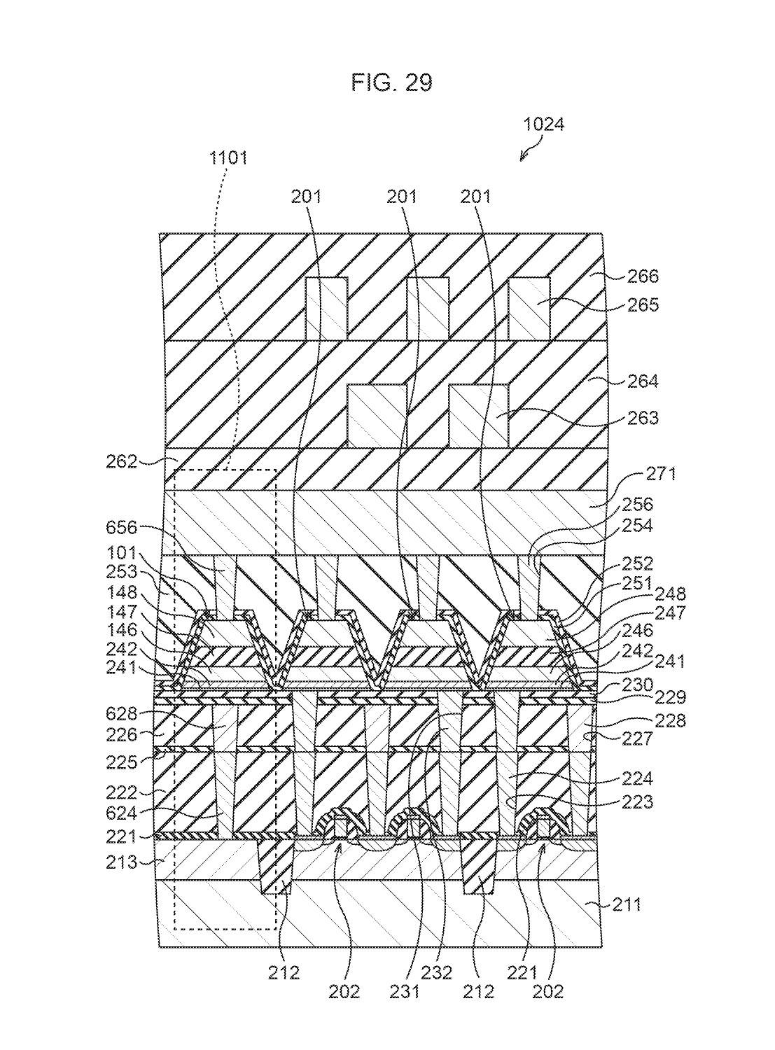

Next, a twenty-fourth embodiment will be explained. The twenty-fourth embodiment is an example of a ferroelectric memory. FIG. 29 is a cross-sectional view illustrating a structure of a semiconductor device according to the twenty-fourth embodiment. The layout and the circuit structure of the semiconductor device according to the twenty-fourth embodiment are similar to those of the first embodiment. FIG. 29 illustrates a cross section corresponding to the cross section taken along the line I-I in FIG. 1.

In a semiconductor device 1024 according to the twenty-fourth embodiment, as illustrated in FIG. 29, the guard ring 1101 includes a pseudo wiring 628 and a pseudo wiring 624 with an annular planar shape as well as the pseudo ferroelectric capacitor 101, the part of the wiring 271 and the pseudo wiring 656. The other structure is similar to the twenty-first embodiment (FIG. 26). The guard ring 1101 has a structure similar to that illustrated in FIG. 29 also in the cross section taken along a line II-II, the cross section taken along a line III-III, and the cross section taken along a line IV-IV in FIG. 1.

Effects similar to those of the twenty-first embodiment can be obtained by the semiconductor device 1024. The pseudo wiring 628 and the pseudo wiring 624 also contribute to suppression of intrusion of moisture and hydrogen.

### Twenty-Fifth Embodiment

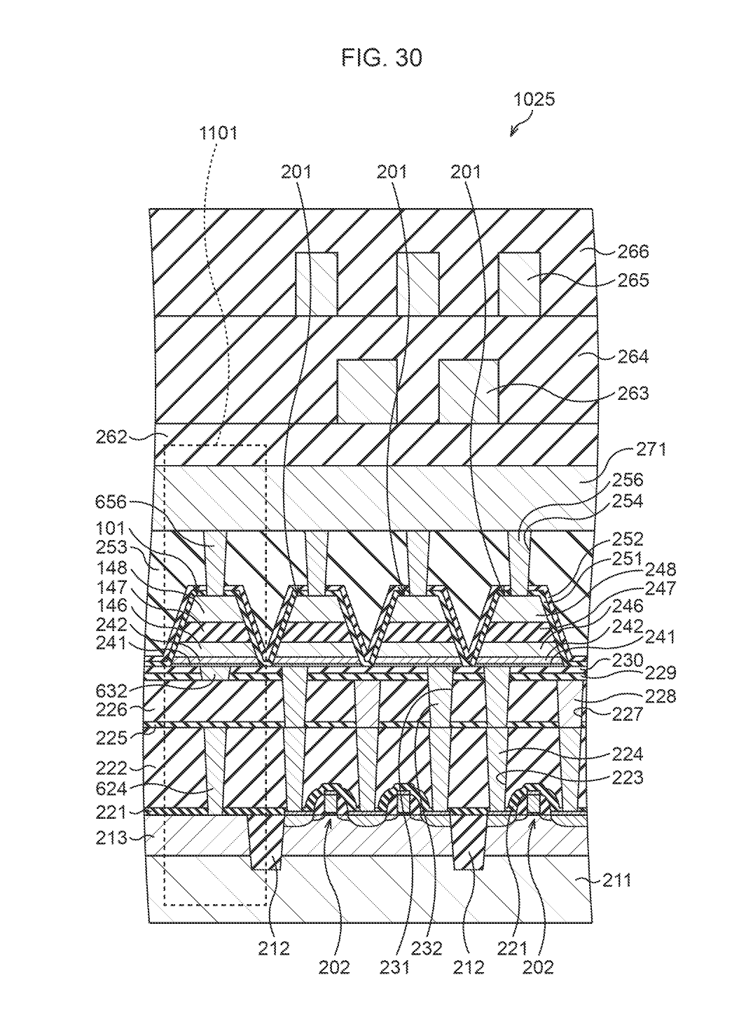

Next, a twenty-fifth embodiment will be explained. The twenty-fifth embodiment is an example of a ferroelectric memory. FIG. 30 is a cross-sectional view illustrating a structure of a semiconductor device according to the twenty-fifth embodiment. The layout and the circuit structure of the semiconductor device according to the twenty-fifth embodiment are similar to those of the first embodiment. FIG. 30 illustrates a cross section corresponding to the cross section taken along the line I-I in FIG. 1.

In a semiconductor device 1025 according to the twenty-fifth embodiment, as illustrated in FIG. 30, the guard ring 1101 includes a pseudo wiring 632 with an annular planar shape as well as the pseudo ferroelectric capacitor 101, the part of the wiring 271, the pseudo wiring 656 and the pseudo wiring 624. The other structure is similar to the twenty-third embodiment (FIG. 28). The guard ring 1101 has a structure similar to that illustrated in FIG. 30 also in the cross section taken along a line II-II, the cross section taken along a line III-III, and the cross section taken along a line IV-IV in FIG. 1.

Effects similar to those of the twenty-third embodiment can be obtained by the semiconductor device 1025. The pseudo wiring 632 also contributes to suppression of intrusion of moisture and hydrogen.

### Twenty-Sixth Embodiment

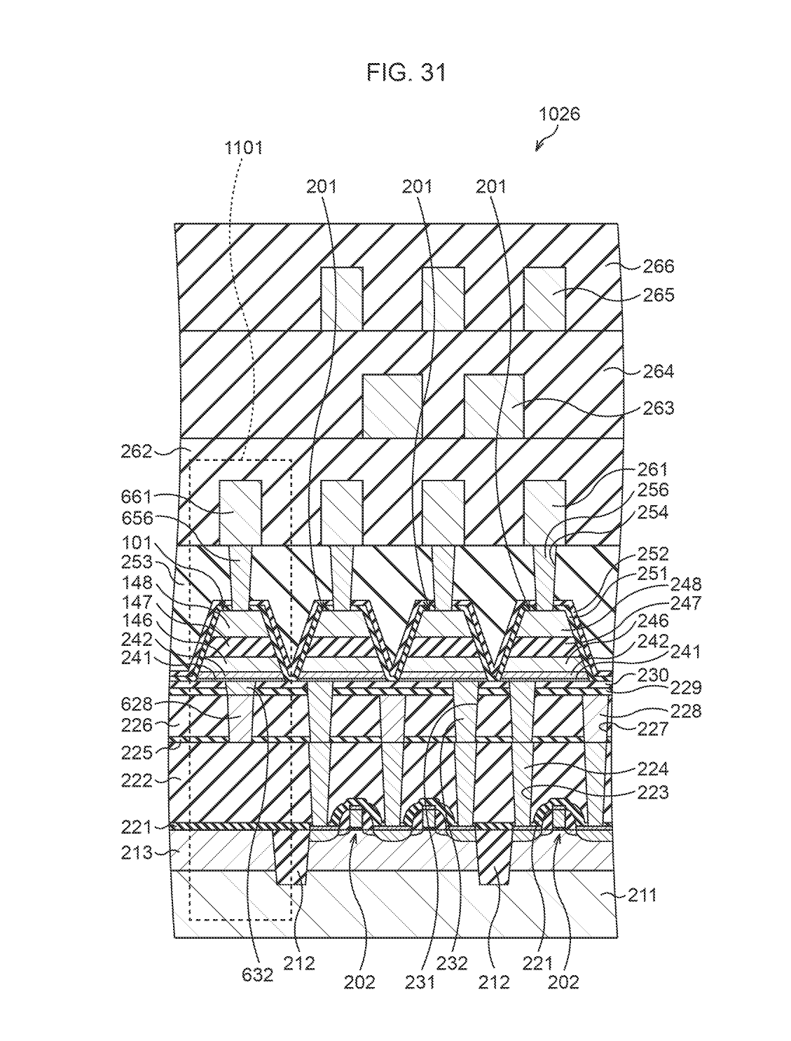

Next, a twenty-sixth embodiment will be explained. The twenty-sixth embodiment is an example of a ferroelectric memory. FIG. 31 is a cross-sectional view illustrating a structure of a semiconductor device according to the twenty-sixth embodiment. The layout and the circuit structure of the semiconductor device according to the twenty-sixth embodiment are similar to those of the first embodiment. FIG. 31 illustrates a cross section corresponding to the cross section taken along the line I-I in FIG. 1.

In a semiconductor device 1026 according to the twenty-sixth embodiment, as illustrated in FIG. 31, the guard ring 1101 includes a pseudo wiring 632 with an annular planar shape as well as the pseudo ferroelectric capacitor 101, the pseudo wiring 661, the pseudo wiring 656 and the pseudo wiring 628. The other structure is similar to the seventeenth embodiment (FIG. 22). The guard ring 1101 has a structure similar to that illustrated in FIG. 31 also in the cross section taken along a line II-II, the cross section taken along a line III-III, and the cross section taken along a line IV-IV in FIG. 1.

Effects similar to those of the seventeenth embodiment can be obtained by the semiconductor device 1026. The pseudo wiring 632 also contributes to suppression of intrusion of moisture and hydrogen.

### Twenty-Seventh Embodiment

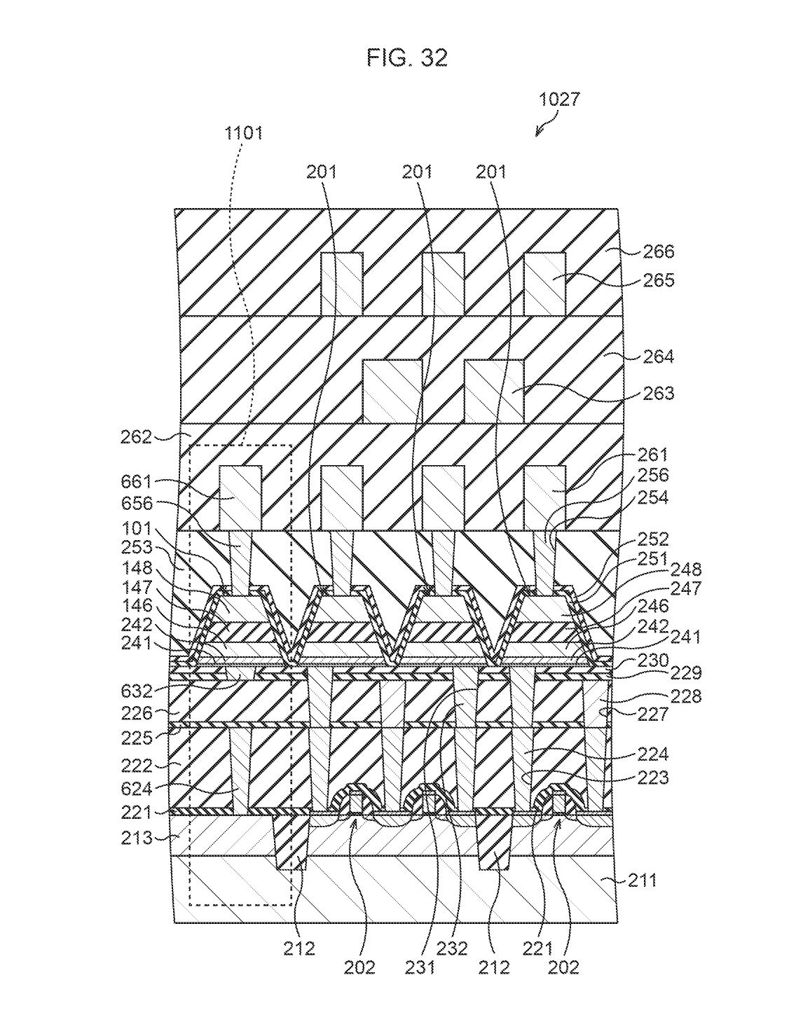

Next, a twenty-seventh embodiment will be explained. The twenty-seventh embodiment is an example of a ferroelectric memory. FIG. 32 is a cross-sectional view illustrating a structure of a semiconductor device according to the twenty-seventh embodiment. The layout and the circuit structure of the semiconductor device according to the twenty-seventh embodiment are similar to those of the first embodiment. FIG. 32 illustrates a cross section corresponding to the cross section taken along the line I-I in FIG. 1.

In a semiconductor device 1027 according to the twenty-seventh embodiment, as illustrated in FIG. 32, the guard ring 1101 includes a pseudo wiring 632 with an annular planar shape as well as the pseudo ferroelectric capacitor 101, the pseudo wiring 661, the pseudo wiring 656, the pseudo wiring 628 and the pseudo wiring 624. The other structure is similar to the eighteenth embodiment (FIG. 23). The guard ring 1101 has a structure similar to that illustrated in FIG. 32 also in the cross section taken along a line II-II, the cross section taken along a line III-III, and the cross section taken along a line IV-IV in FIG. 1.

Effects similar to those of the eighteenth embodiment can be obtained by the semiconductor device 1027. The pseudo wiring 632 also contributes to suppression of intrusion of moisture and hydrogen.

### Twenty-Eighth Embodiment

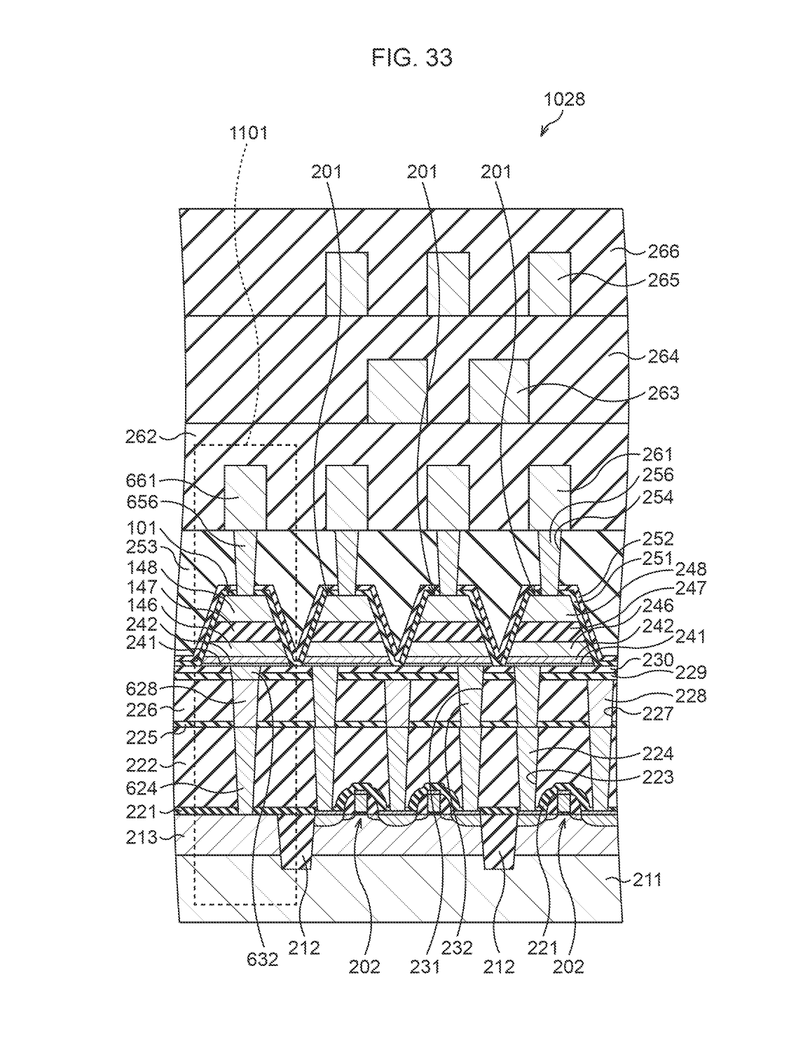

Next, a twenty-eighth embodiment will be explained. The twenty-eighth embodiment is an example of a ferroelectric memory. FIG. 33 is a cross-sectional view illustrating a structure of a semiconductor device according to the twenty-eighth embodiment. The layout and the circuit structure of the semiconductor device according to the twenty-eighth embodiment are similar to those of the first embodiment. FIG. 33 illustrates a cross section corresponding to the cross section taken along the line I-I in FIG. 1.

In a semiconductor device 1028 according to the twenty-eighth embodiment, as illustrated in FIG. 33, the guard ring 1101 includes a pseudo wiring 632 with an annular planar shape as well as the pseudo ferroelectric capacitor 101, the pseudo wiring 661, the pseudo wiring 656, the pseudo wiring 628 and the pseudo wiring 624. The other structure is similar to the nineteenth embodiment (FIG. 24). The guard ring 1101 has a structure similar to that illustrated in FIG. 33 also in the cross section taken along a line II-II, the cross section taken along a line III-III, and the cross section taken along a line IV-IV in FIG. 1.

Effects similar to those of the nineteenth embodiment can be obtained by the semiconductor device 1028. The pseudo wiring 632 also contributes to suppression of intrusion of moisture and hydrogen.

### Twenty-Ninth Embodiment

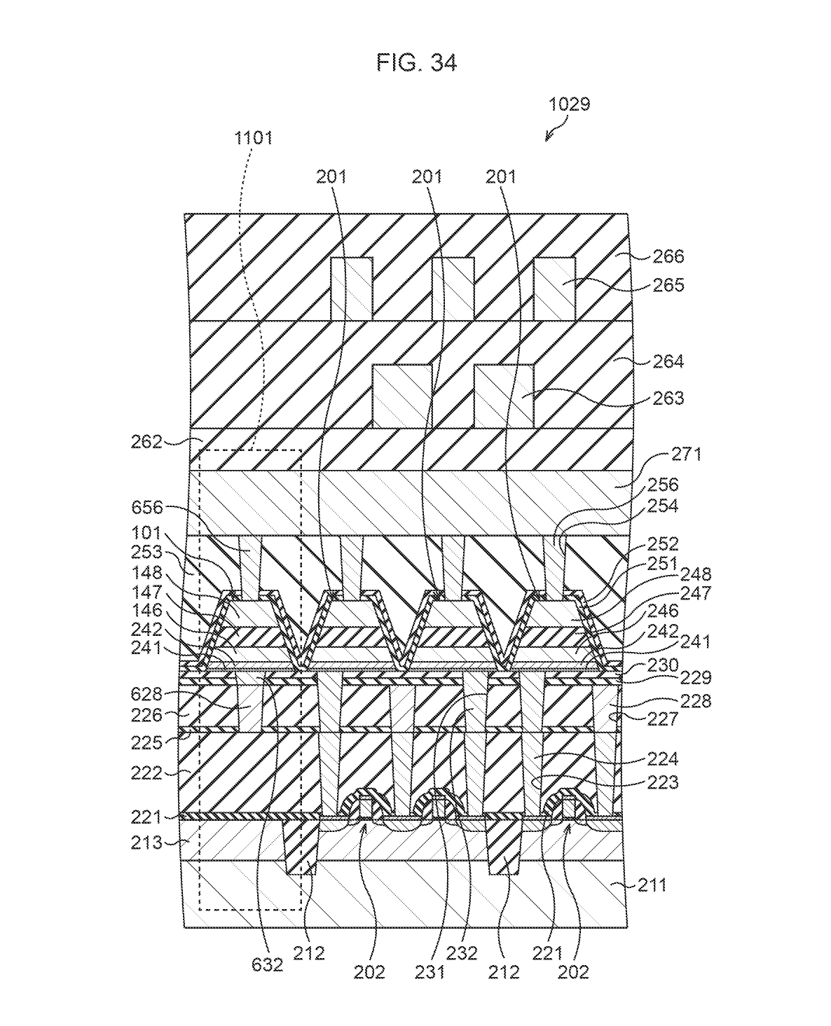

Next, a twenty-ninth embodiment will be explained. The twenty-ninth embodiment is an example of a ferroelectric memory. FIG. 34 is a cross-sectional view illustrating a structure of a semiconductor device according to the twenty-ninth embodiment. The layout and the circuit structure of the semiconductor device according to the twenty-ninth embodiment are similar to those of the first embodiment. FIG. 34 illustrates a cross section corresponding to the cross section taken along the line I-I in FIG. 1.

In a semiconductor device 1029 according to the twenty-ninth embodiment, as illustrated in FIG. 34, the guard ring 1101 includes a pseudo wiring 632 with an annular planar shape as well as the pseudo ferroelectric capacitor 101, the part of the wiring 271, the pseudo wiring 656 and the pseudo wiring 628. The other structure is similar to the twenty-second embodiment (FIG. 27). The guard ring 1101 has a structure similar to that illustrated in FIG. 34 also in the cross section taken along a line II-II, the cross section taken along a line III-III, and the cross section taken along a line IV-IV in FIG. 1.

Effects similar to those of the twenty-second embodiment can be obtained by the semiconductor device 1029. The pseudo wiring 632 also contributes to suppression of intrusion of moisture and hydrogen.

### Thirtieth Embodiment

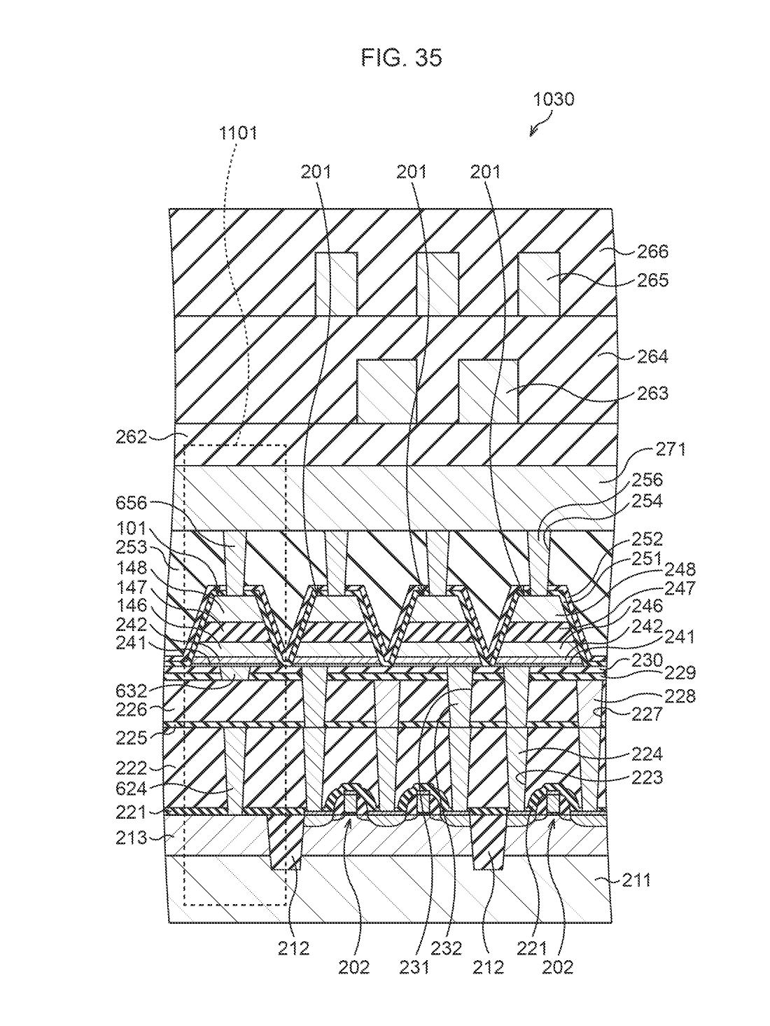

Next, a thirtieth embodiment will be explained. The thirtieth embodiment is an example of a ferroelectric memory. FIG. 35 is a cross-sectional view illustrating a structure of a semiconductor device according to the thirtieth embodiment. The layout and the circuit structure of the semiconductor device according to the thirtieth embodiment are similar to those of the first embodiment. FIG. 35 illustrates a cross section corresponding to the cross section taken along the line I-I in FIG. 1.

In a semiconductor device 1030 according to the thirtieth embodiment, as illustrated in FIG. 35, the guard ring 1101 includes a pseudo wiring 632 with an annular planar shape as well as the pseudo ferroelectric capacitor 101, the part of the wiring 271, the pseudo wiring 656 and the pseudo wiring 624. The other structure is similar to the twenty-third embodiment (FIG. 28). The guard ring 1101 has a structure similar to that illustrated in FIG. 35 also in the cross section taken along a line II-II, the cross section taken along a line III-III, and the cross section taken along a line IV-IV in FIG. 1.

Effects similar to those of the twenty-third embodiment can be obtained by the semiconductor device 1030. The pseudo wiring 632 also contributes to suppression of intrusion of moisture and hydrogen.

### Thirty-First Embodiment

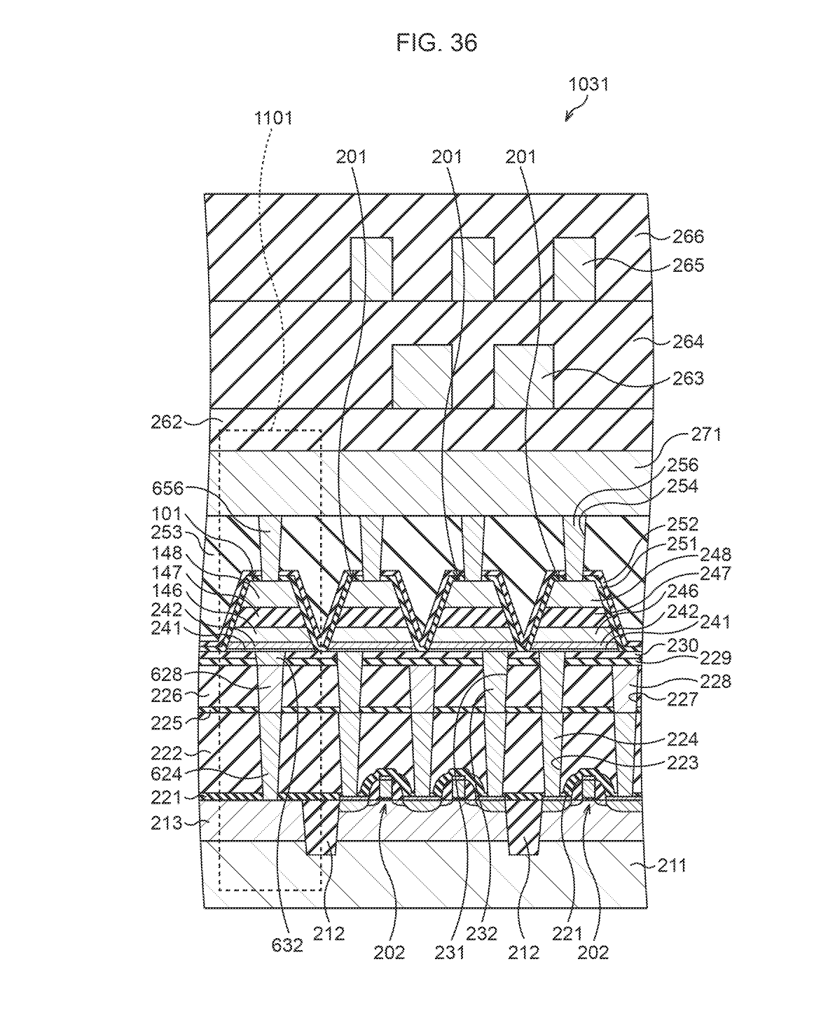

Next, a thirty-first embodiment will be explained. The thirty-first embodiment is an example of a ferroelectric memory. FIG. 36 is a cross-sectional view illustrating a structure of a semiconductor device according to the thirty-first embodiment. The layout and the circuit structure of the semiconductor device according to the thirty-first embodiment are similar to those of the first embodiment. FIG. 36 illustrates a cross section corresponding to the cross section taken along the line I-I in FIG. 1.

In a semiconductor device 1031 according to the thirty-first embodiment, as illustrated in FIG. 36, the guard ring 1101 includes a pseudo wiring 632 with an annular planar shape as well as the pseudo ferroelectric capacitor 101, the part of the wiring 271, the pseudo wiring 656, the pseudo wiring 628 and the pseudo wiring 624. The other structure is similar to the twenty-fourth embodiment (FIG. 29). The guard ring 1101 has a structure similar to that illustrated in FIG. 36 also in the cross section taken along a line II-II, the cross section taken along a line III-III, and the cross section taken along a line IV-IV in FIG. 1.

Effects similar to those of the twenty-fourth embodiment can be obtained by the semiconductor device 1031. The pseudo wiring 632 also contributes to suppression of intrusion of moisture and hydrogen.

In any of the first to thirty-first embodiments, the number of ferroelectric capacitors 201 surrounded by the guard ring 1101 is not particularly limited.

### Thirty-Second Embodiment

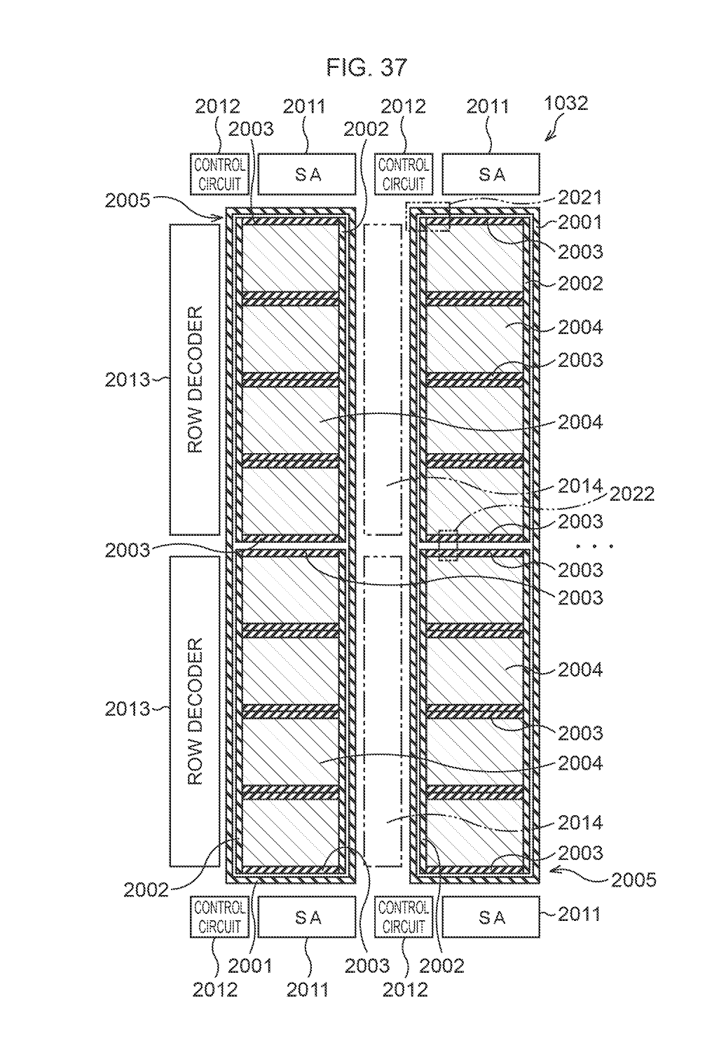

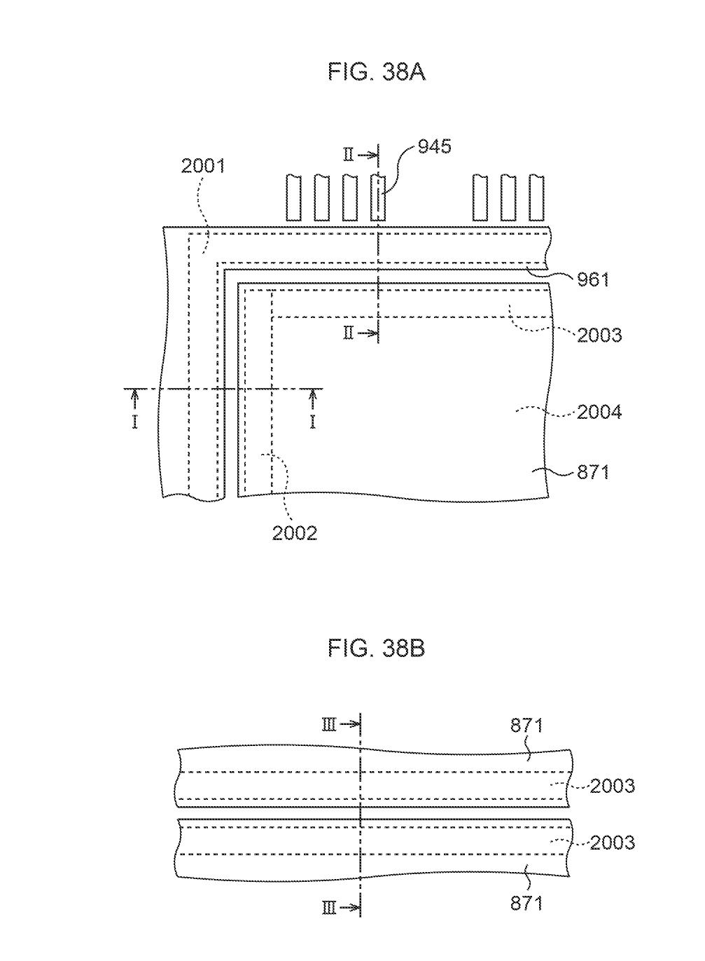

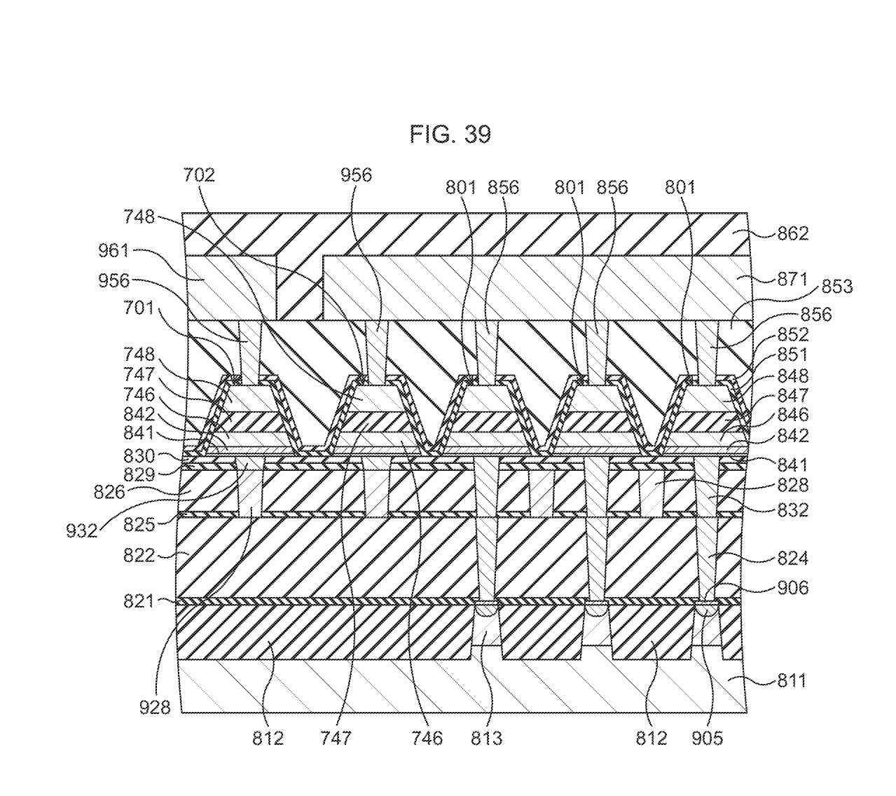

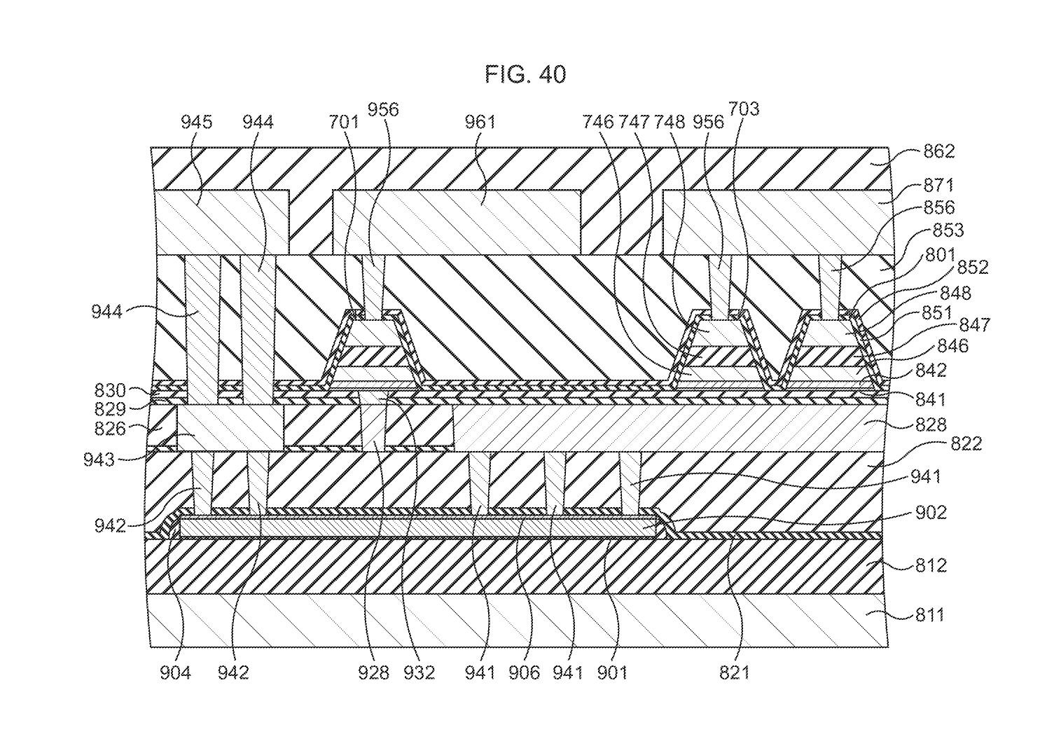

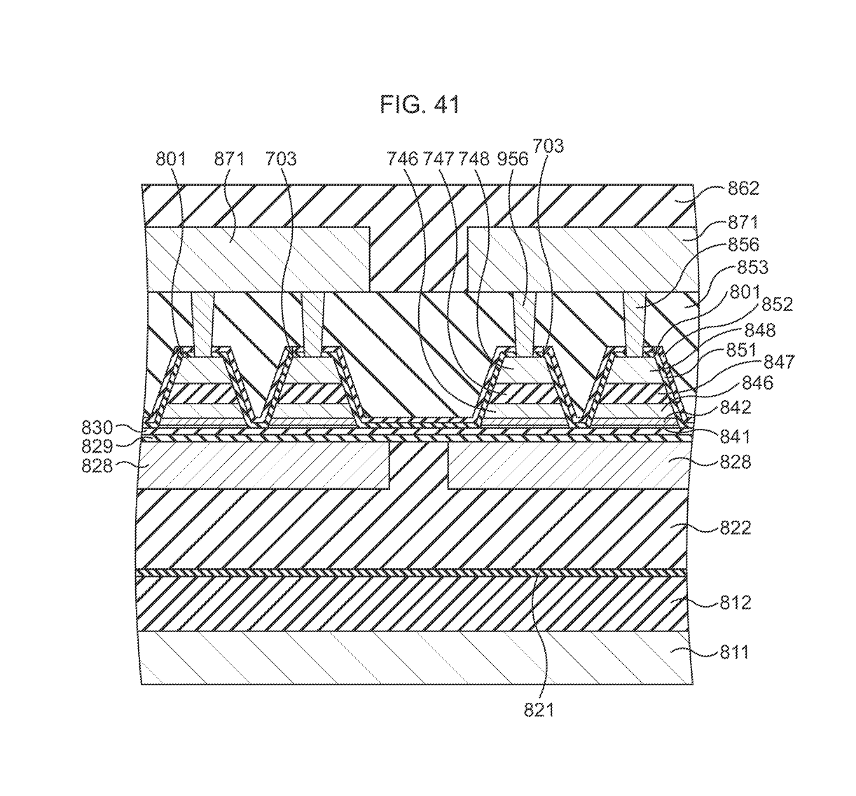

Next, a thirty-second embodiment will be explained. The thirty-second embodiment is an example of a ferroelectric memory. FIG. 37 is a view illustrating a layout of a semiconductor device according to the thirty-second embodiment, and FIG. 38A and FIG. 38B are views illustrating parts of FIG. 37 in enlargement. FIG. 38A corresponds to a region 2021 in FIG. 37, and FIG. 38B corresponds to a region 2022 in FIG. 37. FIG. 39 is a cross-sectional view taken along a line I-I in FIG. 38A, FIG. 40 is a cross-sectional view taken along a line II-II in FIG. 38A, and FIG. 41 is a cross-sectional view taken along a line III-III in FIG. 38B.

First, the layout will be described. In a semiconductor device 1032 according to the thirty-second embodiment, 256 word lines extend in parallel, a plurality of bit lines extend in parallel so as to be orthogonal to the word lines, and one memory cell is disposed at each intersection of these lines. One memory cell includes one ferroelectric capacitor and one switching element. The bit lines extend in an upward and downward direction, and the word lines extend in a leftward and rightward direction in FIG. 37. Two row decoders 2013 are disposed, the word lines are grouped by every 32 lines (four groups), and 128 word lines are connected to one row decoder 2013. The bit lines are grouped by every 22 bits (44 lines), bit lines of 22 bits (44 lines) are connected to one sense amplifier (SA) 2011, and 128 memory cells are connected to one bit line. Each sense amplifier 2011 is provided with a control circuit 2012 which controls the sense amplifier 2011.

One cell region 2004 is assigned to each intersection of one group of word lines and one group of bit lines, and one plate line is shared among 704 ferroelectric capacitors included in one cell region 2004. A bit line is shared among four cell regions 2004 aligning in a direction in which the bit lines extend. A wiring 871 is a part of the plate line and wirings 828 are parts of the bit line, which will be described later.

Outside each cell region 2004, protection structures 2002 extending in parallel with the bit lines and protection structures 2003 extending in parallel with the word lines are disposed. Although details will be described later, a structure similar to the guard ring of the twenty-ninth embodiment (FIG. 34) is included in the protection structures 2002, and a structure similar to the guard ring of the twenty-first embodiment (FIG. 26) is included in the protection structures 2003. The protection structures 2002 are connected sequentially among the four groups of word lines connected to one row decoder 2013. Further, both ends of the protection structures 2003 are connected to the protection structures 2002.

The eight cell regions 2004 aligning in the direction in which the bit lines extend are surrounded by a protection structure 2001 from outside the protection structures 2002 and the protection structures 2003. Although details will be described later, a structure similar to the guard ring of the twenty-ninth embodiment (FIG. 34) is included in the protection structure 2001. A shunt 2014 of the word line is disposed at a level higher than the wiring 871, which functions as a part of the plate line, between adjacent protection structures 2001 in the direction in which the word lines extend.

Next, a cross-sectional structure of the semiconductor device 1032 will be described. In the semiconductor device 1032, an element isolation region 812 which defines active regions of transistors is formed at a surface of a semiconductor substrate 811. A P-well 813 is formed in the active region, and a switching element with the P-well 813 is formed. The switching element is a field effect transistor, for example. This field effect transistor includes, as illustrated in FIG. 4A, a gate insulating film 401, a gate electrode 402, impurity doped regions 403, an insulating side wall 404, impurity doped regions 405 and silicide layers 406, for example. The gate electrode 402 functions as a part of the word line.

A cover film 821 covering the switching element is formed over the semiconductor substrate 811, and an interlayer insulating film 822 is formed over the cover film 821. A contact hole through which the silicide layer 406 is exposed is formed in the interlayer insulating film 822 and the cover film 821, and a conductive plug 824 is formed in the contact hole. An etching stopper film 825 is formed over the interlayer insulating film 822 and the conductive plug 824, and an interlayer insulating film 826 is formed over the etching stopper film 825. An opening is formed in the interlayer insulating film 826 and the etching stopper film 825, and a wiring 828 is formed in the opening. The wiring 828 is connected to a part of the conductive plugs 824 and functions as a part of the bit line. An oxidation preventing film 829 is formed over the interlayer insulating film 826 and the wiring 828, and a buffer film 830 is formed over the oxidation preventing film 829. A contact hole through which a part of the conductive plugs 824 is exposed is formed in the buffer film 830, the oxidation preventing film 829, the interlayer insulating film 826 and the etching stopper film 825, and a conductive plug 832 is formed in the contact hole.

A titanium nitride film 841 and an aluminum titanium nitride film 842 are formed on and above the buffer film 830 and the conductive plug 832. The ferroelectric capacitors 201, a pseudo ferroelectric capacitor 701 included in the protection structure 2001, a pseudo ferroelectric capacitor 702 included in the protection structure 2002, and a pseudo ferroelectric capacitor 703 included in the protection structure 2003 are formed above the aluminum titanium nitride film 842. The pseudo ferroelectric capacitor 701 is formed in the protection structure 2001, the pseudo ferroelectric capacitor 702 is formed in the protection structure 2002, and the pseudo ferroelectric capacitor 703 is formed in the protection structure 2003. The ferroelectric capacitor 801 includes a bottom electrode 846, a capacitor insulating film 847 and a top electrode 848, and each of the pseudo ferroelectric capacitor 701, the pseudo ferroelectric capacitor 702 and the pseudo ferroelectric capacitor 703 includes a pseudo bottom electrode 746, a pseudo capacitor insulating film 747 and a pseudo top electrode 748. The titanium nitride film 841 and the aluminum titanium nitride film 842 are patterned similarly to the bottom electrode 846, the capacitor insulating film 847 and the top electrode 848, and the pseudo bottom electrode 746, the pseudo capacitor insulating film 747 and the pseudo top electrode 748. The bottom electrode 846 of one of the ferroelectric capacitors 801 is electrically connected to one of the conductive plugs 832.

The bottom electrode 846 includes, as illustrated in FIG. 4B, an iridium film 431, an iridium oxide film 432 and a platinum film 433. The capacitor insulating film 847 includes a ferroelectric film 434 and a ferroelectric film 435. The ferroelectric film 434 and the ferroelectric film 435 are different in composition, for example. The top electrode 848 includes an iridium oxide film 436, an iridium oxide film 437 and an iridium film 438. For example, the oxidation degree of the iridium oxide film 437 is higher than the oxidation degree of the iridium oxide film 436.

The pseudo bottom electrode 746 includes, as illustrated in FIG. 4C, an iridium film 331, an iridium oxide film 332 and a platinum film 333. The pseudo capacitor insulating film 747 includes a ferroelectric film 334 and a ferroelectric film 335. The ferroelectric film 334 and the ferroelectric film 335 are different in composition, for example. The pseudo top electrode 748 includes an iridium oxide film 336, an iridium oxide film 337 and an iridium film 338. For example, the oxidation degree of the iridium oxide film 337 is higher than the oxidation degree of the iridium oxide film 336.

A protection film 851 covering the ferroelectric capacitors 801, the pseudo ferroelectric capacitor 701, the pseudo ferroelectric capacitor 702 and the pseudo ferroelectric capacitor 703 is formed over the buffer film 830, a protection film 852 is formed over the protection film 851, and an interlayer insulating film 853 is formed over the protection film 852. A contact hole through which the top electrode 848 is exposed is formed in the interlayer insulating film 853, the protection film 852 and the protection film 851, and a conductive plug 856 is formed in the contact hole.

A wiring 871 electrically connected to the conductive plug 856 is formed above the interlayer insulating film 853. The wiring 871 functions as a part of the plate line. The wiring 871 is formed to cover all the ferroelectric capacitors 801 included in the cell region 2004 and regions between the ferroelectric capacitors 801 from above the top electrodes 848. Therefore, the plurality of ferroelectric capacitors 801 connected to this wiring 871 and the regions between the ferroelectric capacitors 801 are within the contour of the wiring 871 in planar view. The wiring 871 is formed to extend into the protection structure 2002 and the protection structure 2003, and a part of the wiring 871 is included in the protection structure 2002 and the protection structure 2003. An interlayer insulating film 862 covering the wiring 861 is formed over the interlayer insulating film 853, and wirings and so on similar to those of the first embodiment are formed.

The protection structure 2002 includes the pseudo ferroelectric capacitor 702, as described above. As illustrated in FIG. 39, the pseudo top electrode 748 in the pseudo ferroelectric capacitor 702 is connected to the wiring 871 via a pseudo wiring 956 in the interlayer insulating film 853 and so on. A pseudo wiring 932 in contact with the titanium nitride film 841 under the pseudo ferroelectric capacitor 702 is formed in the buffer film 830 and the oxidation preventing film 829, and a pseudo wiring 928 in contact with the pseudo wiring 932 is formed in the interlayer insulating film 826 and the etching stopper film 825. The pseudo wiring 956, the pseudo ferroelectric capacitor 702, the pseudo wiring 932 and the pseudo wiring 928 extend from one end to another end of the protection structure 2002.

The protection structure 2003 includes the pseudo ferroelectric capacitor 703, as described above. As illustrated in FIG. 40 and FIG. 41, the pseudo top electrode 748 in the pseudo ferroelectric capacitor 703 is connected to the wiring 871 via the pseudo wiring 956 in the interlayer insulating film 853 and so on. The pseudo wiring 956 and the pseudo ferroelectric capacitor 702 extend from one end of the protection structure 2003 to another end thereof. The pseudo wiring 956 in the protection structure 2002 and the pseudo wiring 956 in the protection structure 2003 are connected continuously across a boundary between the protection structure 2002 and the protection structure 2003. The pseudo ferroelectric capacitor 702 in the protection structure 2002 and the pseudo ferroelectric capacitor 703 in the protection structure 2003 are connected continuously across the boundary between the protection structure 2002 and the protection structure 2003.

The protection structure 2001 includes the pseudo ferroelectric capacitor 701, as described above. As illustrated in FIG. 39 and FIG. 40, the pseudo top electrode 748 in the pseudo ferroelectric capacitor 701 is connected to a pseudo wiring 961 via the pseudo wiring 956 in the interlayer insulating film 853 and so on. The pseudo wiring 961 is insulated from the wiring 871 and is in a floating state. A pseudo wiring 932 in contact with the titanium nitride film 841 under the pseudo ferroelectric capacitor 701 is formed in the buffer film 830 and the oxidation preventing film 829, and a pseudo wiring 928 in contact with the pseudo wiring 932 is formed in the interlayer insulating film 826 and the etching stopper film 825. The pseudo wiring 961, the pseudo wiring 956, the pseudo ferroelectric capacitor 702, the pseudo wiring 932 and the pseudo wiring 928 extend across the whole circumference of the protection structure 2001.

The protection structure 2001, the protection structure 2002 and the protection structure 2003 are included in a guard ring 2005. The pseudo ferroelectric capacitor 701 is an example of a second pseudo ferroelectric capacitor, the pseudo bottom electrode 746 is an example of a second pseudo bottom electrode, the pseudo capacitor insulating film 747 is an example of a second pseudo capacitor insulating film, and the pseudo top electrode 748 is an example of a second pseudo top electrode.

As illustrated in FIG. 40, the wiring 828 extends to more inside than the protection structure 2001. An insulating film 901, a wiring 902, a silicide layer 906 and an insulating film 924 is formed to pass through a lower side of the protection structure 2001 on the element isolation region 812 contemporaneously with forming the field effect transistor. The wiring 902 and the wiring 828 are electrically connected to each other via a conductive plug 941 in the interlayer insulating film 822 and so on. The other end of the wiring 902, that is, the end outside the protection structure 2001 is connected to a wiring 945 on the interlayer insulating film 853 via a conductive plug 942 in the interlayer insulating film 822 and so on, a conductive film 943 in the interlayer insulating film 826 and so on, and a conductive plug 944 in the interlayer insulating film 853 and so on. The wiring 902 and the wiring 945 also function as a part of the bit line, and the wiring 945 is connected to the sense amplifier 2011.

In the thirty-second embodiment, the guard ring 2005 is provided with a double protection structure (the protection structures 2001 and 2002, or the protection structures 2001 and 2003), and thus intrusion of moisture and hydrogen can be suppressed furthermore. Since the protection structure 2003 is disposed between the cell regions 2004 in the direction in which the bit lines extend and no portion that divides the wiring 828 exists in the protection structure 2003, increase in chip area in a region where it is relatively difficult for in-process degradation to occur can be avoided. On the other hand, since the protection structure 2001 is disposed between the sense amplifier 2011 and the cell region 2004 which is immediately close thereto and the protection structure 2001 includes the pseudo wiring 932 and the pseudo wiring 928, intrusion of moisture and hydrogen can be hindered more securely in a region where it is particularly easy for in-process degradation to occur.

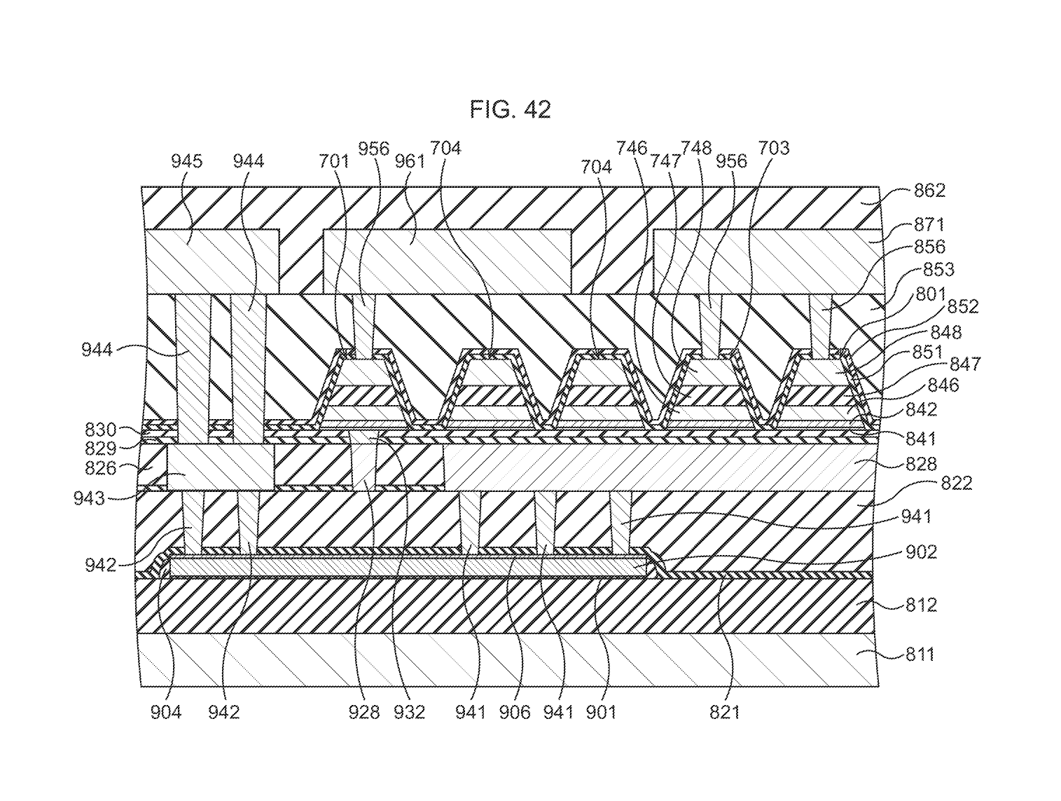

As illustrated in FIG. 42, one or more pseudo ferroelectric capacitors 704 may be between the pseudo ferroelectric capacitor 701 in the protection structure 2001 and the pseudo ferroelectric capacitor 703 in the protection structure 2003. Similarly, one or more pseudo ferroelectric capacitors may be between the pseudo ferroelectric capacitor 701 in the protection structure 2001 and the pseudo ferroelectric capacitor 702 in the protection structure 2002.

### Thirty-Third Embodiment

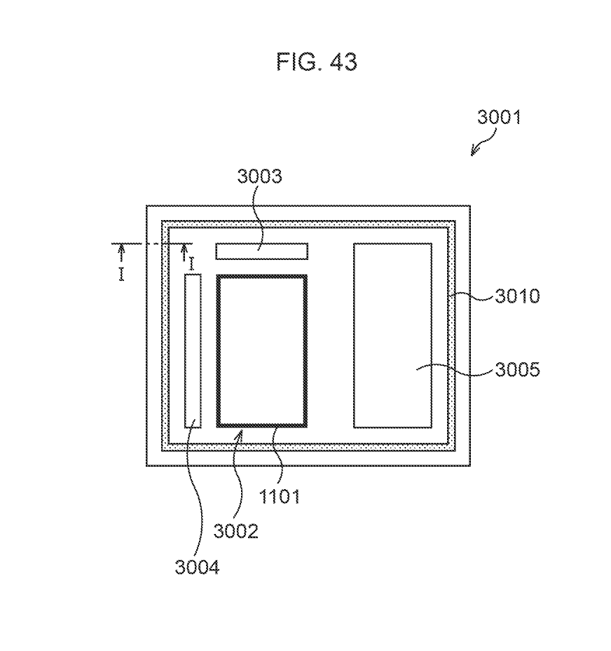

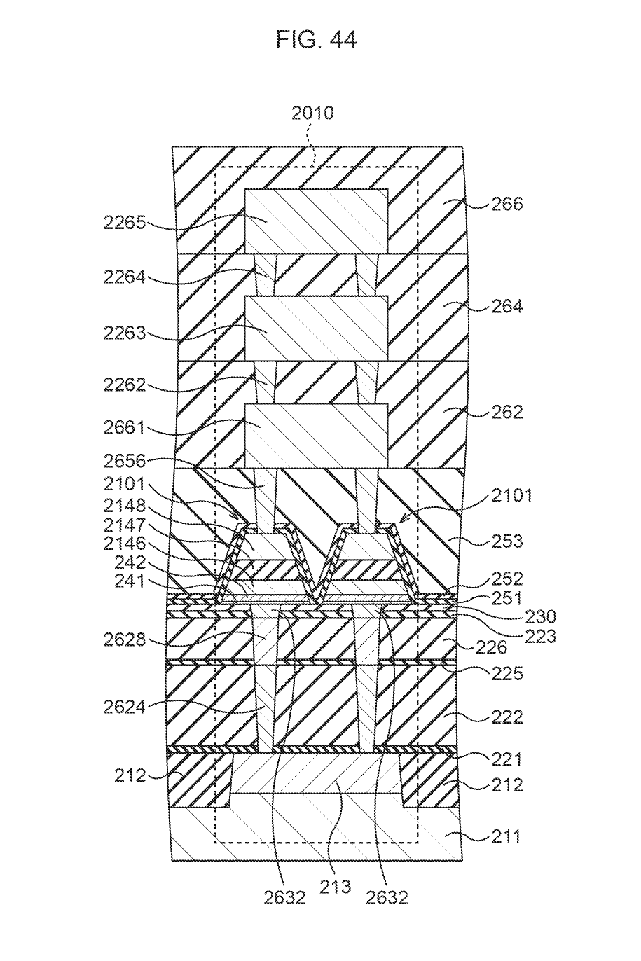

Next, a thirty-third embodiment will be described. FIG. 43 is a view illustrating a layout of a semiconductor device according to the thirty-third embodiment, and FIG. 44 is a cross-sectional view taken along a line I-I in FIG. 43.

A semiconductor device 3001 according to the thirty-third embodiment includes a memory cell array region 3002, as illustrated in FIG. 43. The memory cell array region 3002 includes a plurality of ferroelectric capacitors (not illustrated) and a guard ring 1101 surrounding these ferroelectric capacitors. The structure of one of the first to thirty-first embodiments is employed for the memory cell array region 3002, for example. Memory peripheral circuits 3003 and 3004 are disposed in the vicinity of the memory cell array region 3002. The memory peripheral circuits 3003 and 3004 include a row decoder, a sense amplifier, an amplifier and the like. The semiconductor device 3001 also includes a control circuit 3005. The control circuit 3005 includes a power supply circuit, and an input/output pad, and the like. A guard ring 3010 surrounding the memory cell array region 3002, the memory peripheral circuits 3003 and 3004 and the control circuit 3005 is formed along an outer periphery of the semiconductor device 3001.

As illustrated in FIG. 44, pseudo ferroelectric capacitors 2101 with an annular planar shape are doubly formed on the titanium aluminum nitride film 242. The pseudo ferroelectric capacitors 2101 are included in the guard ring 3010, and surround the ferroelectric capacitors 201 and the pseudo ferroelectric capacitor 101. The pseudo ferroelectric capacitors 2101 each include a pseudo bottom electrode 2146, a pseudo capacitor insulating film 2147 and a pseudo top electrode 2148. The guard ring 3010 includes pseudo wirings 2624, 2628, 2632 and 2656 with an annular planar shape. The pseudo wirings 2624 are doubly formed in the cover film 221 and the interlayer insulating film 222, the pseudo wirings 2628 are doubly formed in the etching stopper film 225 and the interlayer insulating film 226, and the pseudo wirings 2632 are doubly formed in the oxidation preventing film 229 and the buffer film 230. The pseudo wirings 2656 are doubly formed in the protection film 251, the protection film 252 and the interlayer insulating film 253. The guard ring 3010 includes a pseudo wiring 2661 on the insulating film 253, a pseudo wiring 2263 on the interlayer insulating film 262 and a pseudo wiring 2265 on the interlayer insulating film 264. Planar shapes of the pseudo wiring 2661, the pseudo wiring 2263 and the pseudo wiring 2265 are annular. Pseudo wirings 2262 are doubly formed between the pseudo wiring 2661 and the pseudo wiring 2263, and pseudo wirings 2264 are doubly formed between the pseudo wiring 2263 and the pseudo wiring 2265. Planar shapes of the pseudo wirings 2262 and the pseudo wirings 2264 are annular.

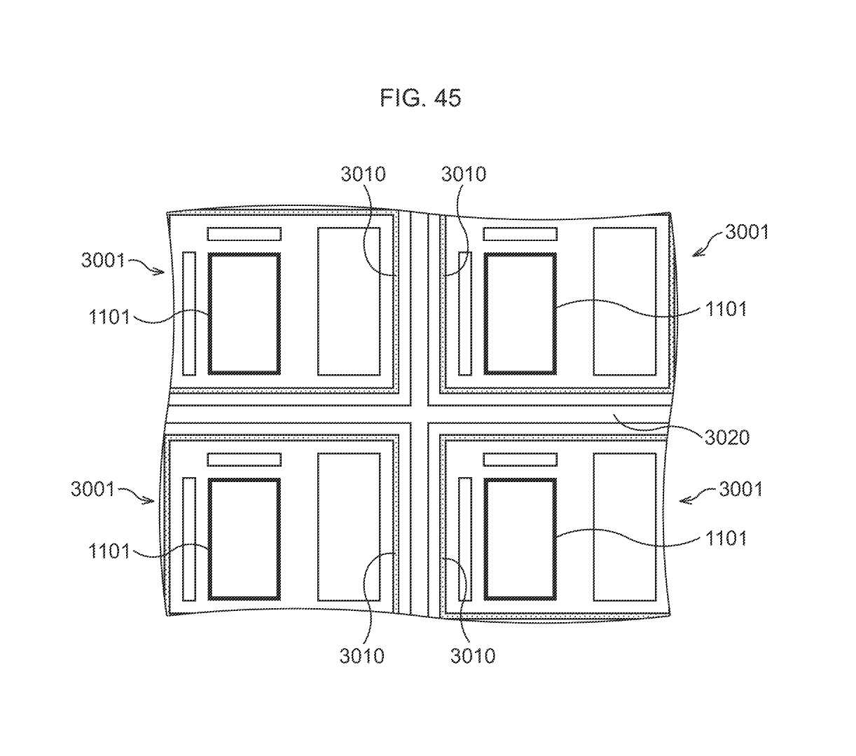

In manufacturing processes of the semiconductor device 3001, as illustrated in FIG. 45, a plurality of semiconductor devices 3001 are formed on one wafer to align in a vertical column with a scribe region 3020 being interposed therebetween. The scribe region 3020 includes an interlayer insulating film which is more liable to absorb moisture than the inside of the semiconductor devices 3001. In the thirty-third embodiment, since the guard ring 3010 which includes the pseudo ferroelectric capacitors 2101 with an annular planar shape is formed in the vicinity of the scribe region 3020 in the semiconductor devices 3001, intrusion of moisture from the scribe region 3020 into the semiconductor devices 3001 can be suppressed. Thus, property deterioration of the ferroelectric capacitors 201 can be suppressed more securely.

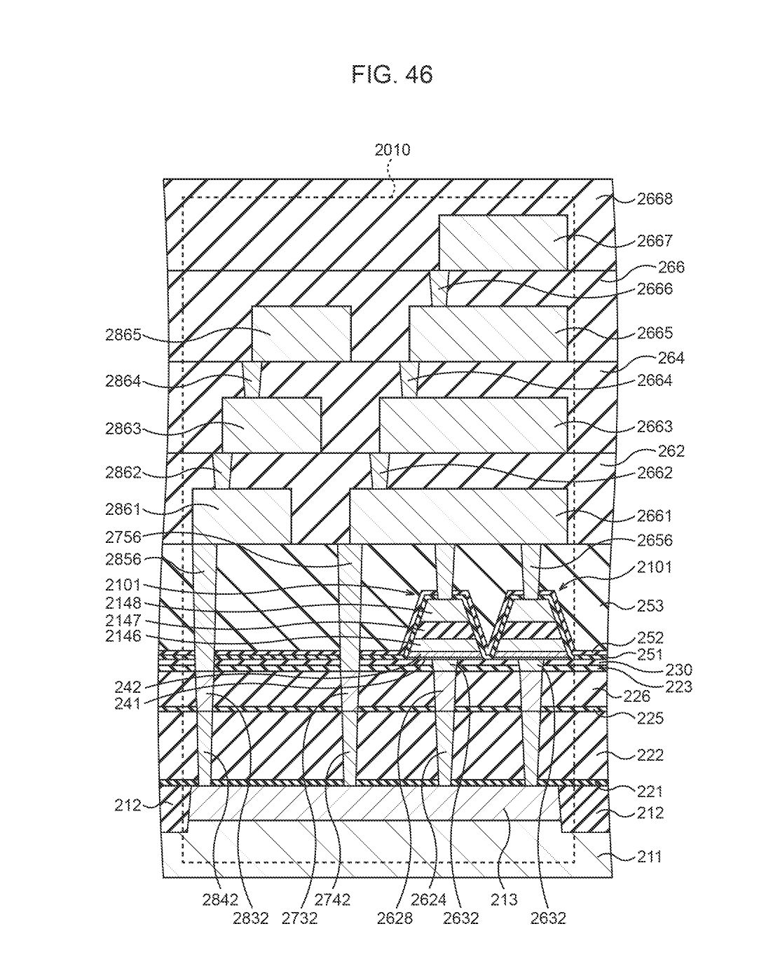

The guard ring 3010 may be structured as illustrated in FIG. 46. Specifically, the guard ring 3010 may be structured so that the higher a pseudo wiring included in the guard ring 3010 is, the more inside the outer edge of the pseudo wiring is in the semiconductor device 3001. In this example, a pseudo wiring 2667 and an interlayer insulating film 2668 are included on an interlayer insulating film 266, and a pseudo wiring 2666 is formed between a pseudo wiring 2665 and the pseudo wiring 2667. Pseudo wirings 2756, 2732 and 2742 which connect the pseudo wiring 2661 and a P-well 213 are also formed. Planar shapes of the pseudo wirings 2667, 2666, 2756, 2732 and 2742 are annular. The guard ring 3010 includes pseudo wirings 2865, 2864, 2863, 2862, 2861, 2856, 2832 and 2842. Planar shapes of the pseudo wirings 2865, 2864, 2863, 2862, 2861, 2856, 2832 and 2842 are annular. This structure is effective particularly when the width of the scribe region 3020 is small. This is because it is difficult for a crack to propagate during scribing.

### Thirty-Fourth Embodiment

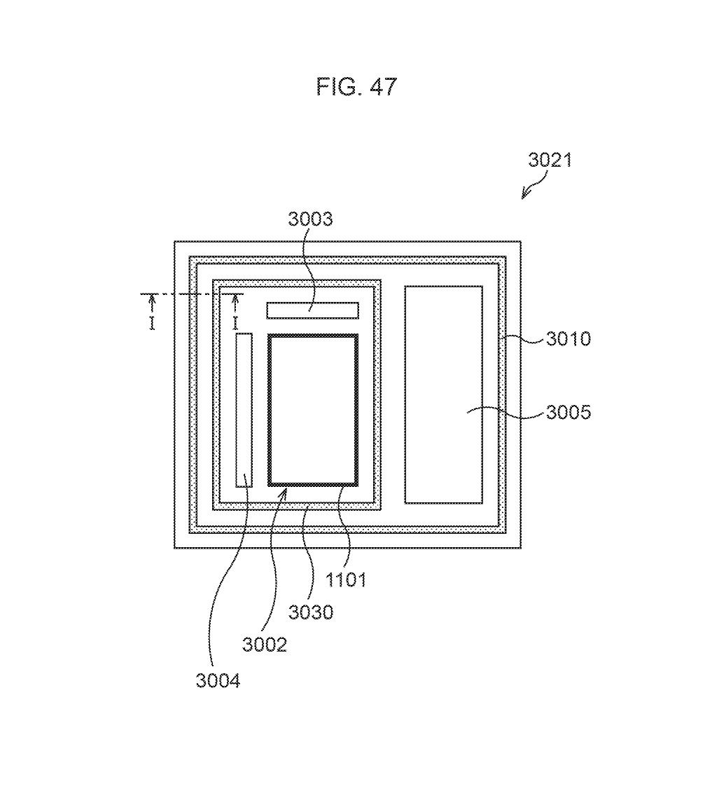

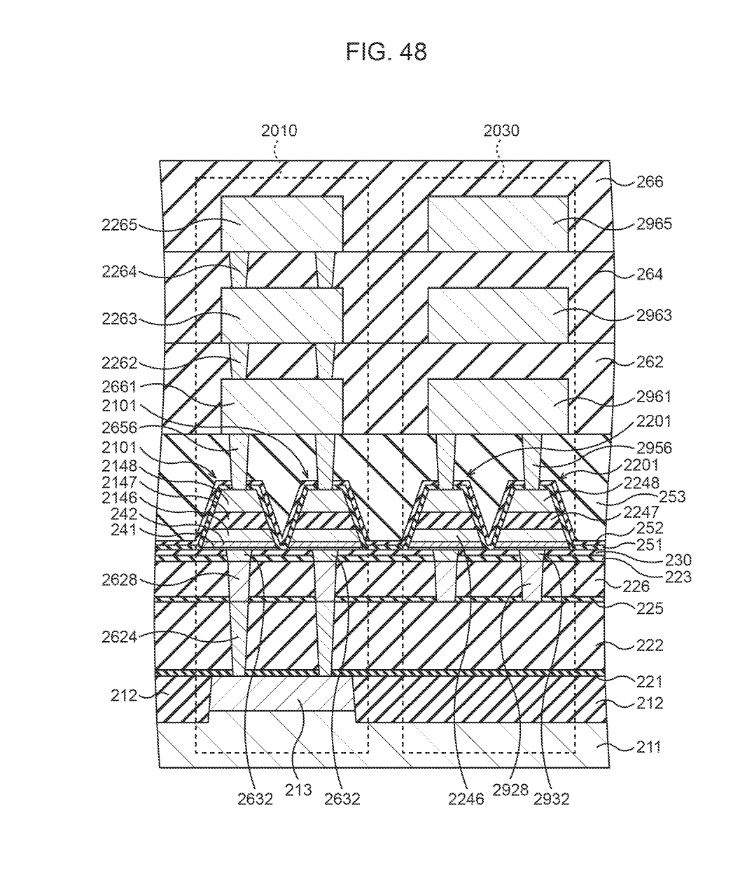

Next, a thirty-fourth embodiment will be described. FIG. 47 is a view illustrating a layout of a semiconductor device according to the thirty-fourth embodiment, and FIG. 48 is a cross-sectional view taken along a line I-I in FIG. 47.

In a semiconductor device 3021 according to the thirty-fourth embodiment, as illustrated in FIG. 47, a guard ring 3030 surrounding the memory cell array region 3002 and the memory peripheral circuits 3003 and 3004 is formed inside the guard ring 3010 and outside the control circuit 3005. The other structure related to the layout is similar to that of the thirty-third embodiment.

As illustrated in FIG. 48, pseudo ferroelectric capacitors 2201 with an annular planar shape are doubly formed on the titanium aluminum nitride film 242. The pseudo ferroelectric capacitors 2201 are included in the guard ring 3030, surround the ferroelectric capacitors 201 and the pseudo ferroelectric capacitor 101 from sides, and are surrounded by the pseudo ferroelectric capacitors 2101. The pseudo ferroelectric capacitors 2201 each include a pseudo bottom electrode 2246, a pseudo capacitor insulating film 2247 and a pseudo top electrode 2248. The guard ring 3030 includes pseudo wirings 2928, 2932 and 2956 with an annular planar shape. The pseudo wirings 2928 are doubly formed in the etching stopper film 225 and the interlayer insulating film 226, and the pseudo wirings 2932 are doubly formed in the oxidation preventing film 229 and the buffer film 230. The pseudo wirings 2956 are doubly formed in the protection film 251, the protection film 252 and the interlayer insulating film 253. The guard ring 3030 includes a pseudo wiring 2961 on the interlayer insulating film 253, a pseudo wiring 2963 on an interlayer insulating film 262 and a pseudo wiring 2965 on an interlayer insulating film 264. Planar shapes of the pseudo wiring 2961, the pseudo wiring 2963 and the pseudo wiring 2965 are annular.

The thirty-fourth embodiment enables to obtain higher moisture resistance.

Next, results of an experiment conducted by the present inventors with respect to the relation between structures and polarization charge amounts of guard rings will be described.

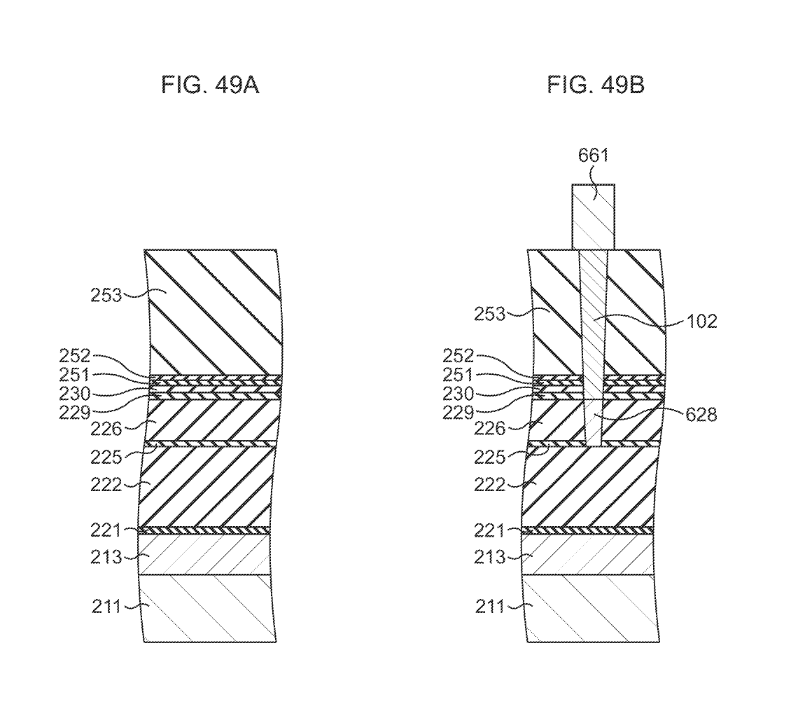

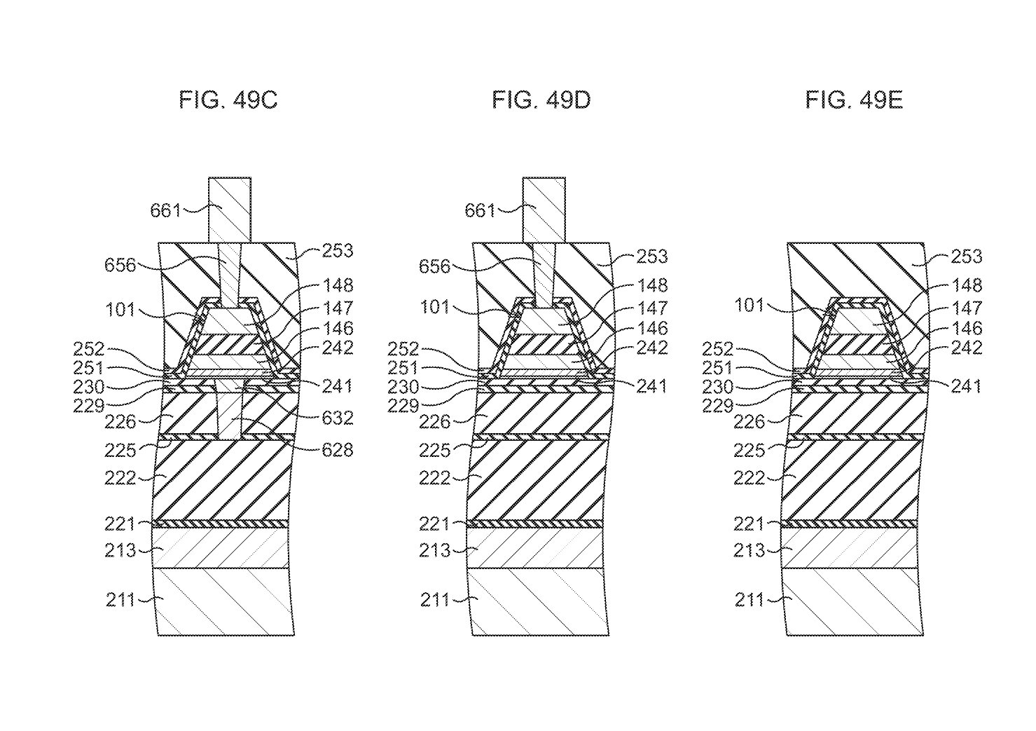

In this experiment, polarization charge amounts of five types of structures below were measured. A structure A included no guard ring in the periphery of ferroelectric capacitors as illustrated in FIG. 49A. In a structure B, as illustrated in FIG. 49B, a guard ring in the periphery of ferroelectric capacitors included the pseudo wiring 661, the pseudo wiring 102 and the pseudo wiring 628. In a structure C, as illustrated in FIG. 49C, a guard ring in the periphery of ferroelectric capacitors included the pseudo ferroelectric capacitor 101, the pseudo wiring 661, the pseudo wiring 656, the pseudo wiring 632 and the pseudo wiring 628. In a structure D, as illustrated in FIG. 49D, a guard ring in the periphery of ferroelectric capacitors included the pseudo ferroelectric capacitor 101, the pseudo wiring 661 and the pseudo wiring 656. In a structure E, as illustrated in FIG. 49E, a guard ring in the periphery of ferroelectric capacitors included the pseudo ferroelectric capacitor 101.

The sample of the structure C, the sample of the structure D, and the sample of the structure E were manufactured following the twenty-sixth embodiment (FIG. 31), the sixteenth embodiment (FIG. 21), and the first embodiment (FIG. 3A), respectively. The sample of the structure A was manufactured following the first embodiment and meanwhile omitting formation of the pseudo ferroelectric capacitors 101. The sample of the structure B was manufactured following the third embodiment (FIG. 8) and meanwhile omitting formation of the pseudo ferroelectric capacitors 101 and forming the pseudo wiring 102 contemporaneously with forming the conductive plug 256. Measurement results of polarization charge amounts Qsw with 1.8 V in these five structures are presented in Table 50. In Table 50, relative values by setting the average value of polarization charge amounts Qsw of the structure A to 1.0 are illustrated.

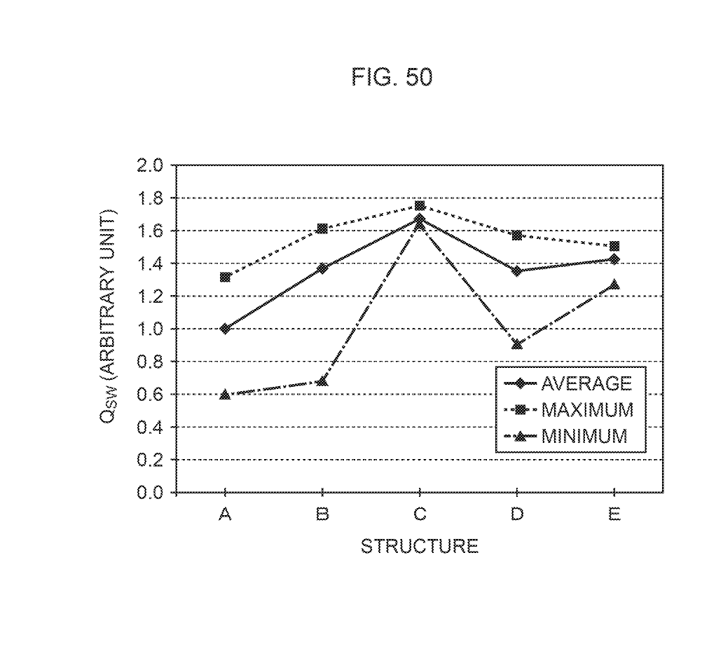

As illustrated in FIG. 50, in any of the structure C, the structure D and the structure E, all of the minimum value, the maximum value and the average value were higher than those of the structure A. In any of the structure C, the structure D and the structure E, the minimum value, which is most important among the minimum value, the maximum value and the average value, was higher than that of the structure B. In any of the structure C, the structure D and the structure E, dispersion in polarization charge amount was smaller than that of the structure B. From these results, it may be said that more excellent properties than those of the structure A and the structure B were obtained in the structure C, the structure D and the structure E. Most excellent properties were obtained in the structure C.

By the above-described semiconductor device and the like, since an appropriate guard ring or guard rings is or are provided, a sufficient polarization charge amount can be obtained even when ferroelectric capacitors are microfabricated.

All examples and conditional language provided herein are intended for the pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device, comprising:
a semiconductor substrate;
a ferroelectric capacitor above the semiconductor substrate;
a first guard ring around the ferroelectric capacitor above the semiconductor substrate, wherein
the ferroelectric capacitor comprises a bottom electrode, a capacitor insulating film and a top electrode, and
the first guard ring comprises a first pseudo bottom electrode, a first pseudo capacitor insulating film and a first pseudo top electrode, and surrounds the ferroelectric capacitors in planar view.

2. The semiconductor device according to claim 1, wherein:
the first pseudo bottom electrode is at a same level as the bottom electrode in relation to the substrate;
the first pseudo capacitor insulating film is at a same level as the capacitor insulating film in relation to the substrate; and
the first pseudo top electrode is at a same level as the top electrode in relation to the substrate.

3. The semiconductor device according to claim 1, wherein the first guard ring comprises a first conductive pattern above the first pseudo top electrode.

4. The semiconductor device according to claim 3, wherein the first guard ring comprises a second conductive pattern in contact with an upper surface of the first pseudo top electrode and a lower surface of the first conductive pattern.

5. The semiconductor device according to claim 4, further comprising:
a first insulating film over the top electrode and the first pseudo top electrode; and
a second insulating film over the first insulating film, wherein
the first conductive pattern is in the second insulating film, and
the second conductive pattern is in the first insulating film.

6. The semiconductor device according to claim 1, wherein the first guard ring comprises a third conductive pattern below the first pseudo bottom electrode.

7. The semiconductor device according to claim 6, wherein the first guard ring comprises a fourth conductive pattern below the third conductive pattern.

8. The semiconductor device according to claim 6, further comprising:
a third insulating film under the bottom electrode and the first pseudo bottom electrode; and
a fourth insulating film under the third insulating film, wherein
the bottom electrode and the first pseudo bottom electrode are above the third insulating film, and
the third conductive pattern is in the fourth insulating film.

9. The semiconductor device according to claim 6, wherein the first guard ring comprises a fifth conductive pattern in contact with a lower surface of the first pseudo bottom electrode and an upper surface of the third conductive pattern.

10. The semiconductor device according to claim 7, wherein the fourth conductive pattern is connected to the semiconductor substrate.

11. The semiconductor device according to claim 6, further comprising:
a third insulating film under the bottom electrode and the first pseudo bottom electrode;
a fourth insulating film under the third insulating film; and
a fifth insulating film under the fourth insulating film, wherein
the third conductive pattern is in the fourth insulating film.

12. The semiconductor device according to claim 9, further comprising:
a third insulating film under the bottom electrode and the first pseudo bottom electrode;
a fourth insulating film under the third insulating film; and
a fifth insulating film under the fourth insulating film, wherein
the fifth conductive pattern is in the third insulating film, and
the third conductive pattern is in the fourth insulating film.

13. The semiconductor device according to claim 7, further comprising:
a third insulating film under the bottom electrode and the first pseudo bottom electrode;
a fourth insulating film under the third insulating film; and
a fifth insulating film under the fourth insulating film, wherein
the fourth conductive pattern is in the fifth insulating film.

14. The semiconductor device according to claim 1, further comprising a wiring above the top electrode, the wiring overlapping the ferroelectric capacitors and regions between the ferroelectric capacitors in planar view.

15. The semiconductor device according to claim 14, wherein the first conductive pattern is coupled to the wiring.

16. The semiconductor device according to claim 1, further comprising a second guard ring that comprises a second pseudo bottom electrode, a second pseudo capacitor insulating film and a second pseudo top electrode,
wherein the second guard ring surrounds the first guard ring in planar view.

17. The semiconductor device according to claim 1, further comprising a silicon nitride film under the bottom electrode and the first pseudo bottom electrode.

18. A method of manufacturing a semiconductor device, comprising:
forming a first conductive film, a ferroelectric film and a second conductive film over a semiconductor substrate; and
etching the first conductive film, the ferroelectric film and the second conductive film so as to form a ferroelectric capacitor and a first guard ring,
wherein the first guard ring surrounds the ferroelectric capacitor in planar view.
